(19) United States
(12) Patent Application Publication
(10) Pub. No.: US 2016/0028027 A1
(43) Pub. Date: Jan. 28, 2016

(54) Organometallic Complex, Light-Emitting Element, Light-Emitting Device, Electronic Device, and Lighting Device

(71) Applicant: Semiconductor Energy Laboratory Co., Ltd., Kanagawa-ken (JP)

(72) Inventors: Hideko Inoue, Atsugi (JP); Tomoka HARA, Ebina (JP); Takahiro ISHISONE, Atsugi (JP); Kunihiko SUZUKI, lsehara (JP); Takao HAMADA, Atsugi (JP); Miki KANAMOTO, Atsugi (JP)

(73) Assignee: Semiconductor Energy Laboratory Co., Ltd., Kanagawa-ken (JP)

(21) Appl. No.: 14/808,603

(22) Filed: Jul. 24, 2015

(30) Foreign Application Priority Data
Jul. 25, 2014 (JP) 2014-151503

(51) Int. Cl. H01L 51/00; H01L 27/32; H01L 51/50; C07F 15/00; C09K 11/06

(52) U.S. Cl. CPC H01L 51/0085; C07F 15/0033; C09K 11/06; H01L 51/5016; H01L 27/3244; H01L 27/3225; C09K 2211/185; C09K 2211/1059; C09K 2211/1007

(57) ABSTRACT

An object is to provide a novel organometallic complex. Another object is to provide an organometallic complex exhibiting green to blue phosphorescence. Another object is to provide an organometallic complex having deep HOMO and exhibiting green to blue phosphorescence. Another object is to provide a light-emitting element with high emission efficiency. Another object is to provide a light-emitting element exhibiting green to blue phosphorescence and having low drive voltage. To provide an organometallic complex which includes a 1,2,4-triazole skeleton and in which an N-carbazolyl group is bonded to the 3-position of the 1,2,4-triazole skeleton via a phenylene group, a phenyl group is bonded to the 4-position of the 1,2,4-triazole skeleton, the 2-position of the 1,2,4-triazole skeleton coordinates to iridium, and the phenylene group is bonded to the iridium. To provide a light-emitting element including the organometallic complex as an emission center.

### TECHNICAL FIELD

One embodiment of the present invention relates to an organometallic complex, and a light-emitting element, a display module, a lighting module, a display device, a light-emitting device, an electronic device, and a lighting device each including the organometallic complex. Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a memory device, a method for driving any of them, and a method for manufacturing any of them.

### BACKGROUND ART

As next generation lighting devices or display devices, display devices using light-emitting elements (organic EL elements) in which organic compounds or organometallic complexes are used as light-emitting substances have been developed and reported because of their potential for thinness, lightness, high-speed response to input signals, low power consumption, and the like.

In an organic EL element, voltage application between electrodes, between which a light-emitting layer is interposed, causes recombination of electrons and holes injected from the electrodes, which brings a light-emitting substance into an excited state, and the return from the excited state to the ground state is accompanied by light emission. Since the spectrum of light emitted from a light-emitting substance depends on the light-emitting substance, use of different types of light-emitting substances makes it possible to obtain light-emitting elements which exhibit various colors.

Although displays or lighting devices including light-emitting elements can be suitably used for a variety of electronic devices as described above, their performance has plenty of room to improve. In order to achieve this, materials that have good characteristics and are easily handled are required.

Patent Document 1 discloses an organometallic complex having a 1,2,4-triazole skeleton.

### REFERENCE

### Patent Document

### [Patent Document 1] Japanese Published Patent Application No. 2012-46479

### DISCLOSURE OF INVENTION

An object of one embodiment of the present invention is to provide a novel organometallic complex. Another object of one embodiment of the present invention is to provide an organometallic complex exhibiting green to blue phosphorescence. Another object of one embodiment of the present invention is to provide an organometallic complex having deep HOMO and exhibiting green to blue phosphorescence. Another object of one embodiment of the present invention is to provide a light-emitting element with high emission efficiency. Another object of one embodiment of the present invention is to provide a light-emitting element exhibiting green to blue phosphorescence and having low drive voltage. Another object of one embodiment of the present invention is to provide a light-emitting device with low power consumption.

Another object of one embodiment of the present invention is to provide a novel light-emitting element. Another object of one embodiment of the present invention is to provide a display module, a lighting module, a light-emitting device, a display device, an electronic device, and a lighting device each having low power consumption.

It is only necessary that at least one of the above objects be achieved in one embodiment of the present invention. Note that the description of these objects does not disturb the existence of other objects. Note that one embodiment of the present invention does not necessarily achieve all the objects. Other objects will be apparent from and can be derived from the description of the specification, the drawings, the claims, and the like.

One embodiment of the present invention is a light-emitting element including an organometallic complex as an emission center. The organometallic complex includes a 1,2,4-triazole skeleton. An N-carbazolyl group is bonded to the 3-position of the 1,2,4-triazole skeleton via a phenylene group. The 2-position of the 1,2,4-triazole skeleton coordinates to iridium. The phenylene group connecting the 1,2,4-triazole skeleton and the N-carbazolyl group is bonded to the iridium.

Another embodiment of the present invention is an organometallic complex including a structure represented by General Formula (G0).

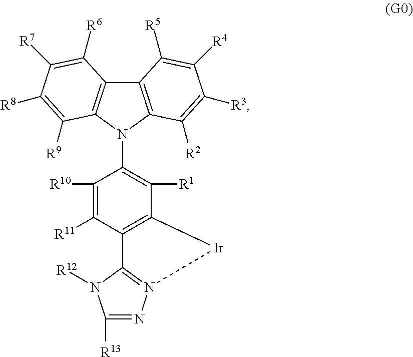

In General Formula (G0), R¹ to R¹³ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G1).

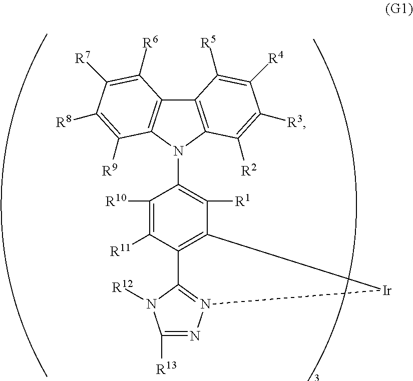

In General Formula (G1), R¹ to R¹³ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G2).

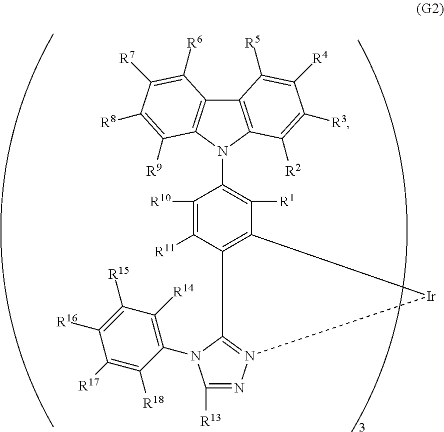

In General Formula (G2), R¹ to R¹¹ and R¹³ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G3).

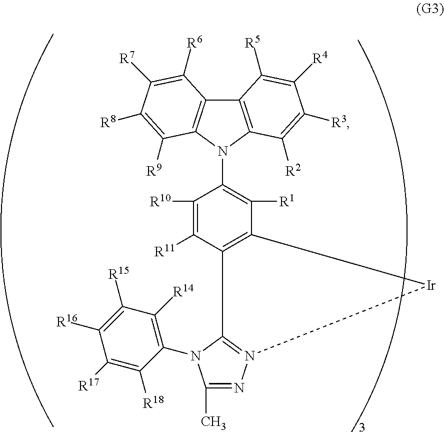

In General Formula (G3), R¹ to R¹¹ and R¹⁴ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G4).

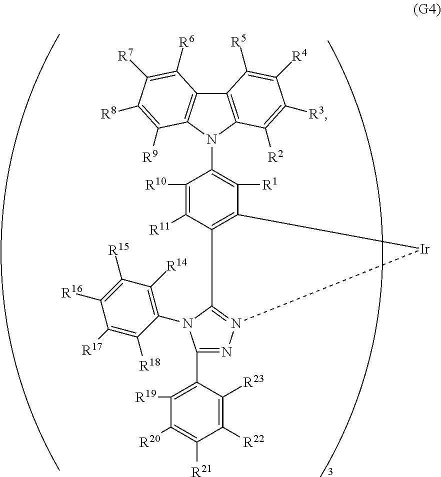

In General Formula (G4), R¹ to R¹¹, R¹⁴ to R¹⁸, and R¹⁹ to R²³ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G5).

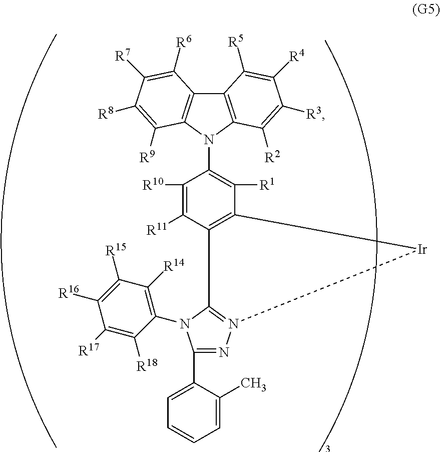

In General Formula (G5), R¹ to R¹¹ and R¹⁴ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G6).

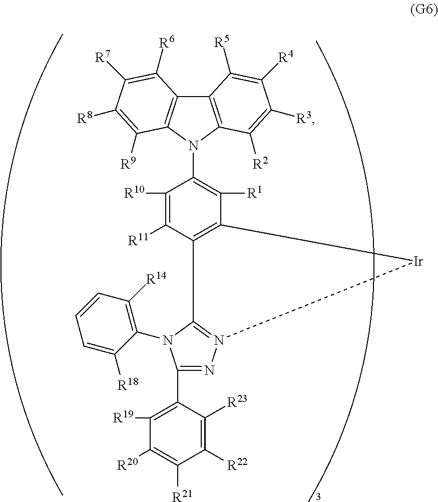

In General Formula (G6), R¹ to R¹¹, R¹⁴, R¹⁸, and R¹⁹ to R²³ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex represented by General Formula (G7).

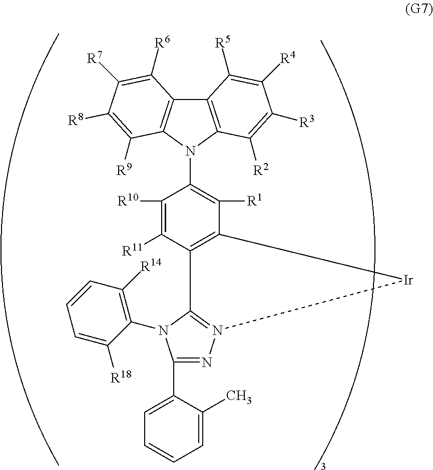

In General Formula (G7), R¹ to R¹¹, R¹⁴, and R¹⁸ each independently represent any one of hydrogen, an alkyl group having 1 to 6 carbon atoms, a cycloalkyl group having 5 to 7 carbon atoms, and an aryl group having 6 to 12 carbon atoms.

Another embodiment of the present invention is an organometallic complex which is any one of the above organometallic complexes and in which each of R¹⁴ and R¹⁸ represents a methyl group or an isopropyl group.

Another embodiment of the present invention is a light-emitting element including any one of the above organometallic complexes.

Another embodiment of the present invention is a light-emitting device including any one of the above light-emitting elements, and a transistor or a substrate.

Another embodiment of the present invention is an electronic device including the above light-emitting device, and a sensor, an operation button, a speaker, or a microphone.

Another embodiment of the present invention is a lighting device including the above light-emitting device and a housing.

Note that the light-emitting device in this specification includes an image display device using a light-emitting element. The light-emitting device may be included in a module in which a light-emitting element is provided with a connector such as an anisotropic conductive film or a tape carrier package (TCP), a module in which a printed wiring board is provided at the end of a TCP, and a module in which an integrated circuit (IC) is directly mounted on a light-emitting element by a chip on glass (COG) method. The light-emitting device may be included in lighting equipment.

One embodiment of the present invention makes it possible to provide a novel organometallic complex. One embodiment of the present invention makes it possible to provide an organometallic complex exhibiting green to blue phosphorescence. One embodiment of the present invention makes it possible to provide an organometallic complex having deep HOMO and exhibiting green to blue phosphorescence. One embodiment of the present invention makes it possible to provide a light-emitting element with high emission efficiency. One embodiment of the present invention makes it possible to provide a light-emitting element exhibiting green to blue phosphorescence and having low drive voltage. One embodiment of the present invention makes it possible to provide a light-emitting device with low power consumption.

Another embodiment of the present invention makes it possible to provide a novel light-emitting element. Another embodiment of the present invention makes it possible to provide a display module, a lighting module, a light-emitting device, a display device, an electronic device, and a lighting device each having low power consumption.

It is only necessary that at least one of the above effects be achieved in one embodiment of the present invention. Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF DRAWINGS

FIGS. 1A and 1B are conceptual diagrams of light-emitting elements.

FIGS. 2A and 2B are conceptual diagrams of an active matrix light-emitting device.

FIGS. 3A and 3B are conceptual diagrams of an active matrix light-emitting device.

FIG. 4 is a conceptual diagram of an active matrix light-emitting device.

FIGS. 5A and 5B are conceptual diagrams of a passive matrix light-emitting device.

FIGS. 6A and 6B illustrate a lighting device.

FIGS. 7A, 7B1, 7B2, 7C, and 7D illustrate electronic devices.

FIG. 8 illustrates a light source device.

FIG. 9 illustrates a lighting device.

FIG. 10 illustrates a lighting device.

FIG. 11 illustrates in-vehicle display devices and lighting devices.

FIGS. 12A to 12C illustrate an electronic device.

FIGS. 13A and 13B are NMR charts of [Ir(MCzptz)₃].

FIG. 14 shows an absorption spectrum and an emission spectrum of [Ir(MCzptz)₃].

FIG. 15 shows an MS spectrum of [Ir(MCzptz)₃].

FIGS. 16A and 16B are NMR charts of [Ir(mpCzptz-dmp)₃].

FIG. 17 shows an absorption spectrum and an emission spectrum of [Ir(mpCzptz-dmp)₃].

FIG. 18 shows an MS spectrum of [Ir(mpCzptz-dmp)₃].

FIGS. 19A and 19B are NMR charts of [Ir(mpCzptz-diPrp)₃].

FIG. 20 shows an absorption spectrum and an emission spectrum of [Ir(mpCzptz-diPrp)₃].

FIG. 21 shows calculation results of energy levels of molecular orbitals and distribution of HOMO and LUMO of [Ir(MCzptz)₃] and [Ir(Mptz)₃].

FIG. 22 shows voltage-current characteristics of Light-emitting element 1 and Light-emitting element 2.

FIG. 23 shows emission spectra of Light-emitting element 1 and Light-emitting element 2.

FIG. 24 shows an absorption spectrum and an emission spectrum of [Ir(Mpcztz)₃].

FIGS. 25A and 25B are NMR charts of [Ir(Mpcztz)₃].

FIG. 26 shows an MS spectrum of [Ir(Mpcztz)₃].

### BEST MODE FOR CARRYING OUT THE INVENTION

Embodiments of the present invention will be explained in detail below with reference to the drawings. Note that the present invention is not limited to the description below, and it is easily understood by those skilled in the art that modes and details can be modified in various ways without departing from the spirit and scope of the present invention. Accordingly, the present invention should not be interpreted as being limited to the content of the embodiments below.

One embodiment of the present invention is an organometallic complex including a 1,2,4-triazole skeleton. An N-carbazolyl group is bonded to the 3-position of the 1,2,4-triazole skeleton via a phenylene group. A phenyl group is bonded to the 4-position of the 1,2,4-triazole skeleton. The 2-position of the 1,2,4-triazole skeleton coordinates to iridium. The phenylene group is bonded to the iridium. Note that the organometallic complex is preferably a tris-type organometallic complex in which three ligands as described above are coordinated.

The organometallic complex emits green to blue light and has high efficiency. The organometallic complex has deep HOMO and thus has an appropriate hole-trapping property when used as a light-emitting substance of a light-emitting element and enables the light-emitting element to have low drive voltage.

In the above organometallic complex, HOMO is unlikely to be distributed over the N-carbazolyl group that is bonded to the phenyl group bonded to the 3-position of the 1,2,4-triazole skeleton. This is because a 1,2,4-triazole complex in which an N-carbazolyl group is not bonded to the above position has shallow HOMO, and the distribution position of HOMO over the 1,2,4-triazole skeleton does not change even when the N-carbazolyl group is bonded. When the N-carbazolyl group is bonded to the phenyl group bonded to the 3-position of the 1,2,4-triazole skeleton, HOMO becomes deep. Thus, the use of the organometallic complex as a light-emitting substance of a light-emitting element enables an improved hole-transport property and low-voltage driving of the light-emitting element. In the organometallic complex, the distribution positions of HOMO and LUMO over the 1,2,4-triazole skeleton do not change even when the N-carbazolyl group is bonded. Accordingly, energy difference between HOMO and LUMO is the same as that in a conventional organometallic complex in which an N-carbazolyl group is not bonded, and the emission color is not affected by bonding of the N-carbazolyl group.

Note that unlike the above organometallic complex, an organometallic complex where any one of the 1- to 8-positions of the carbazolyl group is bonded to the 3-position of the 1,2,4-triazole skeleton and the carbon of the carbazolyl group which is adjacent to the carbon bonded to the triazole is bonded to the iridium does not have deeper HOMO than a conventional organometallic complex where not the carbazolyl group but the phenyl group is bonded to the 1,2,4-triazole skeleton.

The organometallic complex of one embodiment of the present invention can be regarded as an organometallic complex having the structure represented by General Formula (G0) below.

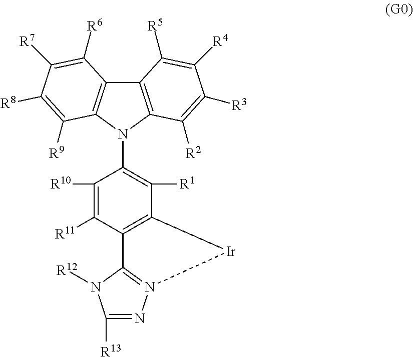

In General Formula (G0), R¹ to R¹³ each independently represent any one of hydrogen, an alkyl group having 1 to 6 carbon atoms, a cycloalkyl group having 5 to 7 carbon atoms, and an aryl group having 6 to 12 carbon atoms.

The organometallic complex of one embodiment of the present invention is preferably a tris-type organometallic complex in which three ligands are coordinated to iridium because an excellent thermophysical property and excellent chemical stability can be achieved. Such an organometallic complex can be represented by General Formula (G1) below.

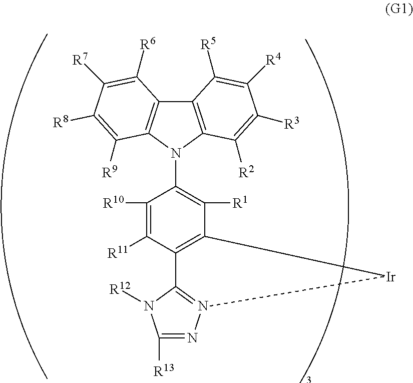

In General Formula (G1), R¹ to R¹³ each independently represent any one of hydrogen, an alkyl group having 1 to 6 carbon atoms, a cycloalkyl group having 5 to 7 carbon atoms, and an aryl group having 6 to 12 carbon atoms.

It is preferable that R¹² represent a phenyl group because an excellent thermophysical property and excellent chemical stability can be achieved. Such an organometallic complex can be represented by General Formula (G2) below.

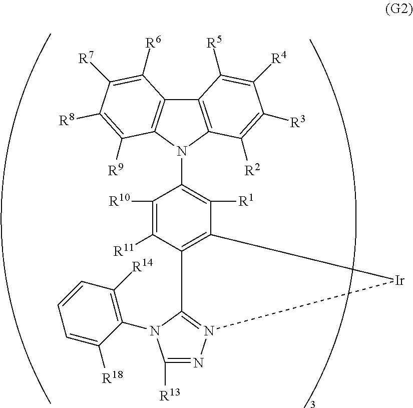

In General Formula (G2), R¹ to R¹¹ and R¹³ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

In such an organometallic complex, R¹³ preferably represents a methyl group or a phenyl group because an excellent thermophysical property and excellent chemical stability can be achieved. R¹³ preferably represents a phenyl group because the polarity of such an organometallic complex, which is relatively high, can be lowered, making it easier to increase the purity in a purification step of the synthesis. Such an organometallic complex can be represented by General Formula (G3) or (G4) below.

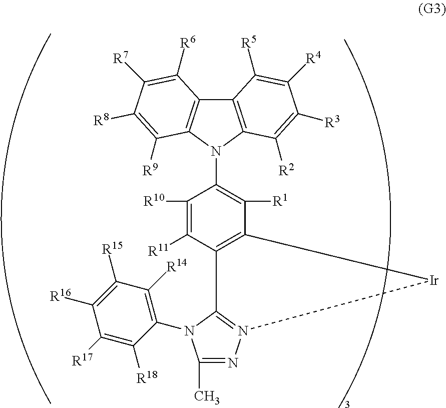

In General Formula (G3), R¹ to R¹¹ and R¹⁴ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

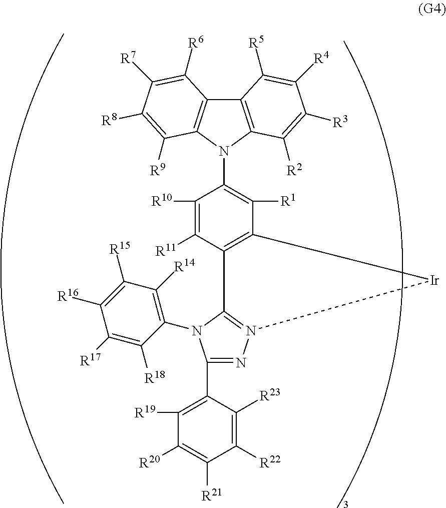

In General Formula (G4), R¹ to R¹¹, R¹⁴ to R¹⁸, and R¹⁹ to R²³ each independently represent any one of hydrogen, an alkyl group having 1 to 6 carbon atoms, a cycloalkyl group having 5 to 7 carbon atoms, and an aryl group having 6 to 12 carbon atoms.

Among the organometallic complexes of embodiments of the present invention, the organometallic complexes represented by General Formulae (G5), (G6), and (G7) are particularly preferable.

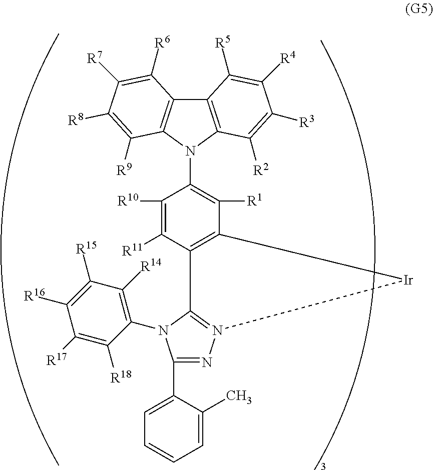

In General Formula (G5), R¹ to R¹¹ and R¹⁴ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

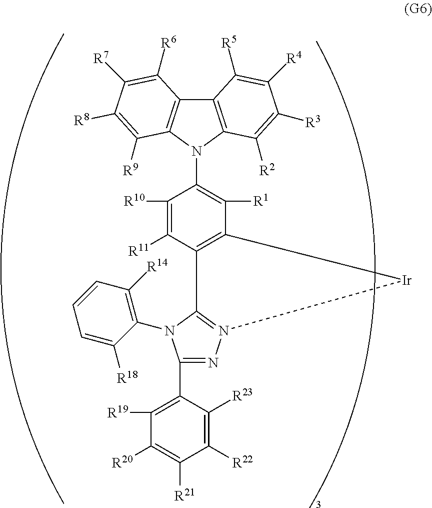

In General Formula (G6), R¹ to R¹¹, R¹⁴, R¹⁸, and R¹⁹ to R²³ each independently represent any one of hydrogen, an alkyl group having 1 to 6 carbon atoms, a cycloalkyl group having 5 to 7 carbon atoms, and an aryl group having 6 to 12 carbon atoms.

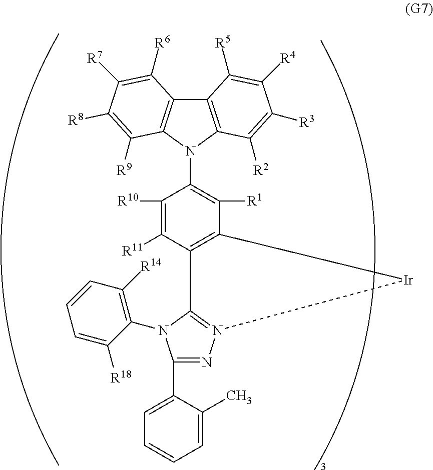

In General Formula (G7), R¹ to R¹¹, R¹⁴, and R¹⁸ each independently represent any one of hydrogen, an alkyl group having 1 to 6 carbon atoms, a cycloalkyl group having 5 to 7 carbon atoms, and an aryl group having 6 to 12 carbon atoms.

Some specific examples of the organometallic complexes of embodiments of the present invention with the above-described structures are shown below.

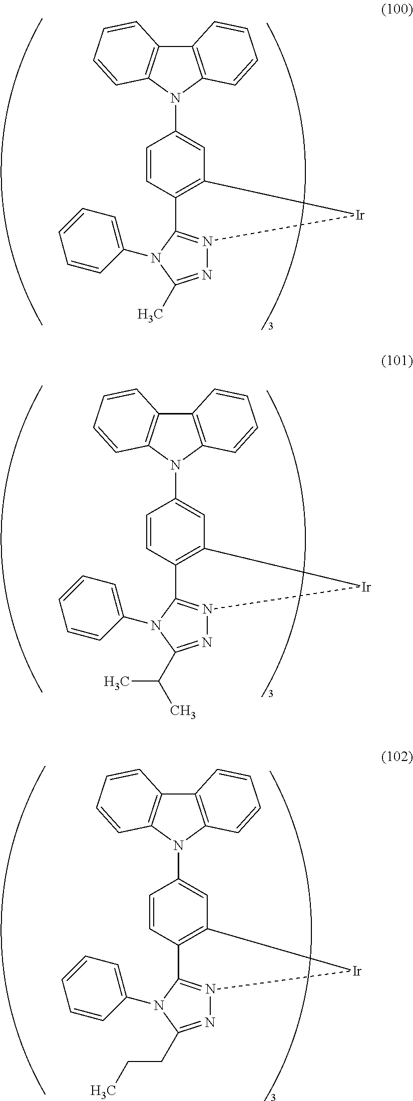

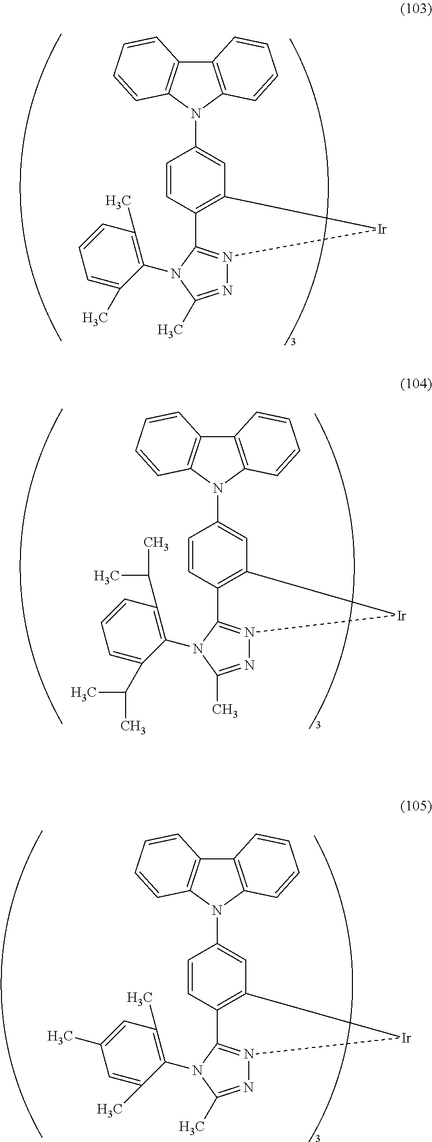

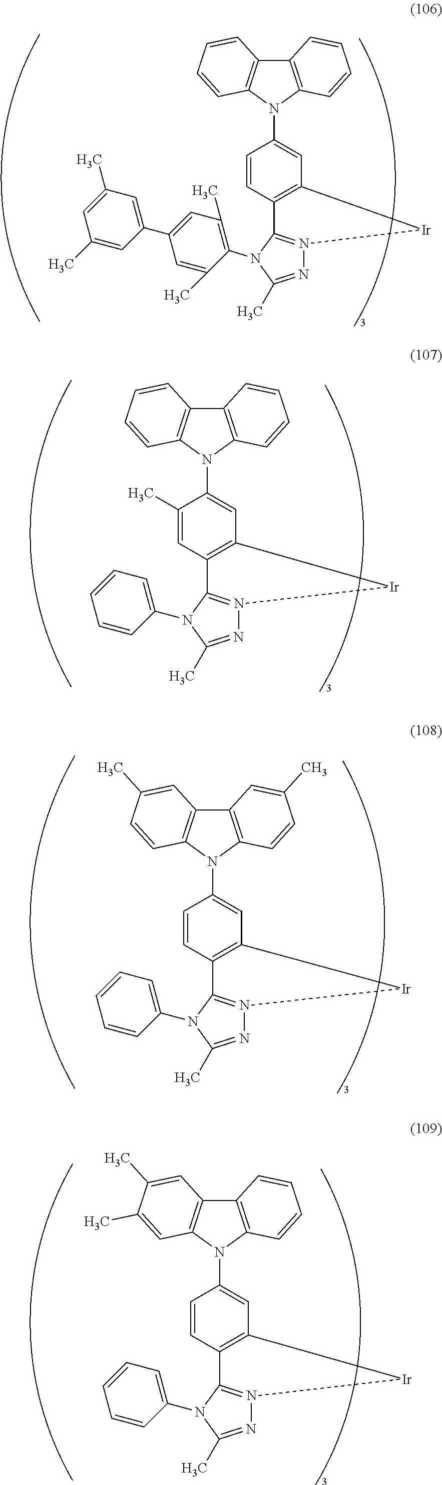

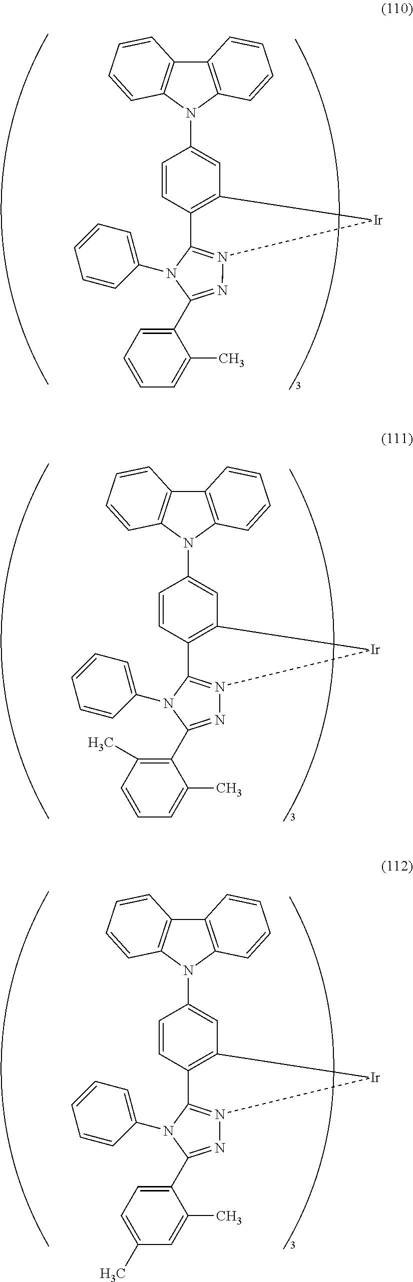

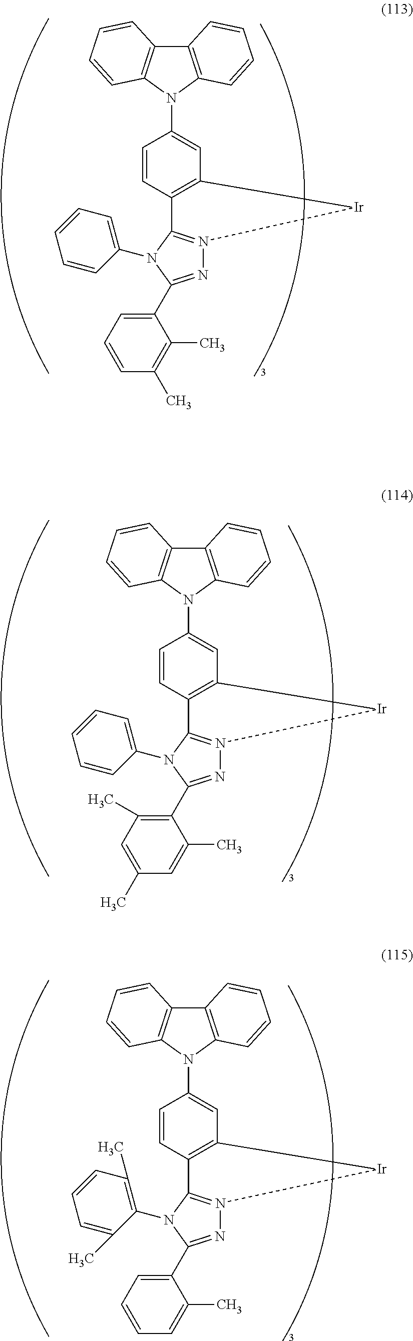

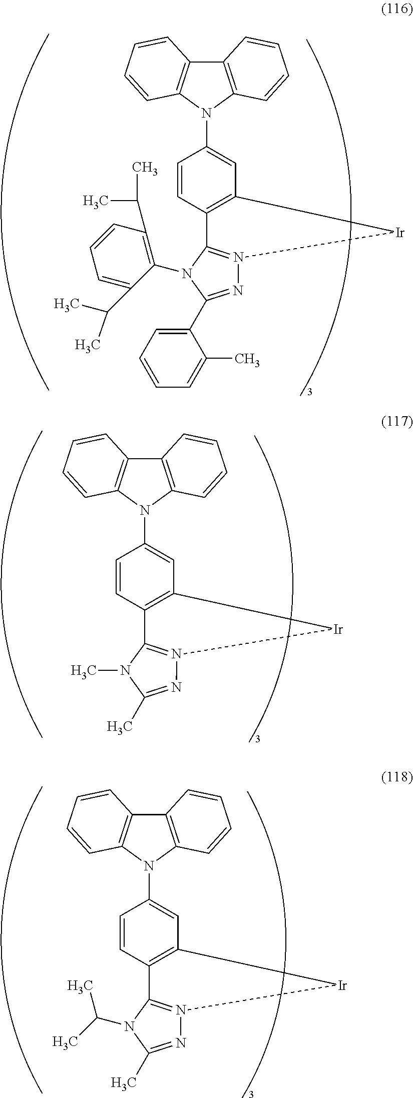

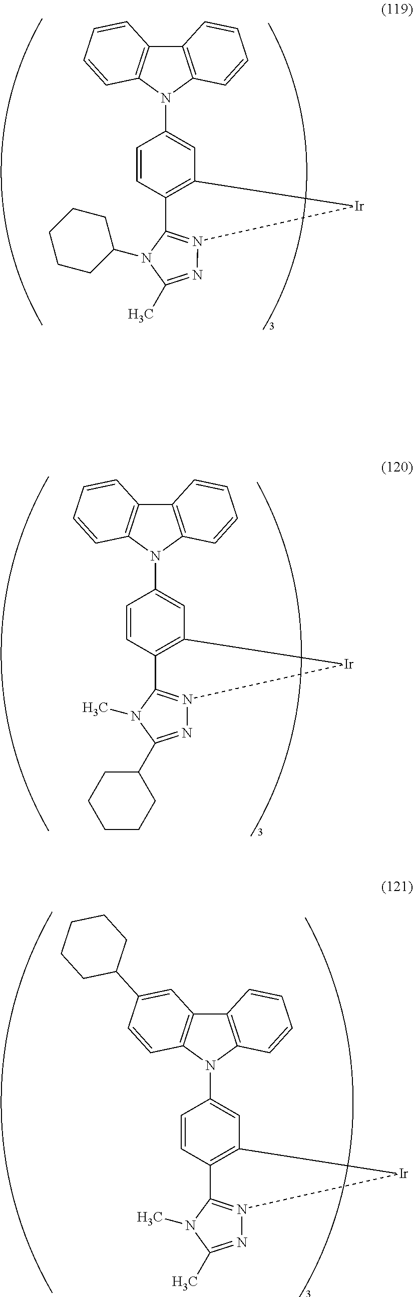

A variety of reactions can be employed as a method for synthesizing the organometallic complex of one embodiment of the present invention described above.

### Synthesis Method of 1,2,4-Triazole Derivative Represented by General Formula (g0)

First, an example of a method for synthesizing a 1,2,4-triazole derivative represented by General Formula (g0) below is described.

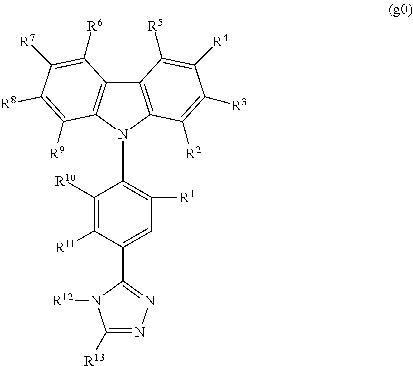

As illustrated in Scheme (a) below, a hydrazide compound (A1) is reacted with a thioether compound having R¹² and R¹³ or an N-substituted thioamide compound having R¹² and R¹³ (A2), whereby the 1,2,4-triazole derivative can be obtained.

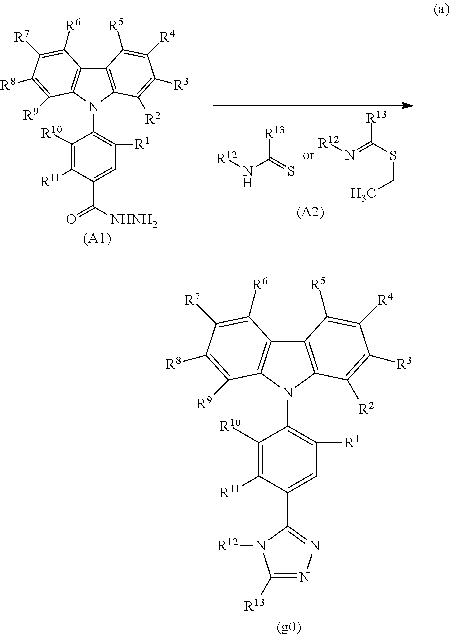

Note that the method for synthesizing the 1,2,4-triazole derivative is not limited to Scheme (a). In another example of the synthesis method, a thioether compound having R¹³ or an N-substituted thioamide compound having R¹³ is reacted with a hydrazide compound having R¹². As shown in Scheme (a′) below, there is also a method in which a dihydrazide compound (A1′) is reacted with a primary amine compound (A2′). Alternatively, as illustrated in Scheme (a″) below, a halide of a 1,2,4-triazole derivative (A1″) may be reacted with a carbazole derivative (A2″). In Scheme (a″), X represents a halogen.

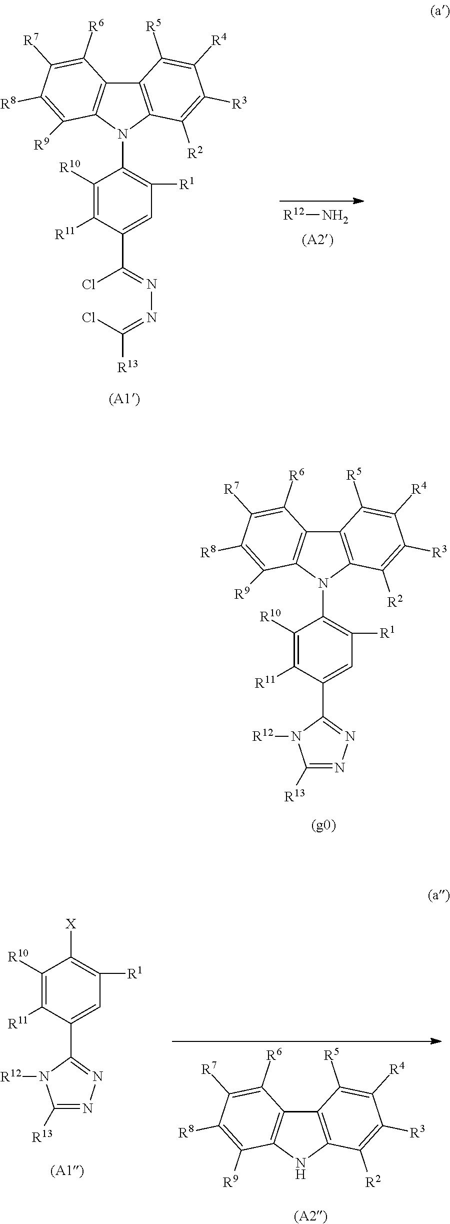

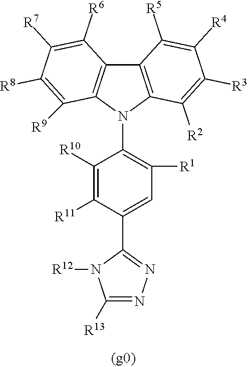

In the above manner, the 1,2,4-triazole derivative can be synthesized under a very simple synthesis scheme.

### Synthesis Method of Organometallic Complex Represented by General Formula (G1)

As illustrated in Synthesis Scheme (b) below, an organometallic complex having the structure represented by General Formula (G1) can be obtained when the 1,2,4-triazole derivative represented by General Formula (g0) is mixed with an iridium metal compound containing a halogen (e.g., iridium chloride hydrate or ammonium hexachloroiridate) or an iridium organometallic complex compound (e.g., an acetylacetonato complex or a diethylsulfide complex) and then the mixture is heated. This heating process may be performed after the 1,2,4-triazole derivative represented by General Formula (g0) and the iridium metal compound containing a halogen or the iridium organometallic complex compound are dissolved in an alcohol-based solvent (e.g., glycerol, ethylene glycol, 2-methoxyethanol, or 2-ethoxyethanol).

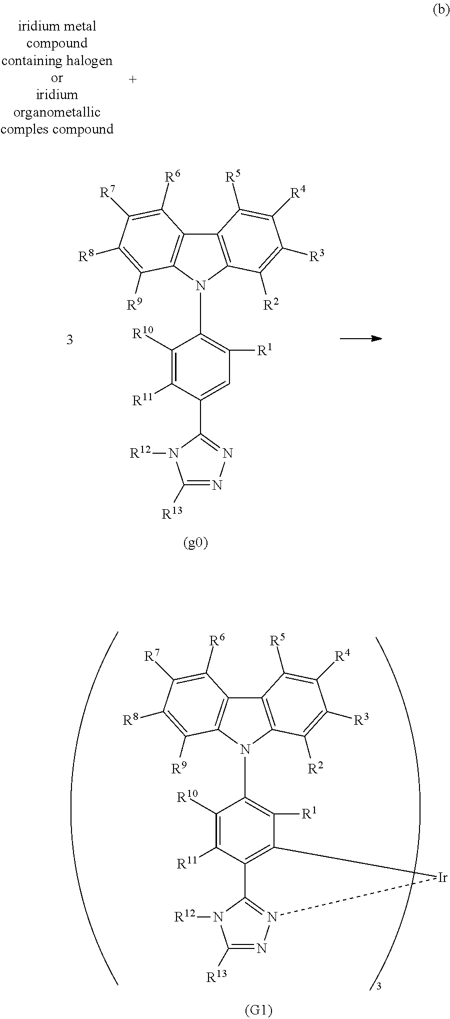

In one embodiment of the present invention, to obtain an orthometalated complex in which a 1,2,4-triazole derivative is a ligand as described above, the 1,2,4-triazole preferably has a substituent at the 5-position (i.e., R¹³). It is particularly preferable that R¹³ be an alkyl group having 1 to 6 carbon atoms, a cycloalkyl group having 5 to 7 carbon atoms, or an aryl group having 6 to 12 carbon atoms because the yield under Synthesis Scheme (b) can be increased.

In this specification, specific examples of an alkyl group having 1 to 6 carbon atoms include a methyl group, an ethyl group, a propyl group, an isopropyl group, an n-butyl group, a sec-butyl group, an isobutyl group, a tert-butyl group, an n-pentyl group, a 1-methylbutyl group, a 2-methylbutyl group, a 3-methylbutyl group, a 1-ethylpropyl group, a 1,1-dimethylpropyl group, a 1,2-dimethylpropyl group, a 2,2-dimethylpropyl group, and a branched or non-branched hexyl group. Specific examples of a cycloalkyl group having 5 to 7 carbon atoms include a cyclopentyl group, a cyclohexyl group, a 1-methylcyclohexyl group, a 2,6-dimethylcyclohexyl group, and a cycloheptyl group. Examples of an aryl group having 6 to 12 carbon atoms include a phenyl group, a naphthyl group, a biphenyl group, a phenyl group to which one or more methyl groups are bonded, a phenyl group to which one or more ethyl groups are bonded, a phenyl group to which one or more isopropyl groups are bonded, and a phenyl group to which a tert-butyl group is bonded. Note that the above cycloalkyl group and aryl group may have a substituent, an example of which is an alkyl group having 1 to 4 carbon atoms. Specific examples include a methyl group, an ethyl group, a propyl group, an isopropyl group, an n-butyl group, a sec-butyl group, an isobutyl group, and a tert-butyl group.

### Light-Emitting Element

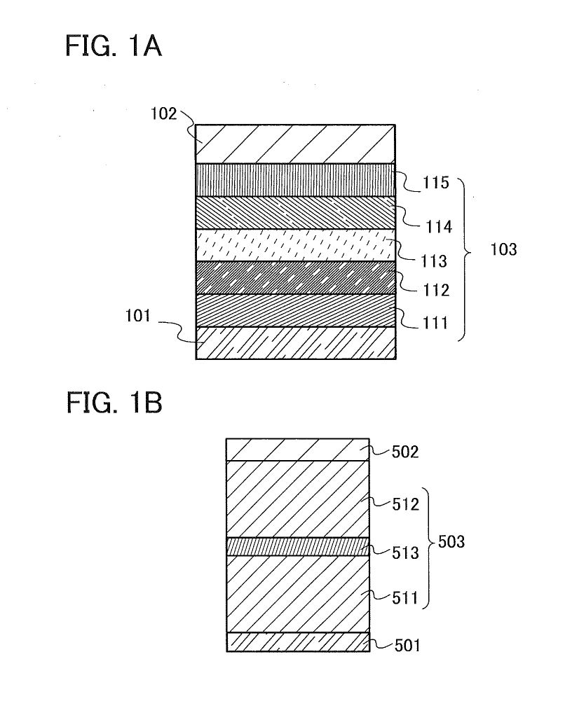

Next, an example of a light-emitting element which is one embodiment of the present invention is described in detail below with reference to FIG. 1A.

In this embodiment, the light-emitting element includes a pair of electrodes (a first electrode 101 and a second electrode 102), and an EL layer 103 provided between the first electrode 101 and the second electrode 102. Note that the first electrode 101 functions as an anode and that the second electrode 102 functions as a cathode.

To function as an anode, the first electrode 101 is preferably formed using any of metals, alloys, conductive compounds having a high work function (specifically, a work function of 4.0 eV or more), mixtures thereof, and the like. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by application of a sol-gel method or the like. In an example of the formation method, indium oxide-zinc oxide is deposited by a sputtering method using a target obtained by adding 1 wt % to 20 wt % of zinc oxide to indium oxide. Further, a film of indium oxide containing tungsten oxide and zinc oxide (IWZO) can be formed by a sputtering method using a target in which tungsten oxide and zinc oxide are added to indium oxide at 0.5 wt % to 5 wt % and 0.1 wt % to 1 wt %, respectively. Another examples are gold (Au), platinum (Pt), nickel (Ni), tungsten (W), chromium (Cr), molybdenum (Mo), iron (Fe), cobalt (Co), copper (Cu), palladium (Pd), nitrides of metal materials (e.g., titanium nitride), and the like. Graphene can also be used. Note that when a composite material described later is used for a layer which is in contact with the first electrode 101 in the EL layer 103, an electrode material can be selected regardless of its work function.

It is preferable that the EL layer 103 have a stacked-layer structure and any of the layers of the stacked-layer structure contain the organometallic complex of one embodiment of the present invention. The organometallic complex is preferably the organometallic complex represented by any one of General Formulae (G0) to (G7) above.

The stacked-layer structure of the EL layer 103 can be formed by combining a hole-injection layer, a hole-transport layer, a light-emitting layer, an electron-transport layer, an electron-injection layer, a carrier-blocking layer, an intermediate layer, and the like as appropriate. In this embodiment, the EL layer 103 has a structure in which a hole-injection layer 111, a hole-transport layer 112, a light-emitting layer 113, an electron-transport layer 114, and an electron-injection layer 115 are stacked in this order over the first electrode 101. Specific examples of the materials forming the layers are given below.

The hole-injection layer 111 is a layer that contains a substance having a high hole-injection property. Molybdenum oxide, vanadium oxide, ruthenium oxide, tungsten oxide, manganese oxide, or the like can be used. Alternatively, the hole-injection layer 111 can be formed using a phthalocyanine-based compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or N,N′-bis{4-[bis(3-methylphenyl)amino]phenyl}-N,N′-diphenyl-(1,1′-biphenyl)-4,4′-diamine (abbreviation: DNTPD), a high molecular compound such as poly(3,4-ethylenedioxythiophene)/poly(styrenesulfonic acid) (PEDOT/PSS), or the like.

Alternatively, a composite material in which a substance having a hole-transport property contains a substance having an acceptor property can be used for the hole-injection layer 111. Note that the use of such a substance having a hole-transport property which contains a substance having an acceptor property enables selection of a material used to form an electrode regardless of its work function. In other words, besides a material having a high work function, a material having a low work function can be used for the first electrode 101. As examples of the substance having an acceptor property, 7,7,8,8-tetracyano-2,3,5,6-tetrafluoroquinodimethane (abbreviation: F₄-TCNQ), chloranil, and the like can be given. In addition, transition metal oxides can be given. Moreover, oxides of metals belonging to Groups 4 to 8 of the periodic table can be given. Specifically, it is preferable to use vanadium oxide, niobium oxide, tantalum oxide, chromium oxide, molybdenum oxide, tungsten oxide, manganese oxide, and rhenium oxide because of their high electron accepting properties. In particular, molybdenum oxide is more preferable because of its stability in the atmosphere, low hygroscopic property, and easiness of handling.

As the substance having a hole-transport property which is used for the composite material, any of a variety of organic compounds such as aromatic amine compounds, carbazole derivatives, aromatic hydrocarbons, and high molecular compounds (e.g., oligomers, dendrimers, or polymers) can be used. Note that the substance having a hole-transport property which is used for the composite material is preferably a substance having a hole mobility of 10⁻⁶ cm²/Vs or more is preferably used. Organic compounds that can be used as the substance having a hole-transport property in the composite material are specifically given below.

Examples of the aromatic amine compounds that can be used for the composite material are N,N-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis {4-[bis(3-methylphenyl)amino]phenyl}-N,N′-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), and the like. Specific examples of the carbazole derivatives are 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), 1,4-bis[4-(N-carbazolyl)phenyl]-2,3,5,6-tetraphenylbenzene, and the like. Examples of the aromatic hydrocarbons are 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, and the like. Besides, pentacene, coronene, or the like can also be used. The aromatic hydrocarbons may have a vinyl skeleton. Examples of the aromatic hydrocarbon having a vinyl skeleton are 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

A high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: poly-TPD) can also be used.

By providing the hole-injection layer 111, a high hole-injection property can be achieved to allow a light-emitting element to be driven at a low voltage.

The hole-transport layer 112 is a layer that contains a substance having a hole-transport property. Examples of the substance having a hole-transport property are aromatic amine compounds such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′,4″-tris(N,N′-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), and the like. The substances mentioned here have high hole-transport properties and are mainly ones that have a hole mobility of 10⁻⁶ cm²/Vs or more. An organic compound given as an example of the substance having a hole-transport property in the composite material described above can also be used for the hole-transport layer 112. A high molecular compound such as poly(N-vinylcarbazole) (abbreviation: PVK) or poly(4-vinyltriphenylamine) (abbreviation: PVTPA) can also be used. Note that the layer that contains a substance having a hole-transport property is not limited to a single layer, and may be a stack of two or more layers including any of the above substances.

The light-emitting layer 113 may be a layer that emits fluorescence, a layer that emits phosphorescence, or a layer emitting thermally activated delayed fluorescence (TADF). Furthermore, the light-emitting layer 113 may be a single layer or include a plurality of layers containing different light-emitting substances. In the case where the light-emitting layer including a plurality of layers is formed, a layer containing a phosphorescent substance and a layer containing a fluorescent substance may be stacked. In that case, an exciplex described later is preferably utilized for the layer containing the phosphorescent substance.

As the fluorescent substance, any of the following substances can be used, for example. Fluorescent substances other than those given below can also be used. Examples of the fluorescent substance are 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-bis[4-(9-phenyl-9H-fluoren-9-yl)phenyl]-N,N-diphenylpyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM), and the like. Condensed aromatic diamine compounds typified by pyrenediamine compounds such as 1,6FLPAPm and 1,6mMemFLPAPrn are preferable because of their high hole-trapping properties, high emission efficiency, and high reliability.

Examples of a material which can be used as a phosphorescent substance in the light-emitting layer 113 are as follows. The examples include organometallic iridium complexes having 4H-triazole skeletons, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), and tris[4-(3-biphenyl)-5-isopropyl-3-phenyl-4H-1,2,4-triazolato]iridium(III) (abbreviation: [Ir(iPrptz-3b)₃]); organometallic iridium complexes having 1H-triazole skeletons, such as tris[3-methyl-1-(2-methylphenyl)-5-phenyl-1H-1,2,4-triazolato]iridium(III) (abbreviation: [Ir(Mptzl-mp)₃]) and tris(1-methyl-5-phenyl-3-propyl-1H-1,2,4-triazolato)iridium(III) (abbreviation: [Ir(Prptzl-Me)₃]); organometallic iridium complexes having imidazole skeletons, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-j]phenanthridinato]iridium(III) (abbreviation: [Ir(dmpimpt-Me)₃]); and organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis {2-[3′,5′-bis(trifluoromethyl)phenyl]pyridinato-N,C²′}iridium(III) picolinate (abbreviation: [Ir(CF₃ppy)₂(pic)]), and bis[2-(4′,6′-difluorophenyl)pyridinato-N,C²′]iridium(III) acetylacetonate (abbreviation: FIr(acac)). These are compounds emitting blue phosphorescence and have an emission peak at 440 nm to 520 nm.

Other examples include organometallic iridium complexes having pyrimidine skeletons, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having pyrazine skeletons, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having pyridine skeletons, such as tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), and bis(2-phenylquinolinato-N,C²′)iridium(III) acetylacetonate (abbreviation: [Ir(pq)₂(acac)]); and rare earth metal complexes such as tris(acetylacetonato)(monophenanthroline)terbium(III) (abbreviation: [Tb(acac)₃(Phen)]). These are mainly compounds emitting green phosphorescence and have an emission peak at 500 nm to 600 nm. Note that organometallic iridium complexes having pyrimidine skeletons have distinctively high reliability and emission efficiency and thus are especially preferable.

Other examples include organometallic iridium complexes having pyrimidine skeletons, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(dlnpm)₂(dpm)]); organometallic iridium complexes having pyrazine skeletons, such as (acetylacetonato)bis(2,3,5-triphenylpyrazinato)iridium(III) (abbreviation: [Ir(tppr)₂(acac)]), bis(2,3,5-triphenylpyrazinato)(dipivaloyhnethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having pyridine skeletons, such as tris(1-phenylisoquinolinato-N,C²′) iridium(III) (abbreviation: [Ir(piq)₃]) and bis(1-phenylisoquinolinato-N,C²′)iridium(III) acetylacetonate (abbreviation: [Ir(piq)₂(acac)]); platinum complexes such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These are compounds emitting red phosphorescence and have an emission peak at 600 nm to 700 nm. Further, organometallic iridium complexes having pyrazine skeletons can provide red light emission with favorable chromaticity.

As well as the above phosphorescent compounds, a variety of phosphorescent substances may be selected and used.

Note that the organometallic complex of one embodiment of the present invention is preferably used as the phosphorescent substance. The organometallic complex of one embodiment of the present invention emits light efficiently, resulting in high emission efficiency of a light-emitting element. The organometallic complex of one embodiment of the present invention has deeper HOMO than other organometallic complexes having a ligand with a 1,2,4-triazole skeleton and has an appropriate hole-trapping property. A light-emitting element including the organometallic complex as a phosphorescent substance can have low drive voltage. Accordingly, a light-emitting device including the light-emitting element can have low power consumption.

Materials that can be used as a TADF material (a material emitting TADF) are given below.

As a material exhibiting TADF, materials given below can be used. A fullerene, a derivative thereof, an acridine derivative such as proflavine, and eosin can be given. Further, a metal-containing porphyrin, such as a porphyrin containing magnesium (Mg), zinc (Zn), cadmium (Cd), tin (Sn), platinum (Pt), indium (In), or palladium (Pd) can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂(OEP)), which are shown in the following structural formulae.

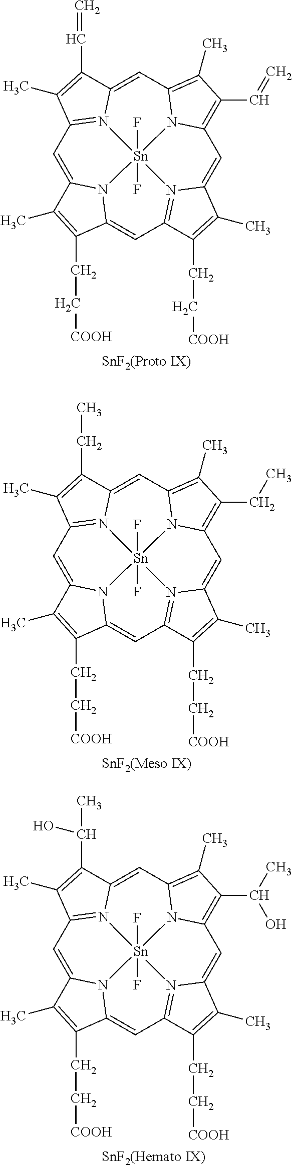

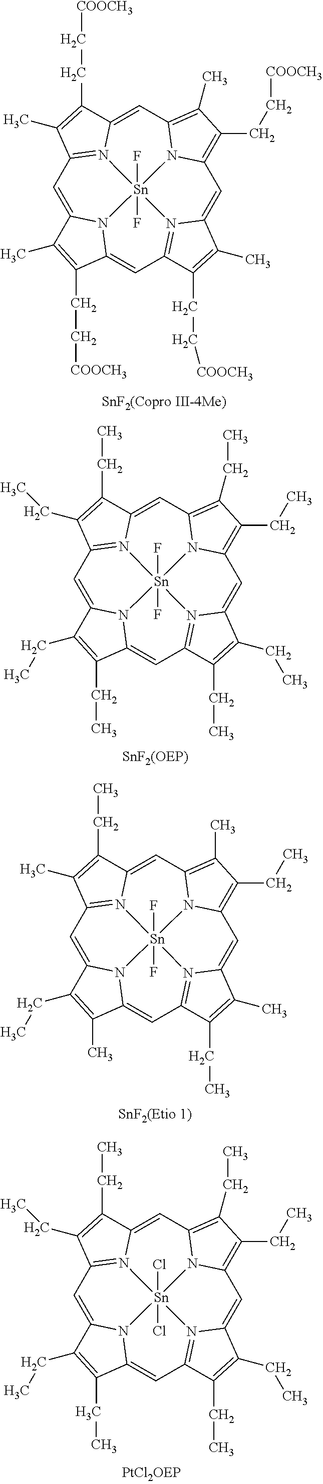

Alternatively, a heterocyclic compound having a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ) shown in the following structural formula, can be used. The heterocyclic compound is preferably used because of the π-electron rich heteroaromatic ring and the π-electron deficient heteroaromatic ring, for which the electron-transport property and the hole-transport property are high. Note that a substance in which the π-electron rich heteroaromatic ring is directly bonded to the π-electron deficient heteroaromatic ring is particularly preferably used because the donor property of the π-electron rich heteroaromatic ring and the acceptor property of the π-electron deficient heteroaromatic ring are both high and the energy difference between the S₁ level and the T₁ level becomes small.

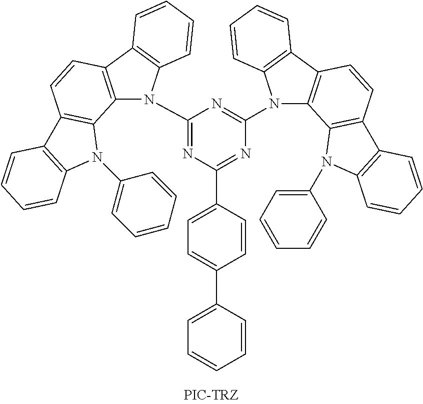 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1]

In the case of using a fluorescent substance, materials that can be suitably used as the host material in the light-emitting layer are materials having an anthracene skeleton such as 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), and 9-phenyl-10-{4-(9-phenyl-9H-fluoren-9-yl)biphenyl-4′-yl}anthracene (abbreviation: FLPPA). The use of a substance having an anthracene skeleton as the host material for the fluorescent substance makes it possible to obtain a light-emitting layer with high emission efficiency and high durability. In particular, CzPA, cgDBCzPA, 2mBnfPPA, and PCzPA are preferable because of their excellent characteristics.

In the case where a material other than the above-mentioned materials is used as a host material, various carrier-transport materials, such as a material having an electron-transport property or a material having a hole-transport property, can be used.

Examples of the material having an electron-transport property are a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); a heterocyclic compound having a polyazole skeleton such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); a heterocyclic compound having a diazine skeleton such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); and a heterocyclic compound having a pyridine skeleton such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB). Among the above materials, a heterocyclic compound having a diazine skeleton and a heterocyclic compound having a pyridine skeleton have high reliability and are thus preferable. Specifically, a heterocyclic compound having a diazine (pyrimidine or pyrazine) skeleton has a high electron-transport property to contribute to a reduction in drive voltage.

Examples of the material having a hole-transport property include a compound having an aromatic amine skeleton such as 4,4′-bis[N-(1-naphthyl)-N-phenylamino]biphenyl (abbreviation: NPB), N,N′-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, a compound having an aromatic amine skeleton and a compound having a carbazole skeleton are preferable because these compounds are highly reliable and have high hole-transport properties to contribute to a reduction in drive voltage. Hole-transport materials can be selected from a variety of substances as well as from the hole-transport materials given above.

Note that the host material may be a mixture of a plurality of kinds of substances, and in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The ratio of the content of the material having a hole-transport property to the content of the material having an electron-transport property may be 1:9 to 9:1.

These mixed host materials may form an exciplex. When a combination of these materials is selected so as to form an exciplex that exhibits light emission whose wavelength overlaps the wavelength of a lowest-energy-side absorption band of the fluorescent substance, the phosphorescent substance, or the TADF material, energy is transferred smoothly and light emission can be obtained efficiently. Such a structure is preferable in that drive voltage can be reduced.

The light-emitting layer 113 having the above-described structure can be formed by co-evaporation by a vacuum evaporation method, or an inkjet method, a spin coating method, a dip coating method, or the like using a solution of the materials.

The electron-transport layer 114 contains a substance having an electron-transport property. For the electron-transport layer 114, the materials having an electron-transport property or having an anthracene skeleton, which are described above as materials for the host material, can be used.

Between the electron-transport layer and the light-emitting layer, a layer that controls transport of electron carriers may be provided. This is a layer formed by addition of a small amount of a substance having a high electron-trapping property to the aforementioned material having a high electron-transport property, and the layer is capable of adjusting carrier balance by retarding transport of electron carriers. Such a structure is very effective in preventing a problem (such as a reduction in element lifetime) caused when electrons pass through the light-emitting layer.

In addition, the electron-injection layer 115 may be provided in contact with the second electrode 102 between the electron-transport layer 114 and the second electrode 102. For the electron-injection layer 115, an alkali metal, an alkaline earth metal, or a compound thereof, such as lithium fluoride (LiF), cesium fluoride (CsF), or calcium fluoride (CaF₂), can be used. For example, a layer that is formed using a substance having an electron-transport property and contains an alkali metal, an alkaline earth metal, or a compound thereof can be used. In addition, an electride may be used for the electron-injection layer 115. Examples of the electride include a substance in which electrons are added at high concentration to calcium oxide-aluminum oxide. Note that a layer that is formed using a substance having an electron-transport property and contains an alkali metal or an alkaline earth metal is preferably used as the electron-injection layer 115, in which case electron injection from the second electrode 102 is efficiently performed.

For the second electrode 102, any of metals, alloys, electrically conductive compounds, and mixtures thereof which have a low work function (specifically, a work function of 3.8 eV or less) or the like can be used. Specific examples of such a cathode material are elements belonging to Groups 1 and 2 of the periodic table, such as alkali metals (e.g., lithium (Li) and cesium (Cs)), magnesium (Mg), calcium (Ca), and strontium (Sr), alloys thereof (e.g., MgAg and AlLi), rare earth metals such as europium (Eu) and ytterbium (Yb), alloys thereof, and the like. However, when the electron-injection layer is provided between the second electrode 102 and the electron-transport layer 114, for the second electrode 102, any of a variety of conductive materials such as Al, Ag, ITO, or indium oxide-tin oxide containing silicon or silicon oxide can be used regardless of the work function. Films of these conductive materials can be formed by a sputtering method, an inkjet method, a spin coating method, or the like.

Any of a variety of methods can be used to form the EL layer 103 regardless whether it is a dry process or a wet process. For example, a vacuum evaporation method, an inkjet method, a spin coating method, or the like may be used. Different formation methods may be used for the electrodes or the layers.

In addition, the electrode may be formed by a wet method using a sol-gel method, or by a wet method using paste of a metal material. Alternatively, the electrode may be formed by a dry method such as a sputtering method or a vacuum evaporation method.

Light emission from the light-emitting element is extracted out through one or both of the first electrode 101 and the second electrode 102. Therefore, one or both of the first electrode 101 and the second electrode 102 is formed as a light-transmitting electrode.

Next, a mode of a light-emitting element with a structure in which a plurality of light-emitting units are stacked (hereinafter this type of light-emitting element is also referred to as a stacked element) is described with reference to FIG. 1B. This light-emitting element includes a plurality of light-emitting units between a pair of electrodes (a first electrode and a second electrode). One light-emitting unit has the same structure as the EL layer 103 illustrated in FIG. 1A. In other words, the light-emitting element illustrated in FIG. 1A includes a single light-emitting unit, and the light-emitting element illustrated in FIG. 1B includes a plurality of light-emitting units.

In FIG. 1B, an EL layer 503 including a stack of a first light-emitting unit 511, a charge-generation layer 513, and a second light-emitting unit 512 is provided between a first electrode 501 and a second electrode 502. The first electrode 501 and the second electrode 502 correspond, respectively, to the first electrode 101 and the second electrode 102 illustrated in FIG. 1A, and can be formed using the materials given in the description for FIG. 1A. Furthermore, the first light-emitting unit 511 and the second light-emitting unit 512 may have the same structure or different structures.

The charge-generation layer 513 preferably contains a composite material of an organic compound and a metal oxide. As this composite material of an organic compound and a metal oxide, the composite material that can be used for the hole-injection layer 111 illustrated in FIG. 1A can be used. Since the composite material of an organic compound and a metal oxide is superior in carrier-injection property and carrier-transport property, low-voltage driving or low-current driving can be realized. Note that when a surface of a light-emitting unit on the anode side is in contact with the charge-generation layer, the charge-generation layer can also serve as a hole-injection layer of the light-emitting unit; thus, a hole-injection layer does not need to be formed in the light-emitting unit.

Note that the charge-generation layer 513 may be formed by stacking a layer containing the above composite material and a layer containing another material. For example, a layer containing the above composite material and a layer containing a compound with a high electron-transport property and a compound selected from the substances with an electron donating property may be stacked. Alternatively, a layer containing a composite material of an organic compound and a metal oxide and a transparent conductive film may be stacked.

An electron-injection buffer layer may be provided between the charge-generation layer 513 and the light-emitting unit on the anode side of the charge-generation layer. The electron-injection buffer layer is a stack of a very thin alkali metal layer and an electron-relay layer containing a substance with an electron-transport property. The very thin alkali metal layer corresponds to the electron-injection layer 115 and has a function of lowering an electron injection barrier. The electron-relay layer has a function of preventing an interaction between the alkali metal layer and the charge-generation layer 513 and smoothly transferring electrons.

The substance with an electron-transport property which is contained in the electron-relay layer is selected such that the LUMO of the substance is between the LUMO of an substance having an acceptor property in the charge-generation layer 513 and the LUMO of a substance contained in a layer in contact with the electron-injection buffer layer in the light-emitting unit on the anode side. As a specific value of the energy level, the LUMO of the substance having an electron-transport property which is contained in the electron-relay layer is preferably greater than or equal to −5.0 eV, more preferably greater than or equal to −5.0 eV and less than or equal to −3.0 eV. Note that as the substance having an electron-transport property which is contained in the electron-relay layer, a metal complex having a metal-oxygen bond and an aromatic ligand or a phthalocyanine-based material is preferably used. In the case where the electron-injection buffer layer is provided, the very thin alkali metal layer of the electron-injection buffer layer serves as the electron-injection layer in the light-emitting unit on the anode side; thus, the electron-injection layer does not need to be formed over the light-emitting unit.

The charge-generation layer 513 provided between the first light-emitting unit 511 and the second light-emitting unit 512 may have any structure as long as electrons can be injected to a light-emitting unit on one side and holes can be injected to a light-emitting unit on the other side when a voltage is applied between the first electrode 501 and the second electrode 502. For example, in FIG. 1B, any layer can be used as the charge-generation layer 513 as long as the layer injects electrons into the first light-emitting unit 511 and holes into the second light-emitting unit 512 when a voltage is applied such that the potential of the first electrode is higher than that of the second electrode.

The light-emitting element having two light-emitting units is described with reference to FIG. 1B; however, the present invention can be similarly applied to a light-emitting element in which three or more light-emitting units are stacked. With a plurality of light-emitting units partitioned by the charge-generation layer between a pair of electrodes, it is possible to provide an element which can emit light with high luminance with the current density kept low and has a long lifetime. A light-emitting device that can be driven at a low voltage and has low power consumption can be realized.

Furthermore, when emission colors of the light-emitting units are made different, light emission having a desired color tone can be obtained from the light-emitting element as a whole. For example, it is easy to enable a light-emitting element having two light-emitting units to emit white light as the whole element when the emission colors of the first light-emitting unit are red and green and the emission color of the second light-emitting unit is blue.

### Micro Optical Resonator (Microcavity) Structure

A light-emitting element with a microcavity structure is formed with the use of a reflective electrode and a semi-transmissive and semi-reflective electrode as the pair of electrodes. The reflective electrode and the semi-transmissive and semi-reflective electrode correspond to the first electrode and the second electrode described above. The light-emitting element with a microcavity structure includes at least an EL layer between the reflective electrode and the semi-transmissive and semi-reflective electrode. The EL layer includes at least a light-emitting layer serving as a light-emitting region.

Light emitted from the light-emitting layer included in the EL layer is reflected and resonated by the reflective electrode and the semi-transmissive and semi-reflective electrode. Note that the reflective electrode is formed using a conductive material having reflectivity and has a visible light reflectivity of 40% to 100%, preferably 70% to 100% and a resistivity of 1×10⁻² Ωcm or lower. In addition, the semi-transmissive and semi-reflective electrode is formed using a conductive material having reflectivity and a light-transmitting property and has a visible light reflectivity of 20% to 80%, preferably 40% to 70%, and a resistivity of 1×10⁻² Ωcm or lower.

In the light-emitting element, by changing thicknesses of the transparent conductive film, the composite material, the carrier-transport material, and the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is emitted from the light-emitting layer and reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of color to be amplified). In that case, the phases of the first reflected light and the first incident light can be aligned with each other and the light emitted from the light-emitting layer can be further amplified.

Note that in the above structure, the EL layer may be formed of light-emitting layers or may be a single light-emitting layer. The tandem light-emitting element described above may be combined with the EL layers; for example, a light-emitting element may have a structure in which a plurality of EL layers is provided, a charge-generation layer is provided between the EL layers, and each EL layer is formed of light-emitting layers or a single light-emitting layer.

### Light-Emitting Device

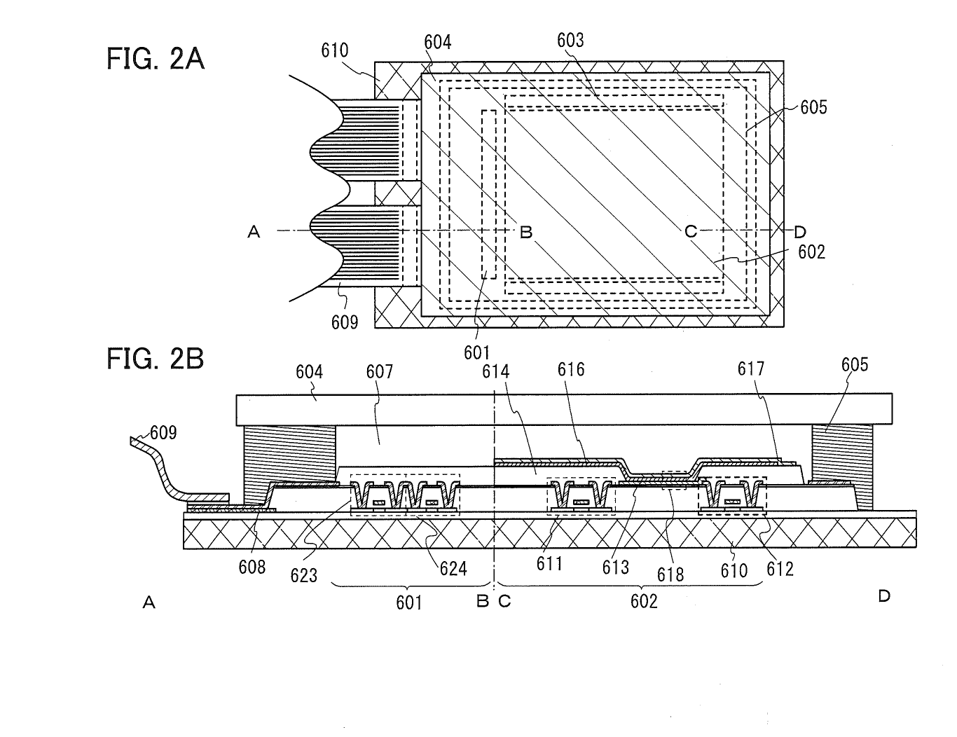

A light-emitting device of one embodiment of the present invention is described using FIGS. 2A and 2B. Note that FIG. 2A is a top view illustrating the light-emitting device and FIG. 2B is a cross-sectional view of FIG. 2A taken along lines A-B and C-D. This light-emitting device includes a driver circuit portion (source line driver circuit) 601, a pixel portion 602, and a driver circuit portion (gate line driver circuit) 603, which can control light emission of a light-emitting element and illustrated with dotted lines. A reference numeral 604 denotes a sealing substrate; 605, a sealing material; and a portion surrounded by the sealing material 605 is a space 607.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting device in the present specification includes, in its category, not only the light-emitting device itself but also the light-emitting device provided with the FPC or the PWB.

Next, a cross-sectional structure will be described with reference to FIG. 2B. The driver circuit portion and the pixel portion are formed over an element substrate 610; the source line driver circuit 601, which is a driver circuit portion, and one of the pixels in the pixel portion 602 are illustrated here.

As the source line driver circuit 601, a CMOS circuit in which an n-channel FET 623 and a p-channel FET 624 are combined is formed. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside, not over the substrate.

The pixel portion 602 includes a plurality of pixels including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

The kind and crystallinity of a semiconductor used for the FETs is not particularly limited; an amorphous semiconductor or a crystalline semiconductor may be used. Examples of the semiconductor used for the FETs include Group 13 semiconductors (e.g., gallium), Group 14 semiconductors (e.g., silicon), compound semiconductors, oxide semiconductors, and organic semiconductor materials. Oxide semiconductors are particularly preferable. Examples of the oxide semiconductor include an In—Ga oxide and an In-M-Zn oxide (M is Al, Ga, Y, Zr, La, Ce, or Nd). Note that an oxide semiconductor that has an energy gap of 2 eV or more, preferably 2.5 eV or more, further preferably 3 eV or more is preferably used, in which case the off-state current of the transistors can be reduced.

Note that to cover an end portion of the first electrode 613, an insulator 614 is formed. The insulator 614 can be found using a positive photosensitive acrylic resin film here.

The insulator 614 is formed to have a curved surface with curvature at its upper or lower end portion in order to obtain favorable coverage. For example, in the case where positive photosensitive acrylic is used for a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a second electrode 617 are formed over the first electrode 613. The first electrode 613, the EL layer 616, and the second electrode 617 correspond, respectively, to the first electrode 101, the EL layer 103, and the second electrode 102 in FIG. 1A or to the first electrode 501, the EL layer 503, and the second electrode 502 in FIG. 1B.

The EL layer 616 preferably contains the organometallic complex of one embodiment of the present invention. The organometallic complex is preferably used as an emission center substance in the light-emitting layer.

The sealing substrate 604 is attached to the element substrate 610 with the sealing material 605, so that a light-emitting element 618 is provided in the space 607 surrounded by the element substrate 610, the sealing substrate 604, and the sealing material 605. The space 607 may be filled with filler such as an inert gas (such as nitrogen or argon), or the sealing material 605. It is preferable that the sealing substrate 604 be provided with a recessed portion and a drying agent be provided in the recessed portion, in which case deterioration due to influence of moisture can be suppressed.

An epoxy-based resin or glass frit is preferably used for the sealing material 605. It is preferable that such a material do not transmit moisture or oxygen as much as possible. As the element substrate 610 and the sealing substrate 604, a glass substrate, a quartz substrate, or a plastic substrate formed of fiber reinforced plastic (FRP), polyvinyl fluoride (PVF), polyester, or acrylic can be used.

Note that in this specification and the like, a transistor or a light-emitting element can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of the flexible substrate, the attachment film, the base material film, and the like are substrates of plastics typified by polyethylene terephthalate (PET), polyethylene naphthalate (PEN), and polyether sulfone (PES). Another example is a synthetic resin such as acrylic. Alternatively, polytetrafluoroethylene (PTFE), polypropylene, polyester, polyvinyl fluoride, polyvinyl chloride, or the like can be used. Alternatively, polyamide, polyimide, aramid, epoxy, an inorganic vapor deposition film, paper, or the like can be used. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Alternatively, a flexible substrate may be used as the substrate, and the transistor or the light-emitting element may be provided directly on the flexible substrate. Still alternatively, a separation layer may be provided between the substrate and the transistor or the substrate and the light-emitting element. The separation layer can be used when part or the whole of a semiconductor device formed over the separation layer is separated from the substrate and transferred onto another substrate. In such a case, the transistor can be transferred to a substrate having low heat resistance or a flexible substrate. For the separation layer, a stack including inorganic films, which are a tungsten film and a silicon oxide film, or an organic resin film of polyimide or the like formed over a substrate can be used, for example.

In other words, a transistor or a light-emitting element may be formed using one substrate, and then transferred to another substrate. Examples of a substrate to which a transistor or a light-emitting element is transferred include, in addition to the above-described substrates over which transistors can be framed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a transistor with excellent characteristics or a transistor with low power consumption can be formed, a device with high durability or high heat resistance can be provided, or reduction in weight or thickness can be achieved.

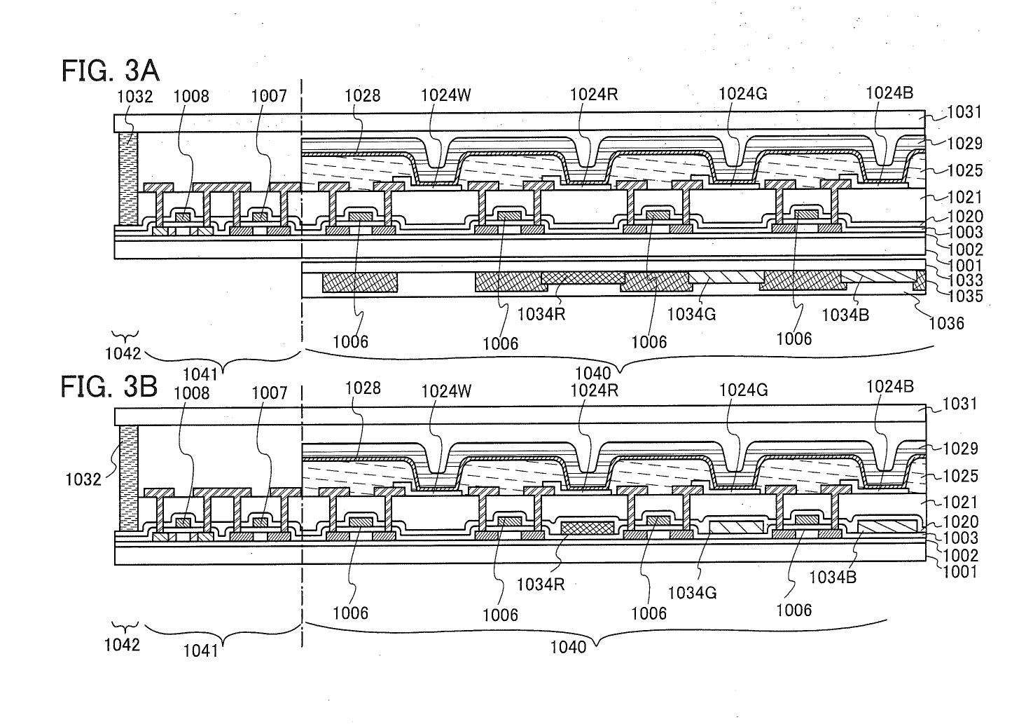

FIGS. 3A and 3B each illustrate an example of a light-emitting device in which full color display is achieved by formation of a light-emitting element exhibiting white light emission and with the use of coloring layers (color filters) and the like. In FIG. 3A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting elements, a partition 1025, an EL layer 1028, a second electrode 1029 of the light-emitting elements, a sealing substrate 1031, a sealing material 1032, and the like are illustrated.

In FIG. 3A, coloring layers (a red coloring layer 1034R, a green coloring layer 1034G, and a blue coloring layer 1034B) are provided on a transparent base material 1033. A black layer (a black matrix) 1035 may be additionally provided. The transparent base material 1033 provided with the coloring layers and the black layer is positioned and fixed to the substrate 1001. Note that the coloring layers and the black layer are covered with an overcoat layer 1036. In FIG. 3A, light emitted from part of the light-emitting layer does not pass through the coloring layers, while light emitted from the other part of the light-emitting layer passes through the coloring layers. Since light which does not pass through the coloring layers is white and light which passes through any one of the coloring layers is red, blue, or green, an image can be displayed using pixels of the four colors.

Note that a light-emitting element including the organometallic complex of one embodiment of the present invention as a light-emitting substance can have high emission efficiency and low power consumption.

FIG. 3B illustrates an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

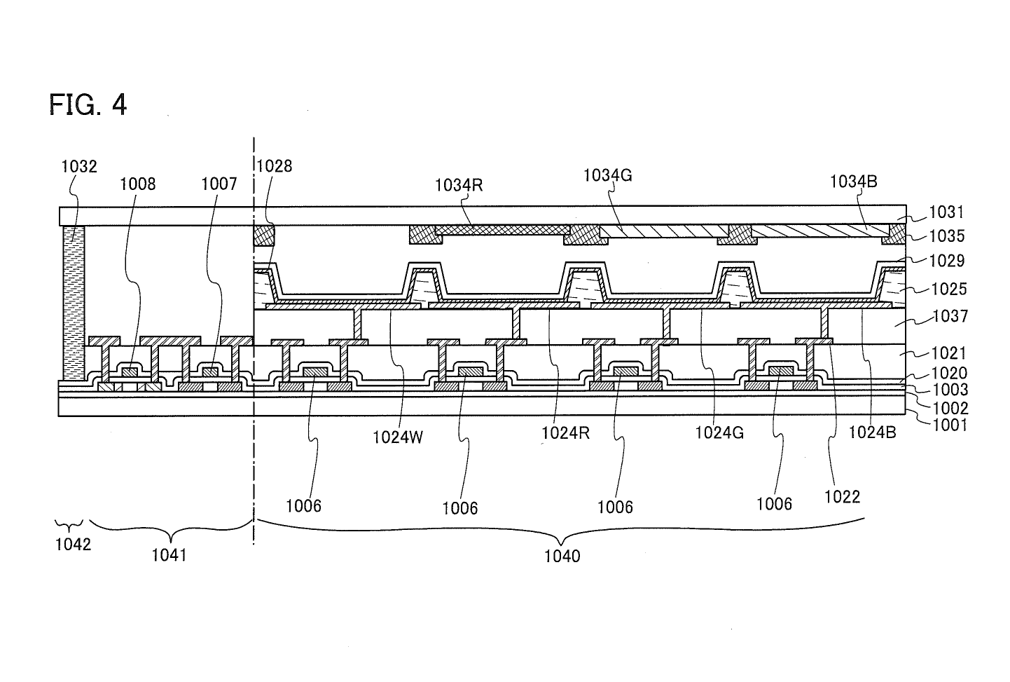

The above-described light-emitting device is a light-emitting device having a structure in which light is extracted from the substrate 1001 side where the FETs are formed (a bottom emission structure), but may be a light-emitting device having a structure in which light is extracted from the sealing substrate 1031 side (a top emission structure). FIG. 4 is a cross-sectional view of a light-emitting device having a top emission structure. In this case, a substrate which does not transmit light can be used as the substrate 1001. The process up to the step of forming a connection electrode which connects the FET and the anode of the light-emitting element is performed in a manner similar to that of the light-emitting device having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film 1021, and can alternatively be formed using any of other various materials.

The first electrodes 1024W, 1024R, 1024G, and 1024B of the light-emitting elements each serve as an anode here, but may serve as a cathode. Further, in the case of a light-emitting device having a top emission structure as illustrated in FIG. 4, the first electrodes are preferably reflective electrodes. The EL layer 1028 is formed to have a structure similar to the structure of the EL layer 103 in FIG. 1A or the EL layer 503 in FIG. 1B, with which white light emission can be obtained.

In the case of a top emission structure as illustrated in FIG. 4, sealing can be performed with the sealing substrate 1031 on which the coloring layers (the red coloring layer 1034R, the green coloring layer 1034G, and the blue coloring layer 1034B) are provided. The sealing substrate 1031 may be provided with the black layer (black matrix) 1035 which is positioned between pixels. The coloring layers (the red coloring layer 1034R, the green coloring layer 1034G, and the blue coloring layer 1034B) and the black layer (the black matrix) 1035 may be covered with the overcoat layer. Note that a light-transmitting substrate is used as the sealing substrate 1031.

Although an example in which full color display is performed using four colors of red, green, blue, and white is shown here, there is no particular limitation and full color display using three colors of red, green, and blue or four colors of red, green, blue, and yellow may be performed.

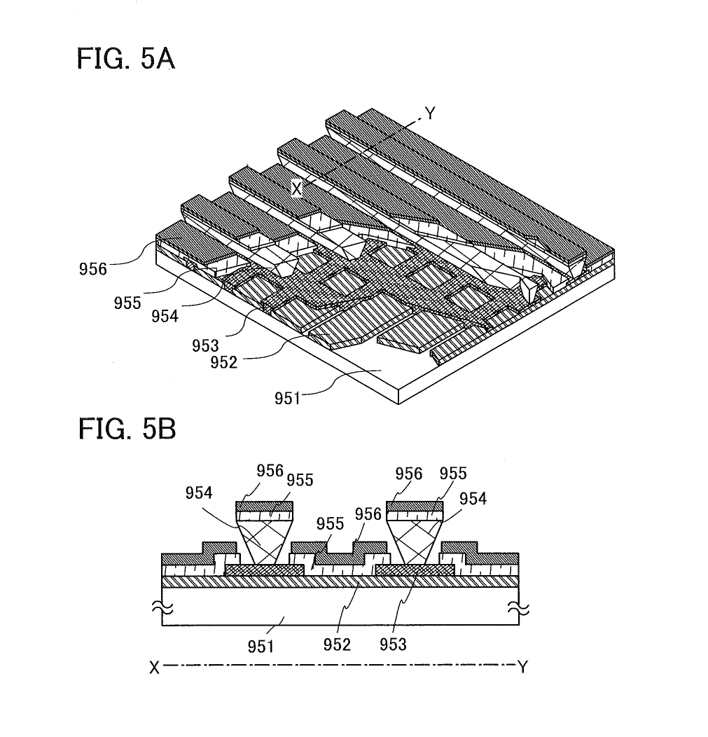

FIGS. 5A and 5B illustrate a passive matrix light-emitting device which is one embodiment of the present invention. FIG. 5A is a perspective view of the light-emitting device, and FIG. 5B is a cross-sectional view of FIG. 5A taken along line X-Y. In FIGS. 5A and 5B, an EL layer 955 is provided between an electrode 952 and an electrode 956 over a substrate 951. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side which is in the same direction as a plane direction of the insulating layer 953 and in contact with the insulating layer 953) is shorter than the upper side (a side which is in the same direction as the plane direction of the insulating layer 953 and not in contact with the insulating layer 953). The partition layer 954 thus provided can prevent defects in the light-emitting element due to static electricity or the like.

Since many minute light-emitting elements arranged in a matrix can each be controlled with the FETs formed in the pixel portion, the above-described light-emitting device can be suitably used as a display device for displaying images.

### Lighting Device

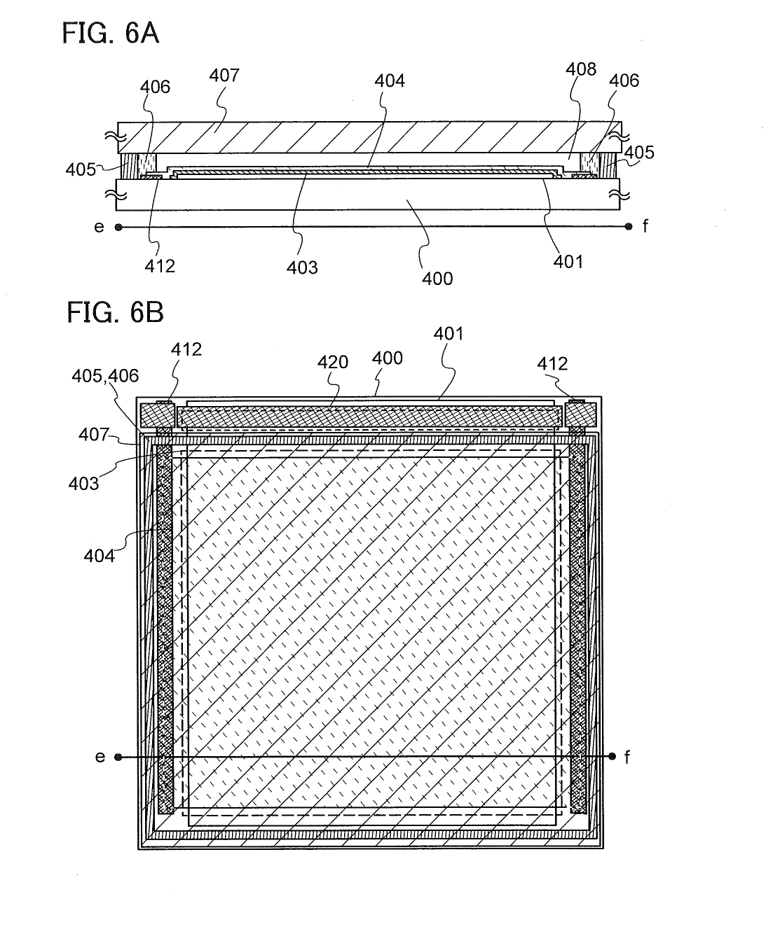

A lighting device which is one embodiment of the present invention is described with reference to FIGS. 6A and 6B. FIG. 6B is a top view of the lighting device, and FIG. 6A is a cross-sectional view of FIG. 6B taken along line e-f.

In the lighting device, a first electrode 401 is formed over a substrate 400 which is a support and has a light-transmitting property. The first electrode 401 corresponds to the first electrode 101 in FIG. 1A. When light is extracted through the first electrode 401 side, the first electrode 401 is formed using a material having a light-transmitting property.

A pad 412 for applying a voltage to a second electrode 404 is provided over the substrate 400.

An EL layer 403 is formed over the first electrode 401. The EL layer 403 corresponds to, for example, the EL layer 103 in FIG. 1A or the EL layer 503 in FIG. 1B. Refer to the descriptions for the structure.

The second electrode 404 is formed to cover the EL layer 403. The second electrode 404 corresponds to the second electrode 102 in FIG. 1A. The second electrode 404 contains a material having high reflectivity when light is extracted through the first electrode 401 side. The second electrode 404 is connected to the pad 412, whereby a voltage is applied.

A light-emitting element is formed with the first electrode 401, the EL layer 403, and the second electrode 404. The light-emitting element is fixed to a sealing substrate 407 with sealing materials 405 and 406 and sealing is performed, whereby the lighting device is completed. It is possible to use only either the sealing material 405 or the sealing material 406. In addition, the inner sealing material 406 (not shown in FIG. 6B) can be mixed with a desiccant, whereby moisture is adsorbed and the reliability is increased.

When parts of the pad 412 and the first electrode 401 are extended to the outside of the sealing materials 405 and 406, the extended parts can serve as external input terminals. An IC chip 420 mounted with a converter or the like may be provided over the external input terminals.

### Electronic Device

Examples of an electronic device which is one embodiment of the present invention are described. Examples of the electronic device are television devices (also referred to as TV or television receivers), monitors for computers and the like, cameras such as digital cameras and digital video cameras, digital photo frames, mobile phones (also referred to as cell phones or mobile phone devices), portable game machines, portable information terminals, audio playback devices, and large game machines such as pachinko machines. Specific examples of these electronic devices are given below.

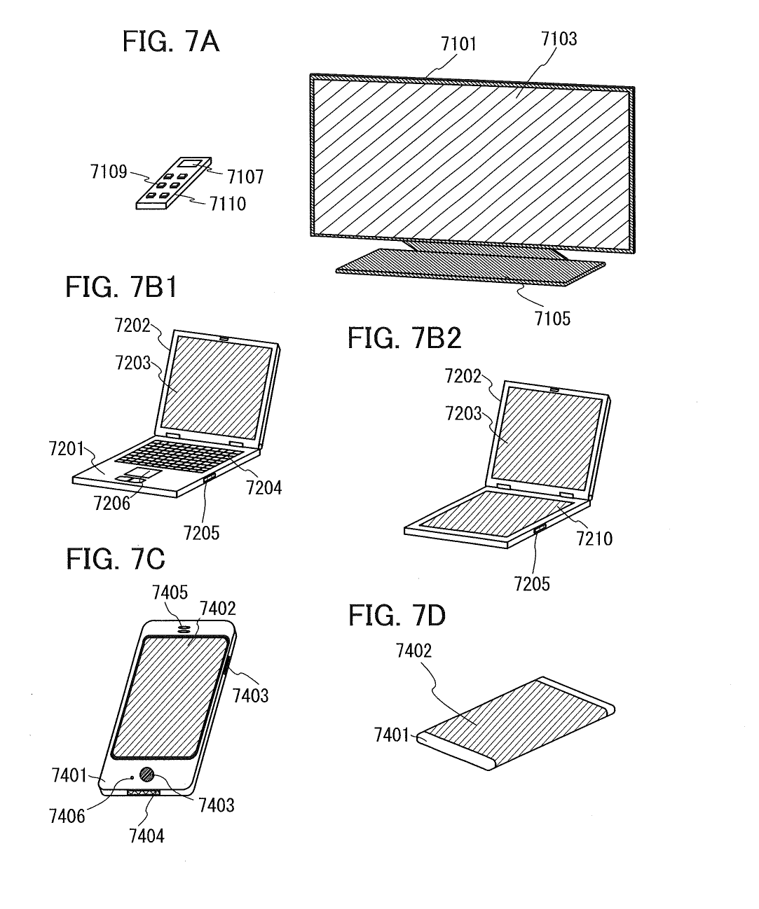

FIG. 7A illustrates an example of a television device. In the television device, a display portion 7103 is incorporated in a housing 7101. In addition, here, the housing 7101 is supported by a stand 7105. Images can be displayed on the display portion 7103, and in the display portion 7103, light-emitting elements are arranged in a matrix.

The television device can be operated with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, and the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

FIG. 7B1 illustrates a computer, which includes a main body 7201, a housing 7202, a display portion 7203, a keyboard 7204, an external connection port 7205, a pointing device 7206, and the like. Note that this computer is manufactured by using light-emitting elements arranged in a matrix in the display portion 7203. The computer illustrated in FIG. 7B1 may have a structure illustrated in FIG. 7B2. A computer illustrated in FIG. 7B2 is provided with a second display portion 7210 instead of the keyboard 7204 and the pointing device 7206. The second display portion 7210 is a touch screen, and input can be performed by operation of display for input on the second display portion 7210 with a finger or a dedicated pen. The second display portion 7210 can also display images other than the display for input. The display portion 7203 may be also a touch screen. Connecting the two screens with a hinge can prevent troubles; for example, the screens can be prevented from being cracked or broken while the computer is being stored or carried.

FIGS. 7C and 7D illustrate an example of a portable information terminal. The portable information terminal is provided with a display portion 7402 incorporated in a housing 7401, operation buttons 7403, an external connection port 7404, a speaker 7405, a microphone 7406, and the like. Note that the portable information terminal has the display portion 7402 including light-emitting elements arranged in a matrix.

Information can be input to the portable information terminal illustrated in FIGS. 7C and 7D by touching the display portion 7402 with a finger or the like. In this case, operations such as making a call and creating an e-mail can be performed by touching the display portion 7402 with a finger or the like.

There are mainly three screen modes of the display portion 7402. The first mode is a display mode mainly for displaying an image. The second mode is an input mode mainly for inputting information such as characters. The third mode is a display-and-input mode in which two modes of the display mode and the input mode are combined.

For example, in the case of making a call or creating an e-mail, a text input mode mainly for inputting text is selected for the display portion 7402 so that text displayed on a screen can be inputted. In this case, it is preferable to display a keyboard or number buttons on almost the entire screen of the display portion 7402.

When a detection device including a sensor such as a gyroscope or an acceleration sensor for sensing inclination is provided inside the mobile phone, screen display of the display portion 7402 can be automatically changed by determining the orientation of the mobile phone (whether the mobile phone is placed horizontally or vertically).

The screen modes are switched by touch on the display portion 7402 or operation with the operation buttons 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal detected by an optical sensor in the display portion 7402 is detected, the screen mode may be controlled so as to be switched from the input mode to the display mode.

The display portion 7402 may function as an image sensor. For example, an image of a palm print, a fingerprint, or the like is taken by the display portion 7402 while in touch with the palm or the finger, whereby personal authentication can be performed. Further, by providing a backlight or a sensing light source which emits near-infrared light in the display portion, an image of a finger vein, a palm vein, or the like can be taken.

Note that in the above electronic devices, any of the structures described in this specification can be combined as appropriate.

The display portion preferably includes a light-emitting element including the organometallic complex of one embodiment of the present invention. The light-emitting element can have high emission efficiency. Further, the light-emitting element can be driven at low voltage. Thus, the electronic device including the organometallic complex of one embodiment of the present invention can have low power consumption.

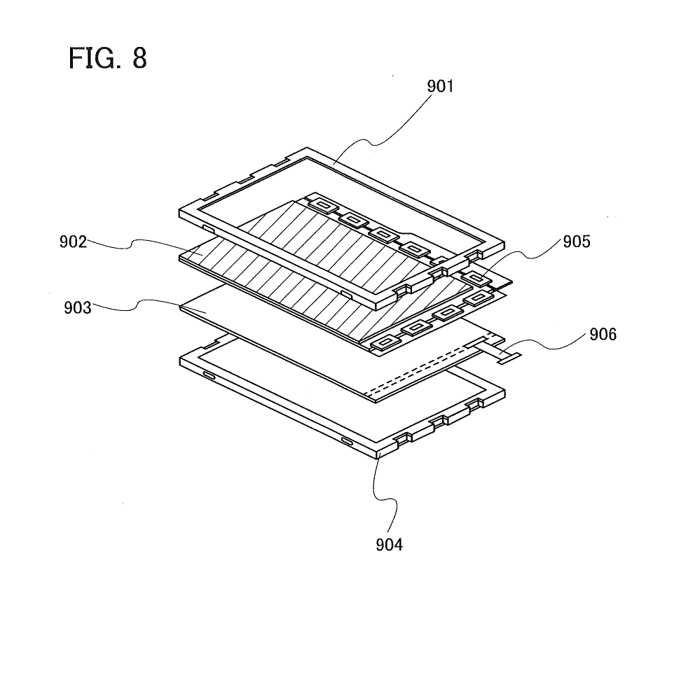

FIG. 8 illustrates an example of a liquid crystal display device including the light-emitting element for a backlight. The liquid crystal display device illustrated in FIG. 8 includes a housing 901, a liquid crystal layer 902, a backlight unit 903, and a housing 904. The liquid crystal layer 902 is connected to a driver IC 905. The light-emitting element is used for the backlight unit 903, to which current is supplied through a terminal 906.

As the light-emitting element, a light-emitting element including the organometallic complex of one embodiment of the present invention is preferably used. By including the light-emitting element, the backlight of the liquid crystal display device can have low power consumption.

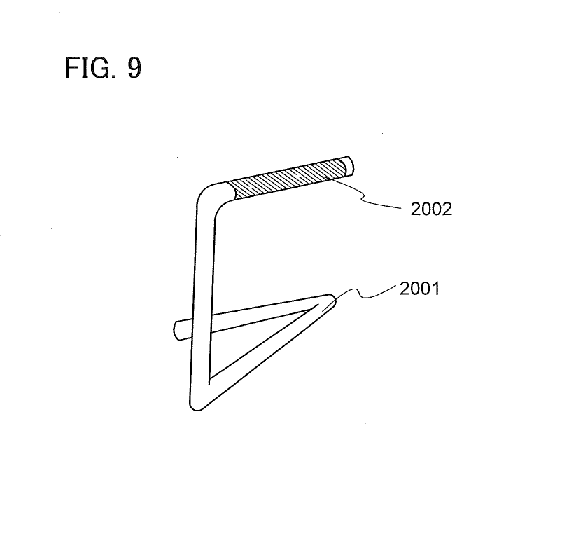

FIG. 9 illustrates an example of a desk lamp which is one embodiment of the present invention. The desk lamp illustrated in FIG. 9 includes a housing 2001 and a light source 2002, and a lighting device including a light-emitting element is used as the light source 2002.

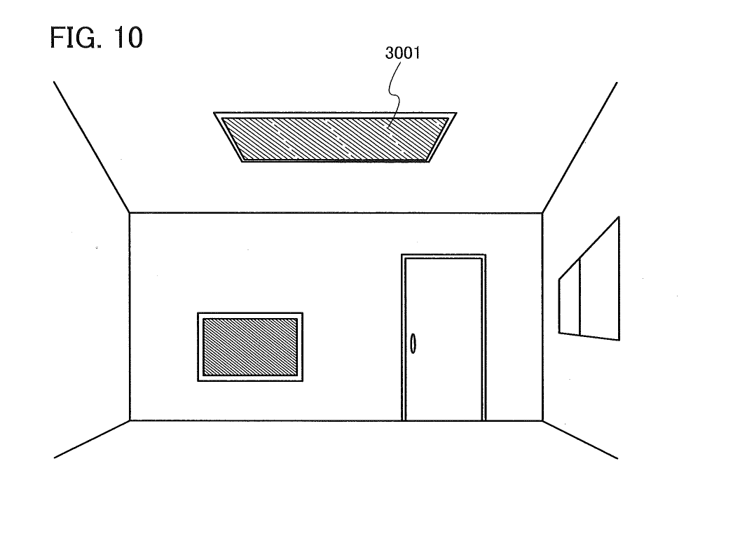

FIG. 10 illustrates an example of an indoor lighting device 3001. A light-emitting element including the organometallic complex of one embodiment of the present invention is preferably used in the lighting device 3001.

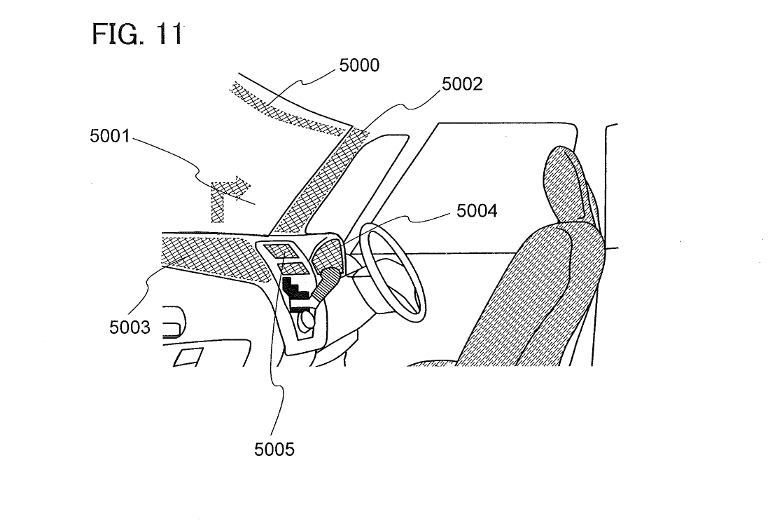

An automobile which is one embodiment of the present invention is illustrated in FIG. 11. In the automobile, light-emitting elements are used for a windshield and a dashboard. Display regions 5000 to 5005 are provided by using the light-emitting elements. The light-emitting elements preferably include the organometallic complex of one embodiment of the present invention, in which case the light-emitting elements can have low power consumption. This also suppresses power consumption of the display regions 5000 to 5005, showing suitability for use in an automobile.

The display regions 5000 and 5001 are display devices which are provided in the automobile windshield and which include the light-emitting elements. When a first electrode and a second electrode are formed of electrodes having light-transmitting properties in these light-emitting elements, what is called a see-through display device, through which the opposite side can be seen, can be obtained. Such a see-through display device can be provided even in the automobile windshield, without hindering the vision. Note that in the case where a transistor for driving or the like is provided, a transistor having a light-transmitting property, such as an organic transistor using an organic semiconductor material or a transistor using an oxide semiconductor, is preferably used.

The display region 5002 is a display device which is provided in a pillar portion and which includes the light-emitting element. The display region 5002 can compensate for the view hindered by the pillar portion by showing an image taken by an imaging unit provided in the car body. Similarly, a display region 5003 provided in the dashboard can compensate for the view hindered by the car body by showing an image taken by an imaging unit provided in the outside of the car body, which leads to elimination of blind areas and enhancement of safety. Showing an image so as to compensate for the area which a driver cannot see makes it possible for the driver to confirm safety easily and comfortably.

The display region 5004 and the display region 5005 can provide a variety of kinds of information such as navigation information, a speedometer, a tachometer, a mileage, a fuel meter, a gearshift indicator, and air-condition setting. The content or layout of the display can be changed freely by a user as appropriate. Note that such information can also be shown by the display regions 5000 to 5003. The display regions 5000 to 5005 can also be used as lighting devices.

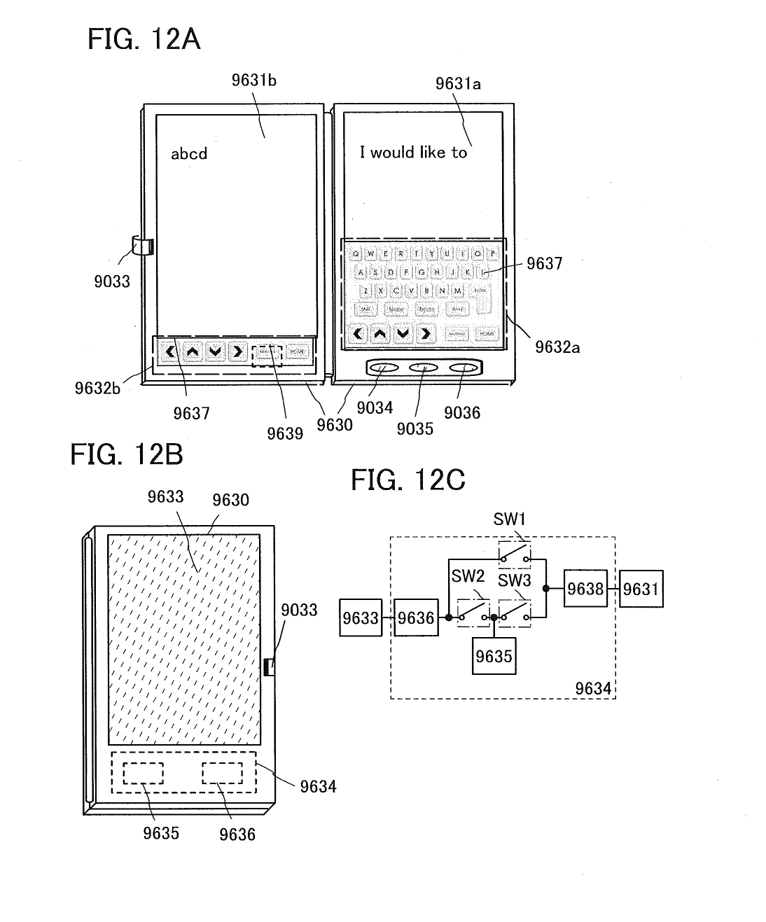

FIGS. 12A and 12B illustrate an example of a foldable tablet terminal. FIG. 12A illustrates the tablet terminal which is unfolded. The tablet terminal includes a housing 9630, a display portion 9631a, a display portion 9631b, a display mode switch 9034, a power switch 9035, a power-saving mode switch 9036, and a clasp 9033. Note that in the tablet terminal, one or both of the display portion 9631a and the display portion 9631b is/are formed using a light-emitting device which includes the light-emitting element containing the organometallic complex of one embodiment of the present invention.

Part of the display portion 9631a can be a touchscreen region 9632a and data can be input when a displayed operation key 9637 is touched. Although half of the display portion 9631a has only a display function and the other half has a touchscreen function, one embodiment of the present invention is not limited to the structure. The whole display portion 9631a may have a touchscreen function. For example, a keyboard can be displayed on the entire region of the display portion 9631a so that the display portion 9631a is used as a touchscreen, and the display portion 9631b can be used as a display screen.

Like the display portion 9631a, part of the display portion 9631b can be a touchscreen region 9632b. When a switching button 9639 for showing/hiding a keyboard on the touchscreen is touched with a finger, a stylus, or the like, the keyboard can be displayed on the display portion 9631b.

Touch input can be performed in the touchscreen region 9632a and the touchscreen region 9632b at the same time.

The display mode switch 9034 can switch the display between portrait mode, landscape mode, and the like, and between monochrome display and color display, for example. The power-saving mode switch 9036 can control display luminance in accordance with the amount of external light in use of the tablet terminal sensed by an optical sensor incorporated in the tablet terminal. Another sensing device including a sensor such as a gyroscope or an acceleration sensor for sensing inclination may be incorporated in the tablet terminal, in addition to the optical sensor.

Although FIG. 12A illustrates an example in which the display portion 9631a and the display portion 9631b have the same display area, one embodiment of the present invention is not limited to the example. The display portion 9631a and the display portion 9631b may have different display areas and different display quality. For example, higher resolution images may be displayed on one of the display portions 9631a and 9631b.

FIG. 12B illustrates the tablet terminal which is folded. The tablet terminal in this embodiment includes the housing 9630, a solar cell 9633, a charge and discharge control circuit 9634, a battery 9635, and a DCDC converter 9636. In FIG. 12B, a structure including the battery 9635 and the DCDC converter 9636 is illustrated as an example of the charge and discharge control circuit 9634.

Since the tablet terminal is foldable, the housing 9630 can be closed when the tablet terminal is not in use. As a result, the display portion 9631a and the display portion 9631b can be protected, thereby providing a tablet terminal with high endurance and high reliability for long-term use.

The tablet terminal illustrated in FIGS. 12A and 12B can have other functions such as a function of displaying various kinds of data (e.g., a still image, a moving image, and a text image), a function of displaying a calendar, a date, the time, or the like on the display portion, a touch-input function of operating or editing the data displayed on the display portion by touch input, and a function of controlling processing by various kinds of software (programs).

The solar cell 9633 provided on a surface of the tablet terminal can supply power to the touchscreen, the display portion, a video signal processing portion, or the like. Note that a structure in which the solar cell 9633 is provided on one or both surfaces of the housing 9630 is preferable because the battery 9635 can be charged efficiently.

The structure and operation of the charge and discharge control circuit 9634 illustrated in FIG. 12B are described with reference to a block diagram of FIG. 12C. FIG. 12C illustrates the solar cell 9633, the battery 9635, the DCDC converter 9636, a converter 9638, switches SW1 to SW3, and a display portion 9631. The battery 9635, the DCDC converter 9636, the converter 9638, and the switches SW1 to SW3 correspond to the charge and discharge control circuit 9634 illustrated in FIG. 12B.

First, description is made on an example of the operation in the case where power is generated by the solar cell 9633 with the use of external light. The voltage of the power generated by the solar cell is raised or lowered by the DCDC converter 9636 so as to be voltage for charging the battery 9635. Then, when power from the solar cell 9633 is used for the operation of the display portion 9631, the switch SW1 is turned on and the voltage of the power is raised or lowered by the converter 9638 so as to be voltage needed for the display portion 9631. When images are not displayed on the display portion 9631, the switch SW1 is turned off and the switch SW2 is turned on so that the battery 9635 is charged.

Although the solar cell 9633 is described as an example of a power generation unit, the power generation unit is not particularly limited, and the battery 9635 may be charged by another power generation unit such as a piezoelectric element or a thermoelectric conversion element (Peltier element). The battery 9635 may be charged by a non-contact power transmission module capable of performing charging by transmitting and receiving power wirelessly (without contact), or another charge unit used in combination, and the power generation unit is not necessarily provided.

Note that the organometallic complex of one embodiment of the present invention can be used for an organic thin-film solar cell. Specifically, the organometallic complex can be used in a carrier-transport layer since the organometallic complex has a carrier-transport property. The organometallic complex can be photoexcited and hence can be used in a power generation layer.

One embodiment of the present invention is not limited to the tablet terminal having the shape illustrated in FIGS. 12A to 12C as long as the display portion 9631 is included.

### Example 1

### Synthesis Example 1

In Synthesis Example 1, a synthesis example of tris[5-(9H-carbazol-9-yl)-2-(5-methyl-4-phenyl-4H-1,2,4-triazol-3-yl-κN2)phenyl-κC]iridium(III) (abbreviation: [Ir(MCzptz)₃]), which is the organometallic complex of one embodiment of the present invention represented by Structural Formula (100) in the embodiment, is specifically described. A structural formula of [Ir(MCzptz)₃] is shown below.

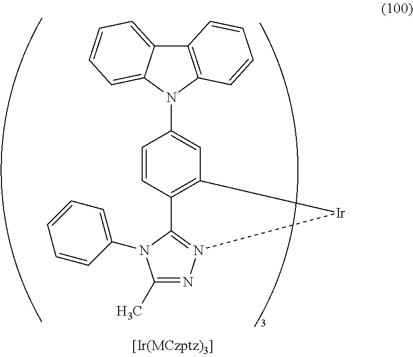

### Step 1: Synthesis of 3-(4-bromophenyl)-5-methyl-4-phenyl-4H-1,2,4-triazole

First, 5.5 g (36 mmol) of thioacetanilide, 7.8 g (36 mmol) of 4-bromobenzohydrazide, and 80 mL of 1-butanol were put into a 300-mL three-neck flask and heated with stirring at 120° C. for 38 hours. To this mixed solution, 1.0 g (6.6 mmol) of thioacetanilide was further added and the mixture was heated with stirring at 120° C. for 13 hours. The resulting reaction solution was concentrated, and the obtained residue was purified by silica gel column chromatography. Ethyl acetate was used as a developing solvent. The obtained fraction was concentrated to give a solid. This solid was recrystallized with ethyl acetate, so that 3-(4-bromophenyl)-5-methyl-4-phenyl-4H-1,2,4-triazole was obtained as a white solid in a yield of 63%. The synthesis scheme of Step 1 is shown in (1-1).

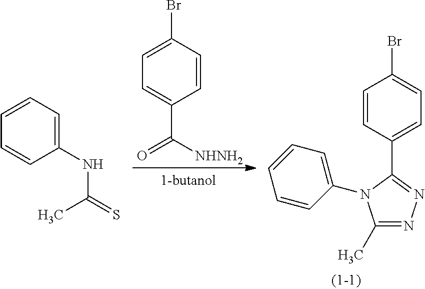

### Step 2: Synthesis of 3-{4-(9H-carbazol-9-yl)phenyl}-5-methyl-4-phenyl-4H-1,2,4-triazole (abbreviation: 1-1MCzptz)

Then, 4.0 g (13 mmol) of 3-(4-bromophenyl)-5-methyl-4-phenyl-4H-1,2,4-triazole obtained in Step 1, 2.1 g (13 mmol) of 9H-carbazole, 0.48 g (2.5 mmol) of copper iodide, 3.87 g (28 mmol) of potassium carbonate, 0.5 g (1.9 mmol) of 18-crown-6-ether, and 20 mL of 1,3-dimethyl-3,4,5,6-tetrahydro-2(1H)pyrimidinone (DMPU) were put into a reaction container equipped with a cooling tube, the air in the container was replaced with nitrogen, and the mixture was heated with stirring at 180° C. for 8 hours. Chloroform was added to the obtained reaction mixture, the resulting mixture was added to 100 mL of 1N hydrochloric acid, and stirring was performed. The organic layer of the resulting mixture was washed with a saturated aqueous solution of sodium hydrogen carbonate and then with saturated brine, and anhydrate magnesium sulfate was added to the organic layer for drying. The obtained mixture was gravity-filtered, and the filtrate was concentrated to give an oily substance. This oily substance was dissolved in toluene and filtered through Celite and alumina. The filtrate was concentrated to obtain a solid. This solid was washed with ethyl acetate, so that 3-{4-(9H-carbazol-9-yl)phenyl}-5-methyl-4-phenyl-4H-1,2,4-triazole (abbreviation: HMCzptz) was obtained as a white solid in a yield of 49%. The synthesis scheme of Step 2 is shown in (1-2).

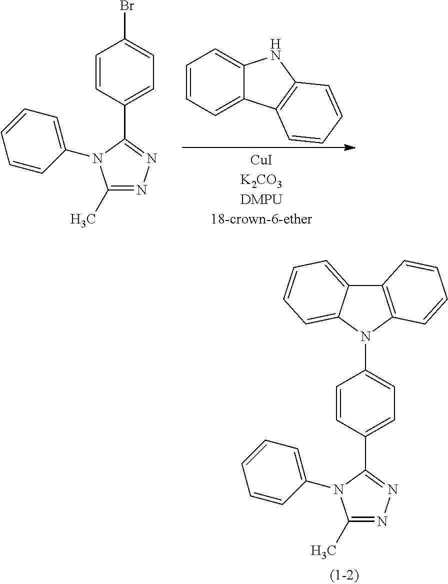

### Step 3: Synthesis of tris[5-(9H-carbazol-9-yl)-2-(5-methyl-4-phenyl-4H-1,2,4-triazol-3-yl-κN2)phenyl-κC]iridium(III) (abbreviation: [Ir(MCzptz)₃])

Next, 1.0 g (2.5 mmol) of HMCzptz, which is the ligand obtained in Step 2, and 0.25 g (0.5 mmol) of tris(acetylacetonato)iridium(III) were put into a reaction container equipped with a three-way cock, the container was degassed, and the air therein was replaced with argon. The mixture was heated with stirring at 250° C. for 44 hours. The resulting reaction mixture was dissolved in dichloromethane and purification by flash column chromatography was performed. As the developing solvent, a mixed solvent of dichloromethane and ethyl acetate in a ratio of 30:70 (v/v) was used. The obtained fraction was concentrated to obtain a solid. This solid was dissolved in ethyl acetate while being heated, and an insoluble solid was removed by gravity filtration. The filtrate was concentrated and recrystallization using ethyl acetate was performed. The resulting powder was washed with toluene and thus [Ir(MCzptz)₃], which is the organometallic complex of one embodiment of the present invention, was obtained as a yellow powder in a yield of 12%. The synthesis scheme of Step 3 is shown in (1-3).

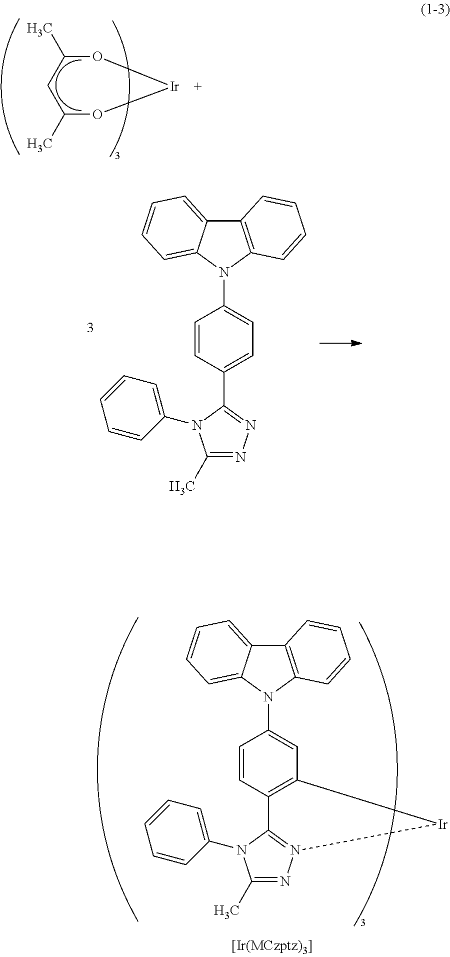

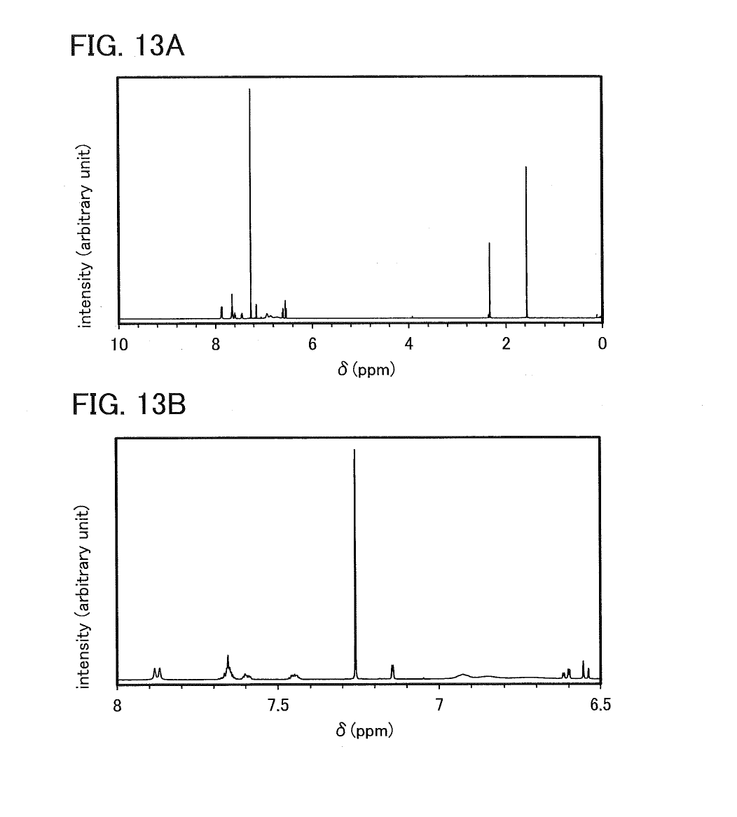

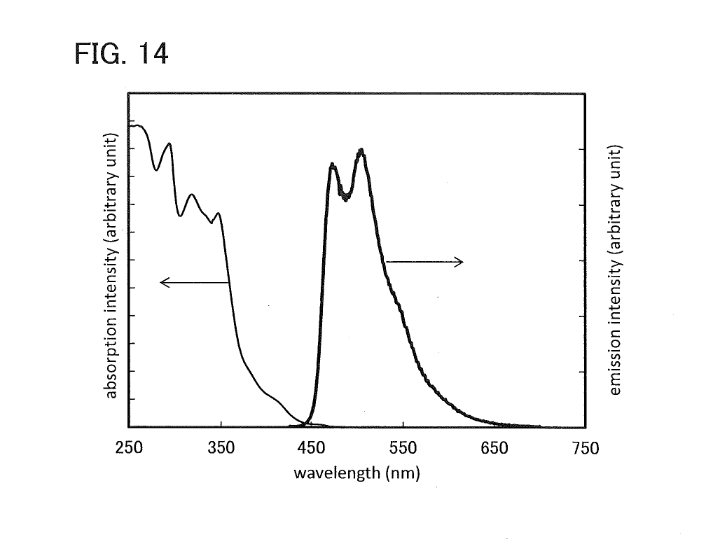

Analysis results by nuclear magnetic resonance (¹H-NMR) spectroscopy of the yellow powder obtained in Step 3 are described below. FIGS. 13A and 13B show the ¹H-NMR charts. Note that FIG. 13B is an enlarged chart showing a range of 6.5 ppm to 8.0 ppm in FIG. 13A. These results revealed that [Ir(MCzptz)₃], which is the organometallic complex of one embodiment of the present invention represented by Structural Formula (100), was obtained in this synthesis example.

¹H-NMR. δ (CDCl₃): 2.33 (s, 9H), 6.53-6.62 (m, 6H), 6.70-6.93 (br, 18H), 7.14 (d, 3H), 7.44-7.46 (m, 3H), 7.58-7.60 (m, 3H), 7.64-7.68 (m, 9H), 7.87 (d, 6H).

Next, analysis of [Ir(MCzptz)₃] was conducted by ultraviolet-visible (UV) absorption spectroscopy. A UV spectrum was measured with an ultraviolet-visible spectrophotometer (V-550, manufactured by JASCO Corporation) using a dichloromethane solution (0.075 mmol/L) at room temperature. In addition, an emission spectrum of [Ir(MCzptz)₃] was measured using a fluorescence spectrophotometer (FS920 manufactured by Hamamatsu Photonics K.K.) and a degassed dichloromethane solution (0.075 mmol/L) at room temperature. FIG. 14 shows the measurement results.

As shown in FIG. 14, [Ir(MCzptz)₃], which is the organometallic complex of one embodiment of the present invention, has emission peaks at 472 nm and 505 nm, and blue green light emission was observed from the dichloromethane solution.

Next, [Ir(MCzptz)₃] obtained in this example was analyzed by liquid chromatography mass spectrometry (LC/MS).

In the analysis by LC/MS, liquid chromatography (LC) separation was carried out with ACQUITY UPLC (manufactured by Waters Corporation) and mass spectrometry (MS) analysis was carried out with Xevo G2 Tof MS (manufactured by Waters Corporation). ACQUITY UPLC BEH C8 (2.1×100 mm, 1.7 μm) was used as a column for the LC separation, and the column temperature was 40° C. Acetonitrile was used for Mobile Phase A and a 0.1% formic acid aqueous solution was used for Mobile Phase B. Further, a sample was prepared in such a manner that [Ir(MCzptz)₃] was dissolved in chloroform at a given concentration and the mixture was diluted with acetonitrile. The injection amount was 5.0 μL.

In the LC separation, a gradient method in which the composition of mobile phases is changed was employed. The ratio of Mobile Phase A to Mobile Phase B was 70:30 for 0 to 1 minute after the start of the measurement, and then the composition was changed such that the ratio of Mobile Phase A to Mobile Phase B in the 10th minute was 95:5. The composition was changed linearly.

In the MS analysis, ionization was carried out by an electrospray ionization (ESI) method. At this time, the capillary voltage and the sample cone voltage were set to 3.0 kV and 30 V, respectively, and detection was performed in a positive mode. The mass range for the measurement was m/z=100 to 1500.

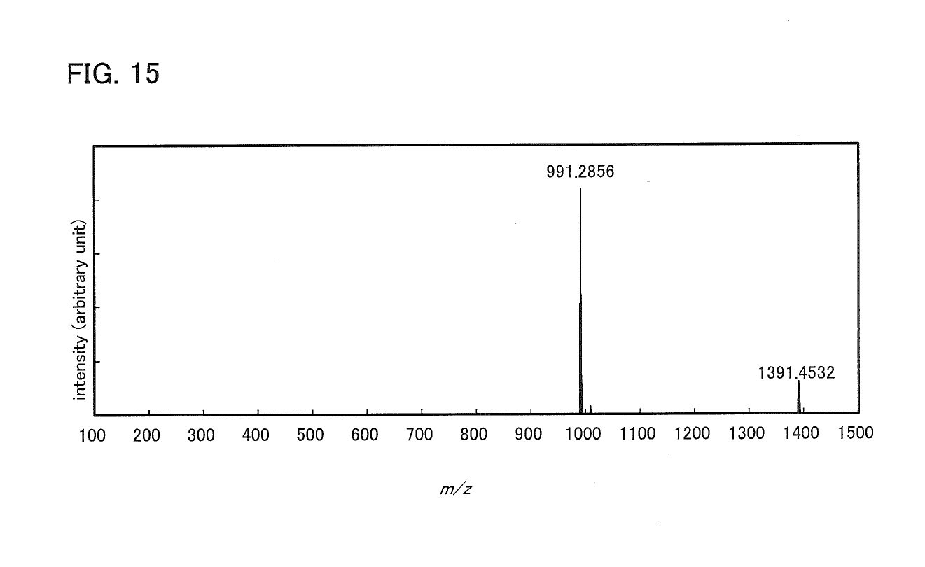

A component with m/z of 1391.45 which underwent the separation and the ionization under the above-described conditions was collided with an argon gas in a collision cell to dissociate into product ions. Energy (collision energy) for the collision with argon was 70 eV. The detection results of the dissociated product ions by time-of-flight (TOF) MS are shown in FIG. 15.

FIG. 15 shows that product ions of [Ir(MCzptz)₃], which is the organometallic complex of one embodiment of the present invention represented by Structural Formula (100), are mainly detected around m/z=991.29. The results in FIG. 15 show characteristics derived from [Ir(MCzptz)₃] and therefore can be regarded as important data for identifying [Ir(MCzptz)₃] contained in a mixture.

It is presumed that the product ion around m/z=991.29 is a cation in a state where the ligand HMCzptz is eliminated from the compound represented by Structural Formula (100), and this is characteristic of the organometallic complex of one embodiment of the present invention.

Next, [Ir(MCzptz)₃] was subjected to electrochemical measurement by cyclic voltammetry.

For the electrochemical measurement, an electrochemical analyzer ALS 600 produced by BAS Inc., a platinum wire working electrode, a platinum wire counter electrode, and an Ag/Ag⁺ reference electrode were used. Before the measurement, a DMF solvent to which tetrabutylammonium salt that was a supporting electrolyte was added at a concentration of 10 mM was put into an electrochemical cell, the sample was added at a concentration of 2 mM, and then, argon bubbling was performed for degasification.

A HOMO level E_{HOMO} is calculated semiempirically by the following expression using the half-wave potential of the first oxidation wave E_{1/2}^{Ox1} obtained by electrochemical measurement (standard: ferrocene).

E_{HOMO} [eV]=−4.94−E_{1/2}^{Ox1}[V vs. Fc/Fc⁺]

The first oxidation potential E_{1/2}^{Ox1} of [Ir(MCzptz)₃] obtained using ferrocene as a standard is 0.45 V (Fc/Fc⁺), and the HOMO level thereof can be calculated to be −5.39 eV from the above potential difference. The above results show that [Ir(MCzptz)₃] that is the organometallic complex of one embodiment of the present invention has deep HOMO.

### Example 2

### Synthesis Example 2

In Synthesis Example 2, a synthesis example of tris{5-(9H-carbazol-9-yl)-2-[5-(2-methylphenyl)-4-(2,6-dimethylphenyl)-4H-1,2,4-triazol-3-yl-κN2]phenyl-κC}iridium(III) (abbreviation: [Ir(mpCzptz-dmp)₃]), which is the organometallic complex of one embodiment of the present invention represented by Structural Formula (115) in the embodiment, is specifically described. A structural formula of [Ir(mpCzptz-dmp)₃] is shown below.

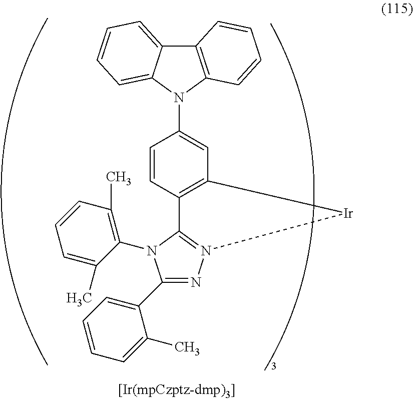

### Step 1: Synthesis of N-(4-bromobenzoyl)-N-(2-methylphenyl)hydrazide

In a 200-mL three-neck flask were put 15.0 g (69.4 mmol) of 4-bromobenzoylhydrazine and 40 mL of N-methyl-2-pyrrolidinone (NMP), and the mixture was stirred in an ice bath. To this solution, a mixed solution of 10.5 g (67.9 mmol) of o-toluoyl chloride and 10 mL of NMP was slowly added dropwise, and the mixture was stirred at room temperature for 24 hours. After reaction for the predetermined time, the reaction mixture was poured into 500 mL of water to precipitate a white solid. This solid was collected by filtration and ultrasonic cleaning using 1M hydrochloric acid and that using pure water were repeated alternately twice. After the cleaning, a white solid was collected; thus, 20.8 g of N-(4-bromobenzoyl)-N-(2-methylphenyl)hydrazide was obtained in a yield of 92%. The synthesis scheme of Step 1 is shown in (2-1).

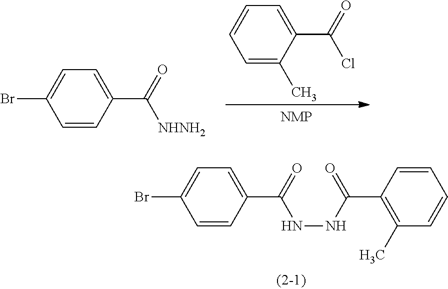

### Step 2: Synthesis of N-(4-bromophenyl)chloromethylidene-N-(2-methylphenyl)chloromethylidenehydrazine

Then, 19.2 g (58.0 mmol) of N-(4-bromobenzoyl)-N-(2-methylphenyl)hydrazide obtained in Step 1, 25.0 g (123 mmol) of phosphorus pentachloride, and 300 mL of toluene were put into a 1-L three-neck flask and the mixture was heated with stirring at 120° C. for 6 hours. After reaction for the predetermined time, the reaction solution was slowly poured into 500 mL of water and the mixture was stirred for 1 hour. After the stirring, an organic layer and an aqueous layer were separated, and the organic layer was washed with water and a saturated aqueous solution of sodium hydrogen carbonate. After the washing, the organic layer was dried with anhydrous magnesium sulfate. The magnesium sulfate was removed from this mixture by gravity filtration, and the filtrate was concentrated, so that N-(4-bromophenyl)chloromethylidene-N-(2-methylphenyl)chloromethylidenehydrazine was obtained as 20.2 g of a brown oily substance in a yield of 94%. The synthesis scheme of Step 2 is shown in (2-2).

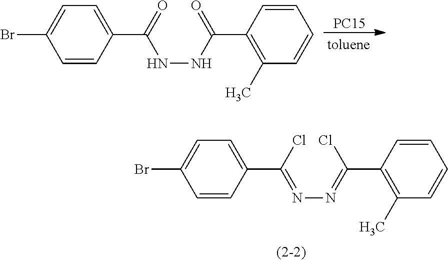 [SMILES: Cc1ccccc1C(=O)NNC(=O)c1ccc(Br)cc1 ; Cc1ccccc1/C(Cl)=N/N=C(\Cl)c1ccc(Br)cc1 ; "PC15"]

### Step 3: Synthesis of 3-(4-bromophenyl)-4-(2,6-dimethylphenyl)-5-(2-methylphenyl)-4H-1,2,4-triazole

Into a 200-mL three-neck flask were put 10 g (27 mmol) of N-(4-bromophenyl)chloromethylidene-N-(2-methylphenyl)chloromethylidenehydrazine obtained in Step 2, 10 g (81 mmol) of 2,6-dimethylaniline, and 60 mL of N,N-dimethylaniline, and the mixture was heated with stirring at 180° C. for 24 hours. After reaction for the predetermined time, this reaction solution was slowly poured into 500 mL of 1M hydrochloric acid and the mixture was stirred at room temperature for 30 minutes, so that a solid was precipitated. This solid was collected by filtration. This solid was recrystallized with ethyl acetate and hexane, so that 3-(4-bromophenyl)-4-(2,6-dimethylphenyl)-5-(2-methylphenyl)-4H-1,2,4-triazole was obtained as 6.8 g of a white solid in a yield of 50%. The synthesis scheme of Step 3 is shown in (2-3).

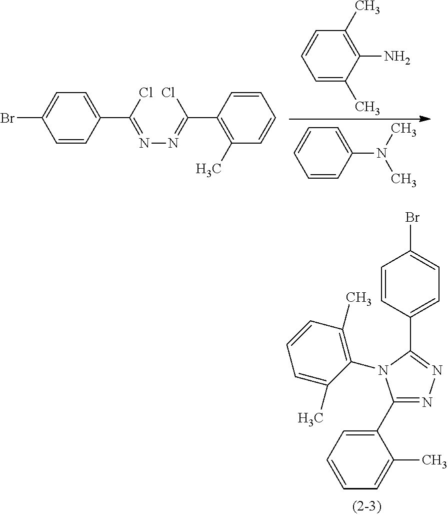

### Step 3-[4-(9H-carbazol-9-yl)phenyl]-4-(2,6-dimethylphenyl)-5-(2-methylphenyl)-4H-1,2,4-triazole (abbreviation: HmpCzptz-dmp)

Into a 100-mL three-neck flask were put 3.0 g (7.2 mmol) of 3-(4-bromophenyl)-4-(2,6-dimethylphenyl)-5-(2-methylphenyl)-4H-1,2,4-triazole obtained in Step 3, 3.6 g (21.5 mmol) of 9H-carbazole, 0.8 g (4.4 mmol) of 1,10-phenanthroline, 0.4 g (2.2 mmol) of copper iodide, 14.3 g (44 mmol) of cesium carbonate, and 15 mL of N,N-dimethylformamide, and the mixture was heated with stirring at 150° C. for 16 hours. After reaction for the predetermined time, the reaction solution was filtered to remove an insoluble matter. Chloroform was added to the filtrate and the mixture was washed with saturated brine and pure water. An organic layer was collected and dried with magnesium sulfate and then the solvent was distilled off, so that a black solid was obtained. This solid was purified by silica gel column chromatography. As a developing solvent, a mixed solvent of hexane and ethyl acetate in a ratio of 4:1 was used. The obtained fraction was concentrated to give a white solid. The obtained white solid was recrystallized with a mixed solvent of ethyl acetate and hexane, so that 3-[4-(9H-carbazol-9-yl)phenyl]-4-(2,6-dimethylphenyl)-5-(2-methylphenyl)-4H-1,2,4-triazole (abbreviation: HmpCzptz-dmp) was obtained as 1.1 g of a white solid in a yield of 30%. The synthesis scheme of Step 4 is shown in (2-4).

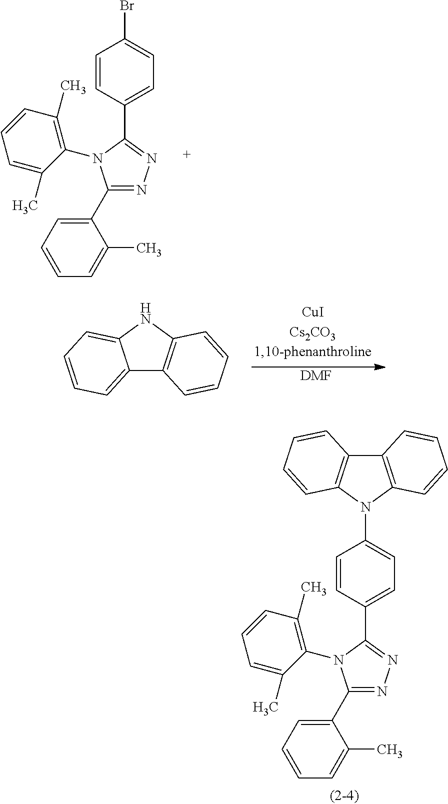

### Step 5: Synthesis of tris {5-(9H-carbazol-9-yl)-2-[5-(2-methylphenyl)-4-(2,6-dimethylphenyl)-4H-1,2,4-triazol-3-yl-κN2]phenyl-κC}iridium(III) (abbreviation: [Ir(mpCzptz-dmp)₃])

Into a container for high-temperature heating were put 1.1 g (2.2 mmol) of HmpCzptz-dmp obtained in Step 4 and 0.21 g (0.44 mmol) of tris(acetylacetonato)iridium(III), and the mixture was heated with stirring at 250° C. for 48 hours. After reaction for the predetermined time, the reaction mixture was dissolved in dichloromethane and purification by silica gel chromatography (a developing solvent: hexane:ethyl acetate=1:4) was performed. The obtained fraction was concentrated to give a yellow solid. This solid was recrystallized with a mixed solvent of ethyl acetate and hexane, so that [Ir(mpCzptz-dmp)₃] was obtained as 0.1 g of a yellow solid in a yield of 13%. The synthesis scheme of Step 5 is shown in (2-5).

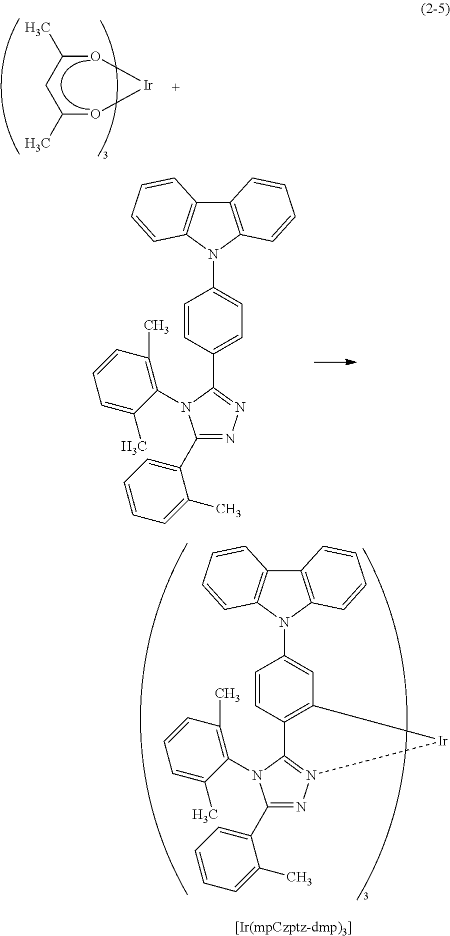

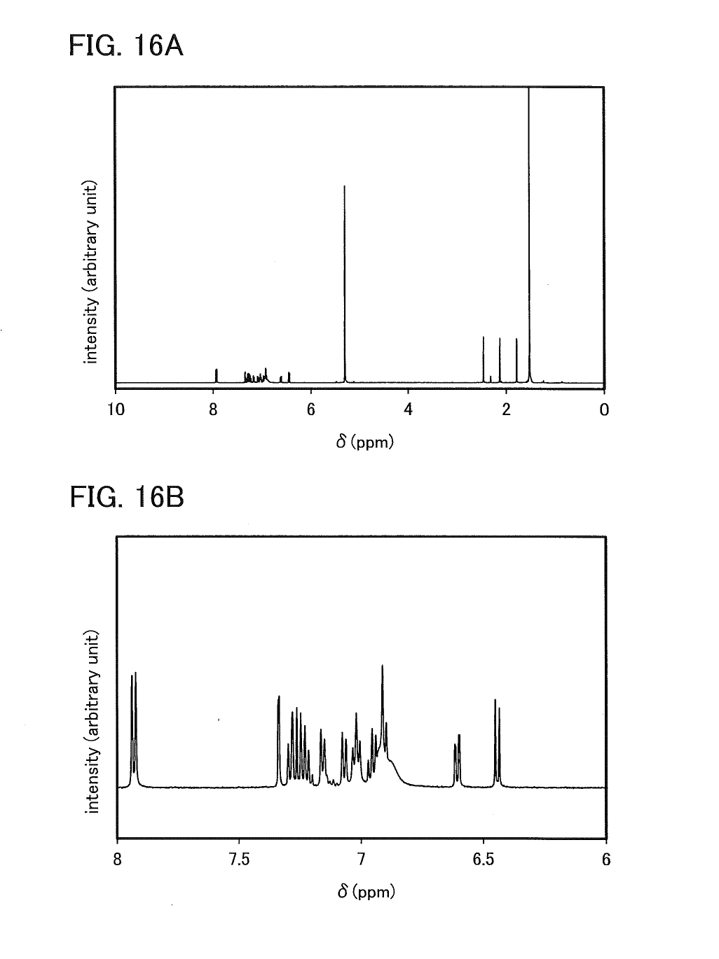

Analysis results by nuclear magnetic resonance (¹H-NMR) spectroscopy of the yellow solid obtained in Step 5 are described below. FIGS. 16A and 16B show the ¹H-NMR charts. Note that FIG. 16B is an enlarged chart showing a range of 6.0 ppm to 8.0 ppm in FIG. 16A. These results revealed that [Ir(mpCzptz-dmp)₃], which is the organometallic complex of one embodiment of the present invention represented by Structural Formula (115), was obtained in this synthesis example.

¹H-NMR. δ (CD₂Cl₂): 1.79 (s, 9H), 2.13 (s, 9H), 2.46 (s, 9H), 6.44 (d, 3H), 6.60 (d, 3H), 6.89-6.93 (m, 18H), 6.97-7.08 (m, 9H), 7.14 (d, 3H), 7.20-7.30 (m, 9H), 7.34 (s, 3H), 7.92 (d, 6H).

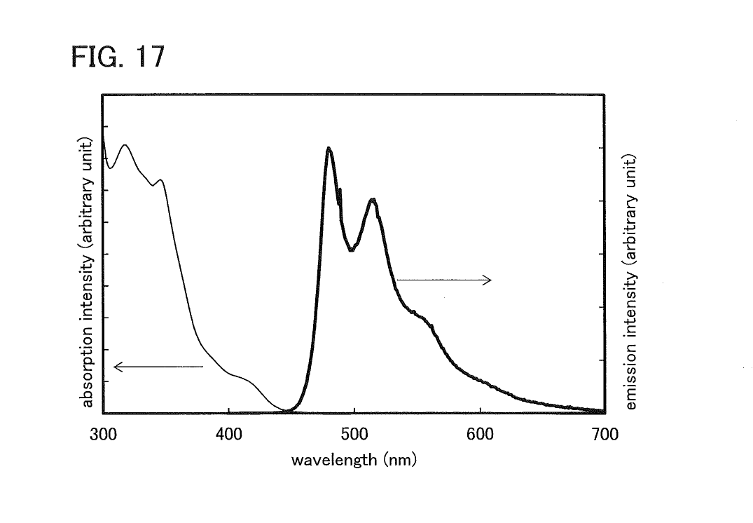

Next, analysis of [Ir(mpCzptz-dmp)₃] was conducted by ultraviolet-visible (UV) absorption spectroscopy. A UV spectrum was measured with an ultraviolet-visible spectrophotometer (V-550, manufactured by JASCO Corporation) using a dichloromethane solution (0.054 mmol/L) at room temperature. In addition, an emission spectrum of [Ir(mpCzptz-dmp)₃] was measured using a fluorescence spectrophotometer (FS920 manufactured by Hamamatsu Photonics K.K.) and a degassed dichloromethane solution (0.054 mmol/L) at room temperature. FIG. 17 shows the measurement results.

As shown in FIG. 17, [Ir(mpCzptz-dmp)₃], which is the organometallic complex of one embodiment of the present invention, has emission peaks at 477 nm and 520 nm, and blue green light emission was observed from the dichloromethane solution.

Next, [Ir(mpCzptz-dmp)₃] obtained in this example was analyzed by liquid chromatography mass spectrometry (LC/MS).

In the analysis by LC/MS, liquid chromatography (LC) separation was carried out with ACQUITY UPLC (manufactured by Waters Corporation) and mass spectrometry (MS) analysis was carried out with Xevo G2 Tof MS (manufactured by Waters Corporation). ACQUITY UPLC BEH C8 (2.1×100 mm, 1.7 μm) was used as a column for the LC separation, and the column temperature was 40° C. Acetonitrile was used for Mobile Phase A and a 0.1% formic acid aqueous solution was used for Mobile Phase B. Further, a sample was prepared in such a manner that [Ir(mpCzptz-dmp)₃] was dissolved in toluene at a given concentration and the mixture was diluted with acetonitrile. The injection amount was 5.0 μL.

In the LC separation, a gradient method in which the composition of mobile phases is changed was employed. The ratio of Mobile Phase A to Mobile Phase B was 90:10 for 0 to 1 minute after the start of the measurement, and then the composition was changed such that the ratio of Mobile Phase A to Mobile Phase B in the 2nd minute was 95:5. After that, the composition was maintained until the 10th minute. The composition was changed linearly.

In the MS analysis, ionization was carried out by an electrospray ionization (ESI) method. At this time, the capillary voltage and the sample cone voltage were set to 3.0 kV and 30 V, respectively, and detection was performed in a positive mode. The mass range for the measurement was m/z=100 to 2000.

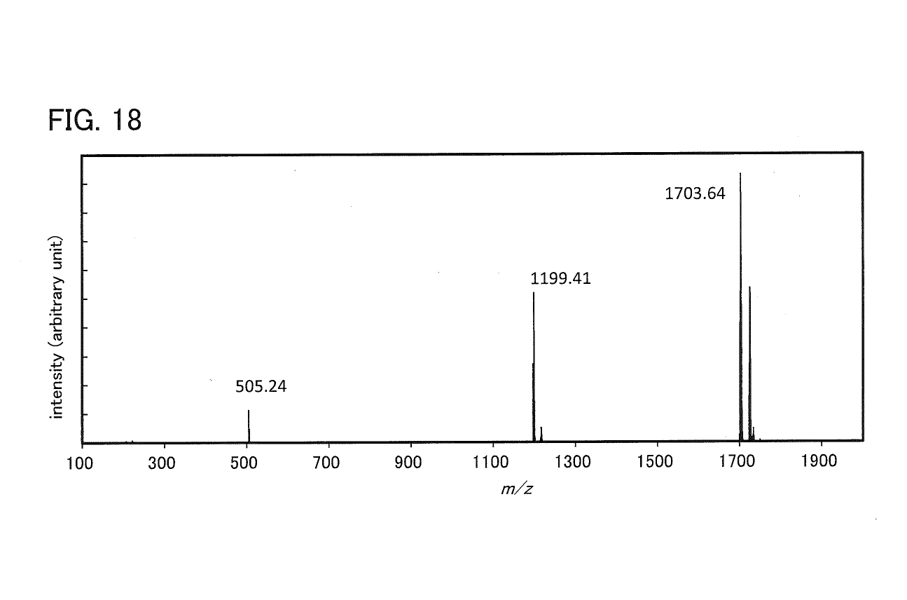

A component with m/z of 1703.64 which underwent the separation and the ionization under the above-described conditions was collided with an argon gas in a collision cell to dissociate into product ions. Energy (collision energy) for the collision with argon was 50 eV. The detection results of the dissociated product ions by time-of-flight (TOF) MS are shown in FIG. 18.

FIG. 18 shows that product ions of [Ir(mpCzptz-dmp)₃], which is the organometallic complex of one embodiment of the present invention represented by Structural Formula (115), are mainly detected around m/z=1199.41 and m/z=505.24. The results in FIG. 18 show characteristics derived from [Ir(mpCzptz-dmp)₃] and therefore can be regarded as important data for identifying [Ir(mpCzptz-dmp)₃] contained in a mixture.

It is presumed that the product ion around m/z=1199.41 is a cation in a state where the ligand HmpCzptz-dmp is eliminated from the compound represented by Structural Formula (115) and the product ion around m/z=505.24 is a cation in a state where a proton was added to the ligand HmpCzptz-dmp, and this is characteristic of the organometallic complex of one embodiment of the present invention.

Next, [Ir(mpCzptz-dmp)₃] was subjected to electrochemical measurement by cyclic voltammetry.

For the electrochemical measurement, an electrochemical analyzer ALS 600 produced by BAS Inc., a platinum wire working electrode, a platinum wire counter electrode, and an Ag/Ag⁺ reference electrode were used. Before the measurement, a DMF solvent to which tetrabutylammonium salt that was a supporting electrolyte was added at a concentration of 10 mM was put into an electrochemical cell, the sample was added at a concentration of 2 mM, and then, argon bubbling was performed for degasification.

A HOMO level E_{HOMO} is calculated semiempirically by the following expression using the half-wave potential of the first oxidation wave E₁^{Ox1} obtained by electrochemical measurement (standard: ferrocene).

E_{HOMO} [eV]=−4.94−E_{1/2}^{Ox1} [V vs. Fc/Fc⁺]

The first oxidation potential E_{1/2}^{Ox1} of [Ir(mpCzptz-dmp)₃] obtained using ferrocene as a standard is 0.54 V (Fc/Fc⁺), and the HOMO level thereof can be calculated to be −5.48 eV from the above potential difference. It is thus found that [Ir(mpCzptz-dmp)₃] that is the organometallic complex of one embodiment of the present invention has deep HOMO.

### Example 3

### Synthesis Example 3

In Synthesis Example 3, a synthesis example of tris{5-(9H-carbazol-9-yl)-2-[5-(2-methylphenyl)-4-(2,6-diisopropylphenyl)-4H-1,2,4-triazol-3-yl-κN2]phenyl-κC}iridium(III) (abbreviation: [Ir(mpCzptz-diPrp)₃]), which is the organometallic complex of one embodiment of the present invention represented by Structural Formula (116) in the embodiment, is specifically described. A structural formula of [Ir(mpCzptz-diPrp)₃] is shown below.

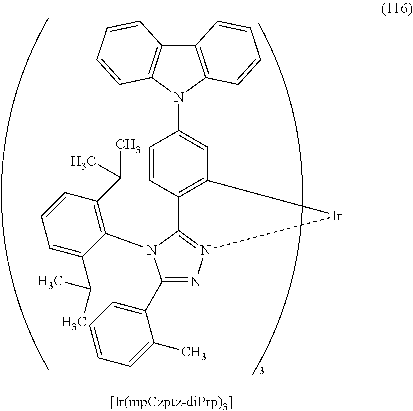

### Step 1: Synthesis of 3-(4-bromophenyl)-5-(2-methylphenyl)-4-(2,6-diisopropylphenyl)-4H-1,2,4-triazole

Into a 200-mL three-neck flask were put 10 g (27 mmol) of N-(4-bromophenyl)chloromethylidene-N′-(2-methylphenyl)chloromethylidenehydrazine obtained in Step 2 of Synthesis Example 2, 14 g (81 mmol) of 2,6-diisopropylaniline, and 60 mL of N,N-dimethylaniline, and the mixture was heated with stirring at 180° C. for 24 hours. After reaction for the predetermined time, this reaction solution was slowly poured into 500 mL of 1M hydrochloric acid, and the mixture was stirred at room temperature for 30 minutes to precipitate a solid. This solid was collected by filtration and recrystallization was performed using ethyl acetate and hexane; thus, 3-(4-bromophenyl)-5-(2-methylphenyl)-4-(2,6-diisopropylphenyl)-4H-1,2,4-triazole was obtained as 8.3 g of a white solid in a yield of 55%. The synthesis scheme of Step 1 is shown in (3-1).

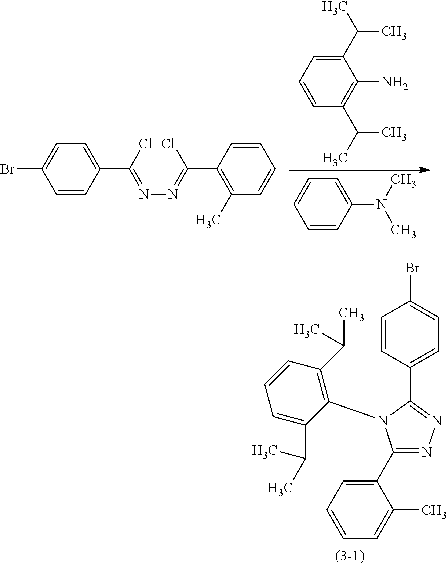

### Step 2: Synthesis of 3-[4-(9H-carbazol-9-yl)phenyl]-5-(2-methylphenyl)-4-(2,6-diisopropylphenyl)-4H-1,2,4-triazole (abbreviation: HmpCzptz-diPrp)

Into a 100-mL three-neck flask were put 4.0 g (8.4 mmol) of 3-(4-bromophenyl)-5-(2-methylphenyl)-4-(2,6-diisopropylphenyl)-4H-1,2,4-triazole obtained in Step 1, 4.2 g (25.2 mmol) of 9H-carbazole, 0.9 g (5.0 mmol) of 1,10-phenanthroline, 0.5 g (2.5 mmol) of copper iodide, 16.3 g (50.0 mmol) of cesium carbonate, and 15 mL of N,N-dimethylformamide, and the mixture was heated with stirring at 150° C. for 16 hours. After reaction for the predetermined time, the reaction solution was filtered to remove an insoluble matter. Chloroform was added to the filtrate and the mixture was washed with saturated brine and pure water. An organic layer was collected and dried with magnesium sulfate and then the solvent was distilled off, so that a black solid was obtained. This solid was purified by silica gel column chromatography. As a developing solvent, a mixed solvent of hexane and ethyl acetate in a ratio of 4:1 was used. The obtained fraction was concentrated to give a white solid. Recrystallization was performed with the use of a mixed solvent of ethyl acetate and hexane, so that 3-[4-(9H-carbazol-9-yl)phenyl]-5-(2-methylphenyl)-4-(2,6-diisopropylphenyl)-4H-1,2,4-triazole (abbreviation: HmpCzptz-diPrp) was obtained as 2.8 g of a white solid in a yield of 33%. The synthesis scheme of Step 2 is shown in (3-2).

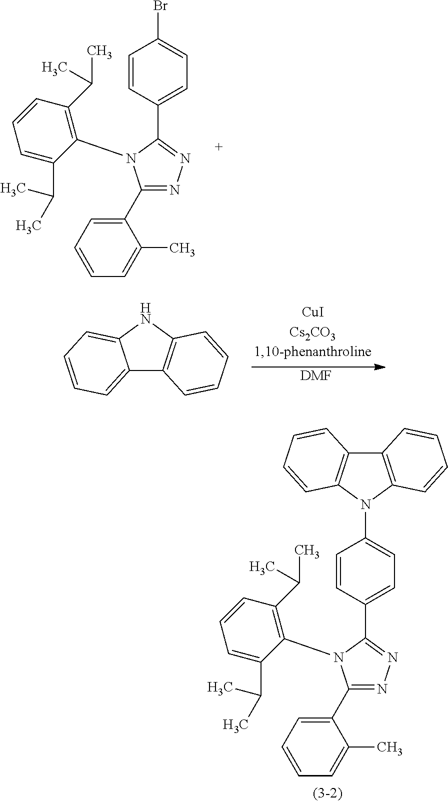

### Step 3: Synthesis of tris{5-(9H-carbazol-9-yl)-2-[5-(2-methylphenyl)-4-(2,6-diisopropylphenyl)-4H-1,2,4-triazol-3-yl-κN2]phenyl-κC}iridium(III) (abbreviation: [Ir(mpCzptz-diPrp)₃])

Into a container for high-temperature heating were put 1.4 g (2.5 mmol) of HmpCzptz-diPrp and 0.25 g (0.5 mmol) of tris(acetylacetonato)iridium(III), and the mixture was heated with stirring at 250° C. for 48 hours. After reaction for the predetermined time, the reaction mixture was dissolved in dichloromethane and purification by silica gel chromatography was performed. As a developing solvent, a mixed solvent of hexane and ethyl acetate in a ratio of 1:4 was used. The obtained fraction was concentrated to give a yellow solid. This solid was recrystallized with a mixed solvent of ethyl acetate and hexane, so that [Ir(mpCzptz-diPrp)₃] was obtained as 0.1 g of a yellow solid in a yield of 11%. The synthesis scheme of Step 3 is shown in (3-3).

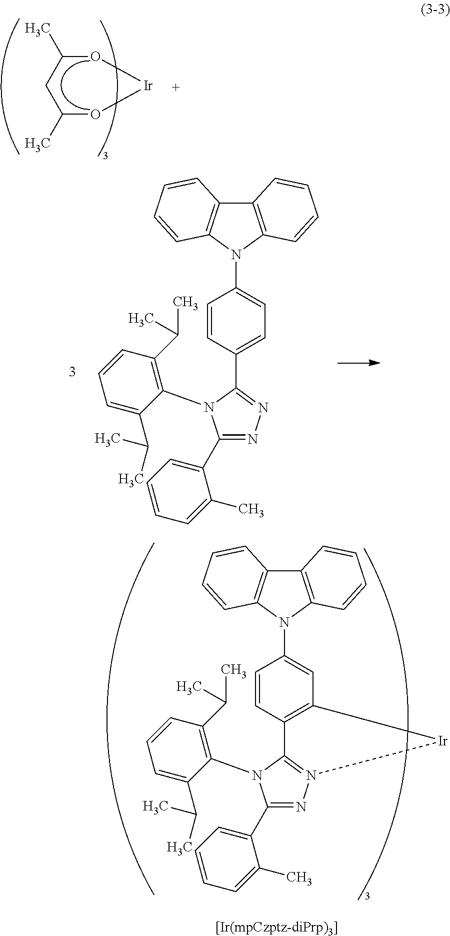

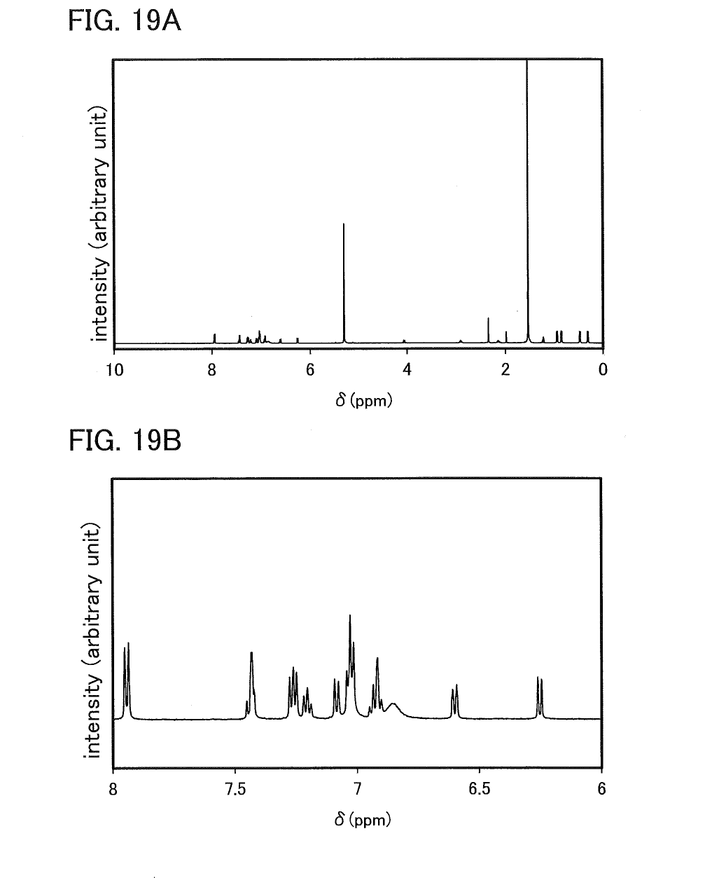

Analysis results by nuclear magnetic resonance (¹H-NMR) spectroscopy of the yellow solid obtained in Step 3 are described below. FIGS. 19A and 19B show the ¹H-NMR charts. Note that FIG. 19B is an enlarged chart showing a range of 6.0 ppm to 8.0 ppm in FIG. 19A. These results revealed that [Ir(mpCzptz-diPrp)₃], which is the organometallic complex of one embodiment of the present invention represented by Structural Formula (116), was obtained in Synthesis Example 3.

¹H-NMR. δ (CD₂Cl₂): 0.29 (d, 9H), 0.46 (d, 9H), 0.84 (d, 9H), 0.92 (d, 9H), 2.12-2.16 (m, 3H), 2.34 (s, 9H), 2.88-2.92 (m, 3H), 6.24 (d, 3H), 6.60 (d, 3H), 6.89-6.94 (m, 15H), 6.94-7.08 (m, 18H), 7.18-7.27 (m, 9H), 7.42 (d, 6H), 7.94 (d, 6H).

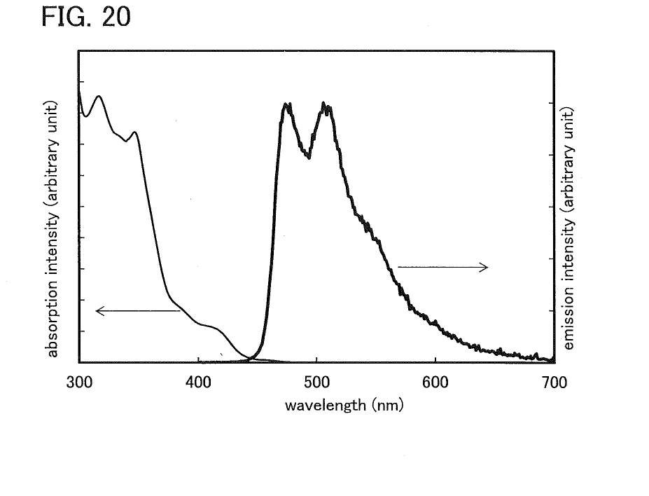

Next, analysis of [Ir(mpCzptz-diPrp)₃] was conducted by ultraviolet-visible (UV) absorption spectroscopy. A UV spectrum was measured with an ultraviolet-visible spectrophotometer (V-550, manufactured by JASCO Corporation) using a dichloromethane solution (0.069 mmol/L) at room temperature. In addition, an emission spectrum of [Ir(mpCzptz-diPrp)₃] was measured using a fluorescence spectrophotometer (FS920 manufactured by Hamamatsu Photonics K.K.) and a degassed dichloromethane solution (0.069 mmol/L) at room temperature. FIG. 20 shows the measurement results. The horizontal axis represents wavelength and the vertical axes represent absorption intensity and emission intensity.

As shown in FIG. 20, [Ir(mpCzptz-diPrp)₃], which is the organometallic complex of one embodiment of the present invention, has emission peaks at 476 nm and 506 nm, and blue green light emission was observed from the dichloromethane solution.

Next, [Ir(mpCzptz-diPrp)₃] was subjected to electrochemical measurement by cyclic voltammetry.

For the electrochemical measurement, an electrochemical analyzer ALS 600 produced by BAS Inc., a platinum wire working electrode, a platinum wire counter electrode, and an Ag/Ag⁺ reference electrode were used. Before the measurement, a DMF solvent to which tetrabutylammonium salt that was a supporting electrolyte was added at a concentration of 10 mM was put into an electrochemical cell, the sample was added at a concentration of 2 mM, and then, argon bubbling was performed for degasification.

A HOMO level E_{HOMO} is calculated semiempirically by the following expression using the half-wave potential of the first oxidation wave E_{1/2}^{Ox1} obtained by electrochemical measurement (standard: ferrocene).

E_{HOMO} [eV]=−4.94−E_{1/2}^{Ox1}[V vs. Fc/Fc⁺]

The first oxidation potential E_{1/2}^{Ox1} of [Ir(mpCzptz-diPrp)₃] obtained using ferrocene as a standard is 0.54 V (Fc/Fc⁺), and the HOMO level thereof can be calculated to be −5.48 eV from the above potential difference. It is thus found that [Ir(mpCzptz-diPrp)₃] that is the organometallic complex of one embodiment of the present invention has deep HOMO.

### Example 4

In Example 4, calculated energy levels of molecular orbitals are described. Calculation results for tris[5-(9H-carbazol-9-yl)-2-(5-methyl-4-phenyl-4H-1,2,4-triazol-3-yl-κN2)phenyl-κC]iridium(III) (abbreviation: [Ir(MCzptz)₃]), which is the organometallic complex of one embodiment of the present invention represented by Structural Formula (100), are described in this example. Note that for comparison, calculation was also performed for tris(5-methyl-3,4-diphenyl-4H-1,2,4-triazolato)iridium(III) (abbreviation: [Ir(Mptz)₃]), which is an organometallic complex represented by Structural Formula (001). Structural formulae of [Ir(MCzptz)₃] and [Ir(Mptz)₃] are shown below.

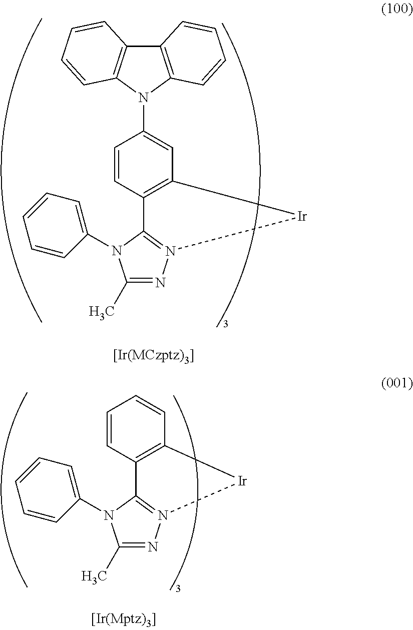

### Calculation Example

First, the most stable structures of the organometallic complex [Ir(MCzptz)₃] that is one embodiment of the present invention and the comparative organometallic complex [Ir(Mptz)₃] in the singlet ground state (S0) were calculated using the density functional theory (DFT). In the DFT, the total energy is represented as the sum of potential energy, electrostatic energy between electrons, electronic kinetic energy, and exchange-correlation energy including all the complicated interactions between electrons. Also in the DFT, since an exchange-correlation interaction is approximated by a functional (a function of another function) of one electron potential represented in terms of electron density, calculations are performed at high speed. Here, B3PW91, which is a hybrid functional, was used to specify the weight of each parameter related to exchange-correlation energy.

As basis functions, 6-311G (a basis function of a triple-split valence basis set using three contraction functions for a valence orbital) was applied to each of H, C, and N atoms, and LanL2DZ was applied to an Ir atom. By the above basis function, for example, orbits of is to 3s are considered in the case of hydrogen atoms while orbits of 1s to 4s and 2p to 4p are considered in the case of carbon atoms. Furthermore, to improve calculation accuracy, the p function and the d function, respectively, were added as polarization basis sets to hydrogen atoms and atoms other than hydrogen atoms. Note that Gaussian 09 was used as a quantum chemistry computational program. A high performance computer (manufactured by SGI Japan, Ltd.) was used for the calculation.

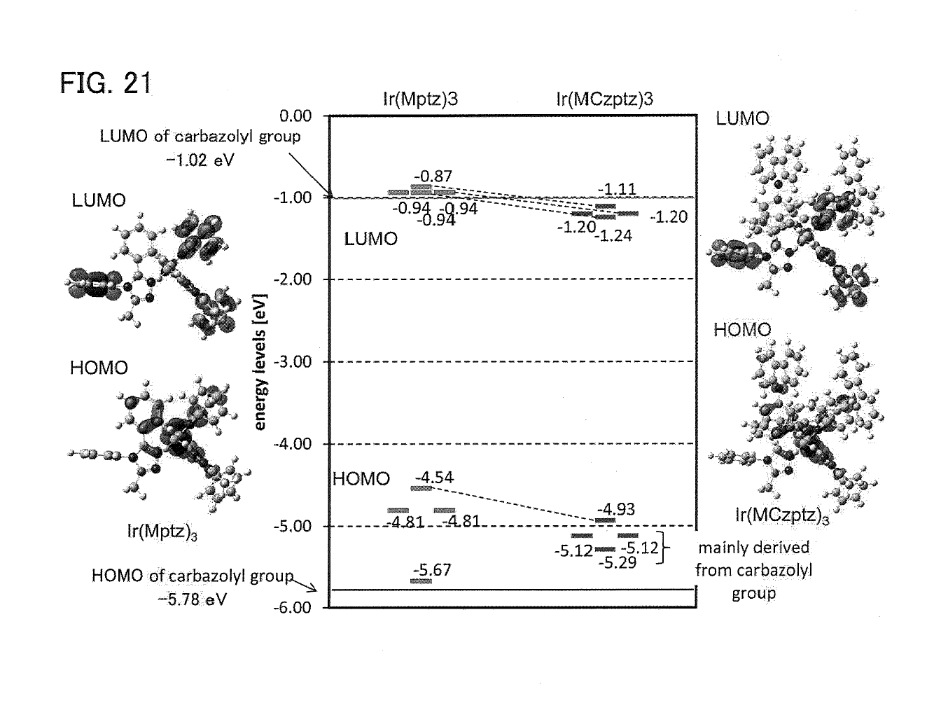

FIG. 21 shows calculation results of energy levels of molecular orbitals and distribution of HOMO and LUMO of the organometallic complex [Ir(MCzptz)₃] that is one embodiment of the present invention and the comparative organometallic complex [Ir(Mptz)₃].

As shown in FIG. 21, the HOMO of [Ir(MCzptz)₃] where the N-carbazolyl group is bonded to the phenyl group on which iridium is ortho-metalated is −4.93 eV, whereas the HOMO of [Ir(Mptz)₃] is −4.54 eV. Comparison between the energy levels of the molecular orbitals of these two substances shows that the substitution with the N-carbazolyl group leads to deeper HOMO. The LUMO of [Ir(MCzptz)₃] is also as deep as −1.24 eV, whereas the LUMO of [Ir(Mptz)₃] is −0.94 eV.

As the distribution of the molecular orbitals shows, HOMO of [Ir(MCzptz)₃] that is one embodiment of the present invention is hardly distributed over the carbazolyl group.

It is thus found that the organometallic complex [Ir(MCzptz)₃] that is one embodiment of the present invention has deeper HOMO than [Ir(Mptz)₃]. In other words, when an N-carbazolyl group is bonded to a phenyl group on which iridium is ortho-metalated in an organometallic complex with shallow HOMO such as [Ir(Mptz)₃], the organometallic complex can have deeper HOMO.

### Example 5

In this example, light-emitting elements of embodiments of the present invention (Light-emitting element 1 and Light-emitting element 2) are described. Structure formulae of organic compounds used for Light-emitting element 1 and Light-emitting element 2 are shown below.

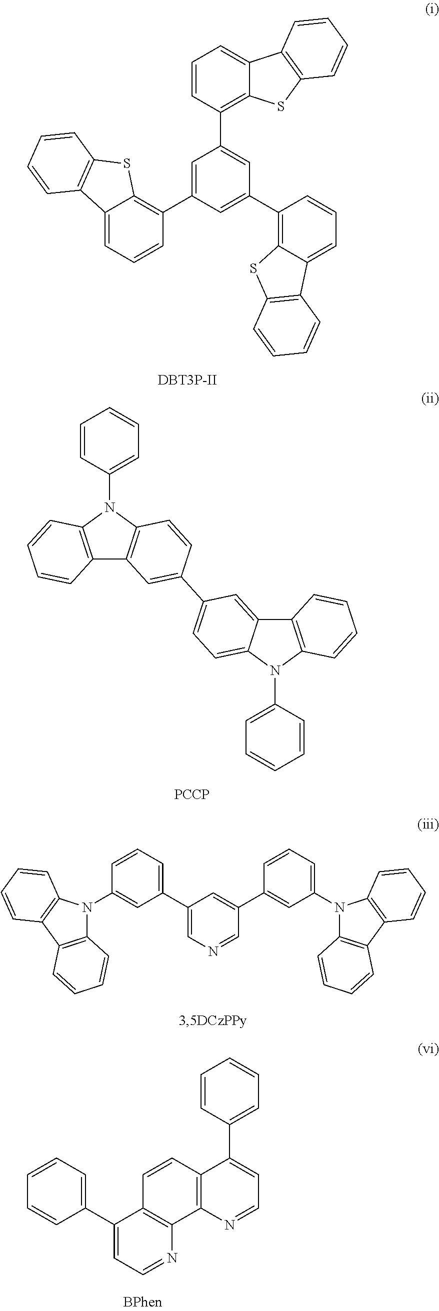

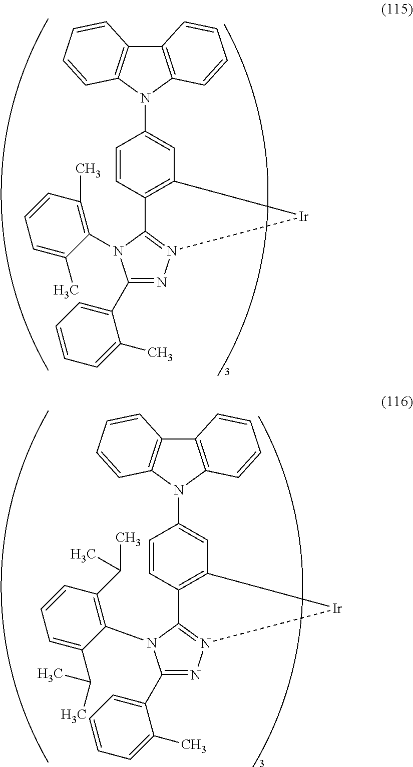

### (Method for Manufacturing Light-Emitting Element 1)

First, a film of indium tin oxide containing silicon oxide (ITSO) was formed over a glass substrate by a sputtering method, so that the first electrode 101 was formed. The thickness of the first electrode 101 was set to 110 nm and the area of the electrode was set to 2 mm×2 mm. Here, the first electrode 101 is an electrode that functions as an anode of the light-emitting element.

Next, in pretreatment for forming the light-emitting element over the substrate, a surface of the substrate was washed with water and baked at 200° C. for 1 hour, and then UV ozone treatment was performed for 370 seconds.

Then, the substrate was transferred into a vacuum evaporation apparatus whose pressure was reduced to approximately 10⁻⁴ Pa, vacuum baking at 170° C. for 30 minutes was performed in a heating chamber of the vacuum evaporation apparatus, and then the substrate was cooled down for approximately 30 minutes.

Then, the substrate over which the first electrode 101 was formed was fixed to a substrate holder provided in the vacuum evaporation apparatus so that the surface on which the first electrode 101 was formed faced downward. The pressure in the vacuum evaporation apparatus was reduced to approximately 10⁻⁴ Pa. After that, over the first electrode 101, 4,4′,4″-(benzene-1,3,5-triyl)tri(dibenzothiophene) (abbreviation: DBT3P-II) represented by Structural Formula (i) above and molybdenum(VI) oxide were deposited by co-evaporation by an evaporation method using resistance heating, so that the hole-injection layer 111 was formed. The thickness of the hole-injection layer 111 was set to 60 nm, and the weight ratio of DBT3P-II to molybdenum oxide was adjusted to 4:2 (=DBT3P-II: molybdenum oxide).

Next, a film of 3,3′-bis(9-phenyl-9H-carbazole) (abbreviation: PCCP) represented by Structural Formula (ii) above was formed to a thickness of 20 nm over the hole-injection layer 111 to form the hole-transport layer 112.

Then, PCCP, 3,5-[bis(9H-carbazol-9-yl)phenyl]pyridine (abbreviation: 35DCzPPy) represented by Structural Formula (iii), and tris{5-(9H-carbazol-9-yl)-2-[5-(2-methylphenyl)-4-(2,6-dimethylphenyl)-4H-1,2,4-triazol-3-yl-κN2]phenyl-κC}iridium(III) (abbreviation: [Ir(mpCzptz-dmp)₃]) represented by Structural Formula (115) were deposited by co-evaporation to a thickness of 30 nm over the hole-transport layer 112 so that PCCP:35DCzPPy:[Ir(mpCzptz-dmp)₃]=1:0.3:0.06 (weight ratio), and then, 35DCzPPy and [Ir(mpCzptz-dmp)₃] were deposited by co-evaporation to a thickness of 10 nm so that 35DCzPPy:[Ir(mpCzptz-dmp)₃]=1:0.06 (weight ratio), whereby the light-emitting layer 113 was formed.

Then, over the light-emitting layer 113, a film of 35DCzPPy was formed to a thickness of 10 nm, and a film of bathophenanthroline (abbreviation: BPhen) represented by Structural formula (vi) was formed to a thickness of 15 nm to form the electron-transport layer 114.

After the formation of the electron-transport layer 114, lithium fluoride (LiF) was deposited by evaporation to a thickness of 1 nm to form the electron-injection layer 115. Finally, aluminum was deposited by evaporation to a thickness of 200 nm to form the second electrode 102 functioning as a cathode. Through the above-described steps, Light-emitting element 1 of this example was fabricated.

The element structure of Light-emitting element 1 is shown in Table 1.

TABLE 1

| Hole- | | | | | | |
|---|---|---|---|---|---|---|
| injection | Hole- | Light-emitting layer | | | | Electron- |
| layer | transport | PCCP:35DCzPPy:[Ir(mpCzptz- | 35DCzPPy:[Ir(mpCzptz- | Electron-transport | | injection |
| DBT3P-II:MoOₓ | layer | dmp)₃] | dmp)₃] | layer | | layer |
| (4:2) | PCCP | (1:0.3:0.06) | (1:0.06) | 35DCzPPy | BPhen | LiF |
| 60 nm | 20 nm | 30 nm | 10 nm | 10 nm | 15 nm | 1 nm |

### (Method for Fabricating Light-Emitting Element 2)

Light-emitting element 2 was fabricated in the same manner as Light-emitting element 1 except that [Ir(mpCzptz-dmp)₃] in Light-emitting element 1 was replaced with tris{5-(9H-carbazol-9-yl)-2-[5-(2-methylphenyl)-4-(2,6-diisopropylphenyl)-4H-1,2,4-triazol-3-yl-κN2]phenyl-κC}iridium(III) (abbreviation: [Ir(mpCzptz-diPrp)₃]) represented by Structural Formula (116).

The element structure of Light-emitting element 2 is shown in Table 2.

TABLE 2

| Hole- | | | | | | |
|---|---|---|---|---|---|---|
| injection | Hole- | Light-emitting layer | | | | Electron- |
| layer | transport | PCCP:35DCzPPy:[Ir(mpCzptz- | 35DCzPPy:[Ir(mpCzptz- | Electron-transport | | injection |
| DBT3P-II:MoOₓ | layer | diPrp)₃] | diPrp)₃] | layer | | layer |
| (4:2) | PCCP | (1:0.3:0.06) | (1:0.06) | 35DCzPPy | BPhen | LiF |

| | | | | | | |
|---|---|---|---|---|---|---|
| 60 nm | 20 nm | 30 nm | 10 nm | 10 nm | 15 nm | 1 nm |

Light-emitting elements 1 and 2 were each sealed using a glass substrate in a glove box containing a nitrogen atmosphere so as not to be exposed to the air (specifically, a sealing material was applied to surround the element and UV treatment and heat treatment at 80° C. for 1 hour were performed at the time of sealing). Then, the initial characteristics of these light-emitting elements were measured. Note that the measurement was performed at room temperature (in an atmosphere kept at 25° C.).

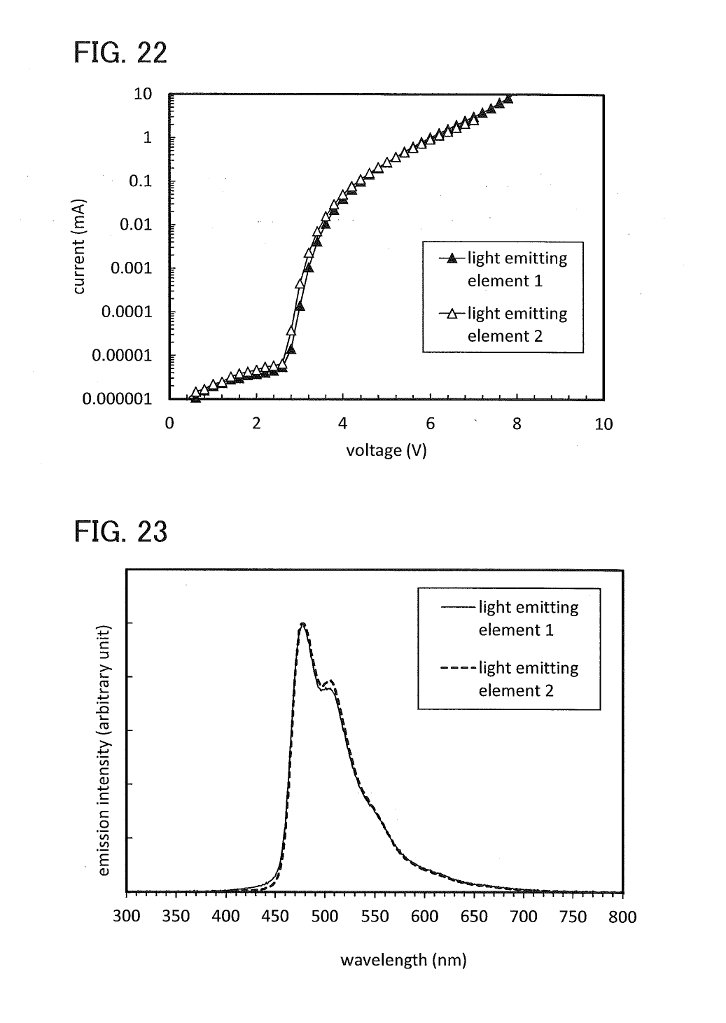

FIG. 22 shows voltage-current characteristics of Light-emitting elements 1 and 2. FIG. 23 shows emission spectra thereof. The results show that Light-emitting elements 1 and 2 both have favorable voltage-current characteristics.

### Comparative Example

In Comparative Example, an absorption spectrum, an emission spectrum, and electrochemical measurement results for tris[3-(5-methyl-4-phenyl-4H-1,2,4-triazol-3-yl-κN2)-9-phenyl-9H-carbazol-2-yl-κC]iridium(III) (abbreviation: [Ir(Mpcztz)₃]), which has a structure similar to that of [Ir(MCzptz)₃], are shown. A structural formula of [Ir(Mpcztz)₃] is shown below.

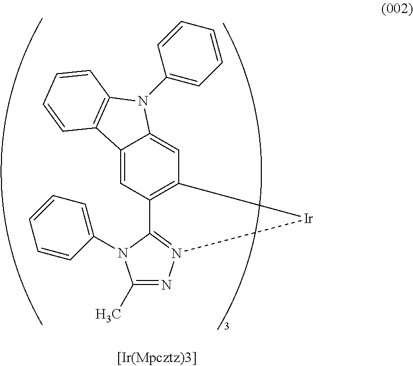

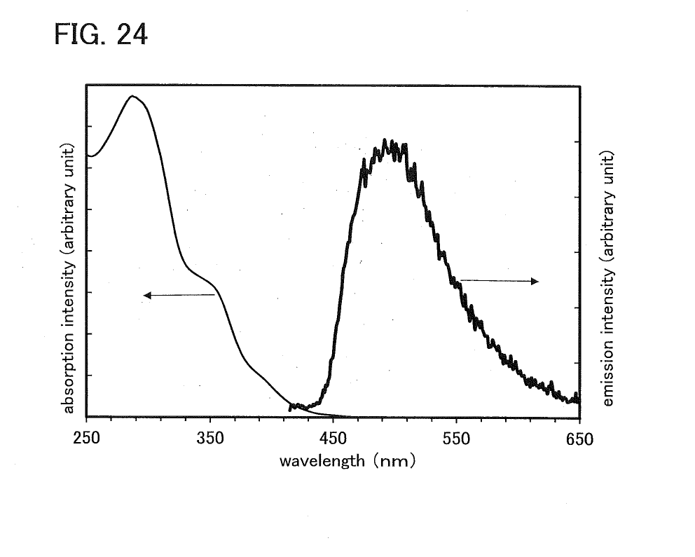

An ultraviolet-visible absorption spectrum (hereinafter, simply referred to as an absorption spectrum) and an emission spectrum of a dichloromethane solution of [Ir(Mpcztz)₃] were measured. The absorption spectrum was measured with the use of an ultraviolet-visible spectrophotometer (V-550, manufactured by JASCO Corporation) in the state where the dichloromethane solution (0.050 mmol/L) was put in a quartz cell at room temperature. The emission spectrum was measured with the use of a fluorescence spectrophotometer (FS920 manufactured by Hamamatsu Photonics K.K.) in the state where the degassed dichloromethane solution (0.050 mmol/L) was put in a quartz cell at room temperature. FIG. 24 shows measurement results of the absorption spectrum and emission spectrum. The horizontal axis represents wavelength and the vertical axes represent absorption intensity and emission intensity. FIG. 24 shows two solid lines: the thin solid line represents the absorption spectrum and the thick solid line represents the emission spectrum. Note that the absorption spectrum in FIG. 24 is the results obtained in such a way that the absorption spectrum measured by putting only dichloromethane in a quartz cell was subtracted from the absorption spectrum measured by putting the dichloromethane solution in a quartz cell.

As shown in FIG. 24, [Ir(Mpcztz)₃] has an emission peak at 492 nm, and green light was observed from the dichloromethane solution. The above results show that although [Ir(Mpcztz)₃] has a structure similar to that of [Ir(MCzptz)₃], there is a big difference in their characteristics that is caused by the position and orientation of the carbazolyl group, and that the emission color has a longer wavelength when iridium is ortho-metalated at the 2-position of the carbazolyl group as in [Ir(Mpcztz)₃].

Next, [Ir(Mpcztz)₃] obtained in Comparative Example was subjected to electrochemical measurement by cyclic voltammetry.

For the electrochemical measurement, an electrochemical analyzer ALS 600 produced by BAS Inc., a platinum wire working electrode, a platinum wire counter electrode, and an Ag/Ag⁺ reference electrode were used. Before the measurement, a DMF solvent to which tetrabutylammonium salt that was a supporting electrolyte was added at a concentration of 10 mM was put into an electrochemical cell, the sample was added at a concentration of 1 mM, and then, argon bubbling was performed for degasification.

A HOMO level E_{HOMO} is calculated semiempirically by the following expression using the half-wave potential of the first oxidation wave E_{1/2}^{Ox1} obtained by electrochemical measurement (standard: ferrocene).

E_{HOMO} [eV]=−4.94−E_{1/2}^{Ox1}[V vs. Fc/Fc⁺]

The first oxidation potential E_{1/2}^{Ox1} of [Ir(Mpcztz)₃] obtained using ferrocene as a standard is 0.16 V (Fc/Fc⁺), and the HOMO level thereof can be calculated to be −5.10 eV from the above potential difference. The above results show that although [Ir(Mpcztz)₃] has a structure similar to that of [Ir(MCzptz)₃], there is a big difference in their characteristics that is caused by the position and orientation of the carbazolyl group, and that the organometallic complex in which iridium is ortho-metalated at the 2-position of the carbazolyl group has extremely shallow HOMO.

Note that [Ir(Mpcztz)₃] for comparison is also a novel substance; thus, its synthesis method is described below.

### Synthesis Example

In this comparative synthesis example, a synthesis example of tris[3-(5-methyl-4-phenyl-4H-1,2,4-triazol-3-yl-κN2)-9-phenyl-9H-carbazol-2-yl-κC]iridium(III) (abbreviation: [Ir(Mpcztz)₃]), which is an organometallic complex represented by Structural Formula (002), is specifically described.

### Step 1: Synthesis of ethyl 4-(phenylamino)benzoate

Into a three-neck flask equipped with a reflux pipe were put 25 g of ethyl 4-bromobenzoate, 12 g of aniline, 1.5 g of palladium acetate, 0.98 g of rac-BINAP, 45 g of potassium carbonate, and 68 mL of toluene, argon bubbling was performed, and irradiation with microwaves (2.45 GHz, 400 W) was performed for 1 hour. To this mixture, 0.90 g of rac-BINAP was added, and irradiation with microwaves (2.45 GHz, 400 W) was performed for 2 hours. The reactant was divided into two and put into airtight containers. First, one of the reaction containers was irradiated with microwaves (2.45 GHz, 400 W) for 2 hours. Furthermore, 0.51 g of (R)-BINAP was added, and irradiation with microwaves (2.45 GHz, 400 W) was performed for 1 hour. Then, 0.72 g of (R)-BINAP and 0.32 g of palladium acetate were added to the other reaction container, and irradiation with microwaves (2.45 GHz, 400 W) was performed for 3 hours. The reactants in the two containers were combined and filtered. The obtained residue was dissolved in dichloromethane and the solution was filtered. The solvent in the filtrate was distilled off, and the obtained residue was dissolved in ethyl acetate. The resulting solution was washed with a saturated aqueous solution of sodium hydrogen carbonate and saturated brine, magnesium sulfate was added, and filtration was performed. The solvent in the filtrate was distilled off, and purification was performed by silica gel column chromatography using a mixed solvent of ethyl acetate and hexane in a ratio of 1:5 as a developing solvent; thus, an objective substance was obtained as a pale yellow solid in a yield of 32%. Note that the irradiation with microwaves was performed using a microwave synthesis system (MicroSYNTH, manufactured by MILESTONE Inc.). The synthesis scheme of Step 1 is shown below.

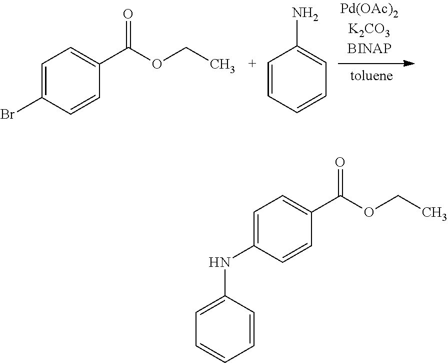 [SMILES: CCOC(=O)c1ccc(Br)cc1 ; NC1=CC=CC=[C+]1 ; CCOC(=O)c1ccc(Nc2ccccc2)cc1]

### Step 2: Synthesis of ethyl 9H-carbazole-3-carboxylate

Then, 8.5 g of ethyl 4-(phenylamino)benzoate obtained in Step 1, 8.7 g of palladium acetate, and 200 mL of glacial acetic acid were put into a three-neck flask equipped with a reflux pipe, the air in the flask was replaced with nitrogen, and the mixture was refluxed for 1 hour. Dichloromethane was added to the resulting mixture, and filtration was performed. This filtrate was subjected to extraction using dichloromethane as an extracting solvent and the separated organic layer was washed with a saturated aqueous solution of sodium hydrogen carbonate. Magnesium sulfate was added and filtration was performed. The solvent in the filtrate was distilled off and purification was performed by flash column chromatography using a mixed solvent of ethyl acetate and hexane in a ratio of 1:5 as a developing solvent; thus, an objective substance was obtained as a yellow oily substance in a yield of 22%. The synthesis scheme of Step 2 is shown below.

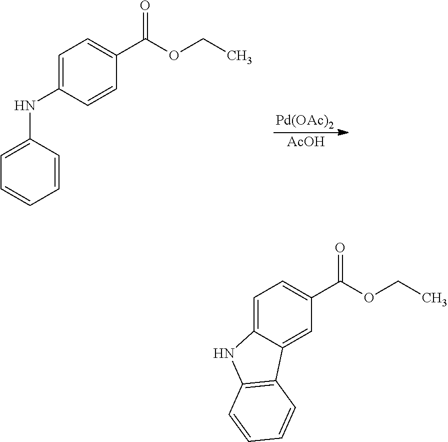 [SMILES: "AcOH" ; CCOC(=O)c1ccc(Nc2ccccc2)cc1 ; CCOC(=O)c1ccc2[nH]c3ccccc3c2c1 ; "Pd(OAc)2"]

### Step 3: Synthesis of ethyl 9-phenyl-9H-carbazole-3-carboxylate

Next, 1.5 g of ethyl 9H-carbazole-3-carboxylate obtained in Step 2, 1.0 g of bromo benzene, 13 g of potassium phosphate, 260 mg of copper iodide, 0.5 mL of N,N-dimethylethylenediamine (DMEDA), and 85 mL of dioxane were put into a three-neck flask equipped with a reflux pipe, the air in the flask was replaced with nitrogen, and the mixture was heated at 120° C. for 48 hours. Furthermore, 66 mg of copper iodide and 0.1 mL of DMEDA were added and the mixture was heated at 120° C. for 30 hours. Water and ethyl acetate were added to the obtained mixture and filtration was performed. This filtrate was subjected to extraction using ethyl acetate as an extracting solvent and the separated organic layer was washed with saturated brine. Magnesium sulfate was added and filtration was performed. The solvent in the filtrate was distilled off, and purification was performed by flash column chromatography using a mixed solvent of ethyl acetate and hexane in a ratio of 1:5 as a developing solvent, whereby an objective substance was obtained as a yellowish white solid in a yield of 60%. The synthesis scheme of Step 3 is shown below.

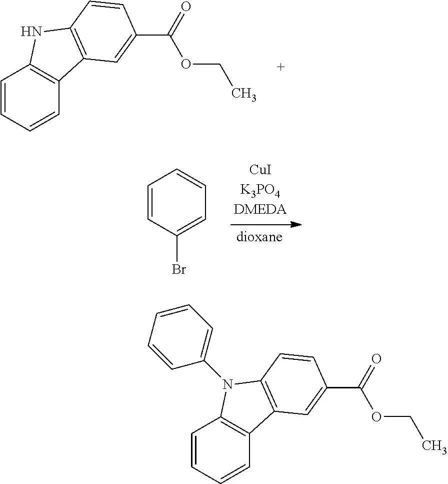

### Step 4: Synthesis of 9-phenyl-9H-carbazole-3-carbohydrazide

Then, 1.3 g of ethyl 9-phenyl-9H-carbazole-3-carboxylate obtained in Step 3 was put into a three-neck flask equipped with a reflux pipe and 13 mL of hydrazine hydrate was added dropwise while stirring was performed. This mixture was heated at 90° C. for 1 hour. Ethanol and 10 mL of hydrazine hydrate were added, and the mixture was heated at 80° C. for 1 hour and 50 minutes. Furthermore, 10 mL of ethanol was added and the mixture was stirred at 80° C. for 8 hours and 45 minutes. To the resulting mixture, 75 mL of water was added and suction filtration was performed. The residue was washed with ethanol to obtain an objective substance as a yellowish white solid in a yield of 96%. The synthesis scheme of Step 4 is shown below.

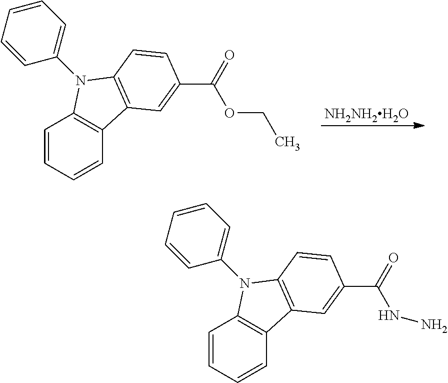

### Step 5: Synthesis of 3-(5-methyl-4-phenyl-4H-1,2,4-triazol-3-yl)-9-phenyl-9H-carbazole (abbreviation: HMpcztz)

Then, 1.0 g of 9-phenyl-9H-carbazole-3-carbohydrazide obtained in Step 4, 0.52 g of thioacetanilide, and 16 mL of 1-butanol were put into a three-neck flask equipped with a reflux pipe and heated at 130° C. for 23 hours. Furthermore, 10 mL of 1-butanol was added and the mixture was heated at 130° C. for 18 hours. The obtained mixture was dissolved in ethyl acetate and the solvent was distilled off. The obtained residue was purified by flash column chromatography using a mixed solvent of ethyl acetate and toluene in a ratio of 1:10 as a developing solvent, whereby an objective substance was obtained as a yellow oily substance in a yield of 60%. The synthesis scheme of Step 5 is shown below.

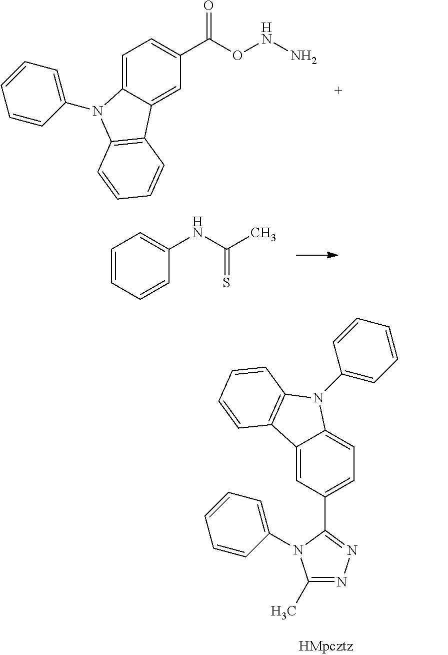

### Step 6: Synthesis of tris[3-(5-methyl-4-phenyl-4H-1,2,4-triazol-3-yl-κN2)-9-phenyl-9H-carbazol-2-yl-κC]iridium(III) (abbreviation: [Ir(Mpcztz)₃])

Next, 0.84 g of HMpcztz (abbreviation) obtained in Step 5 and 0.35 g of tris(acetylacetonato)iridium(III) (abbreviation: Ir(acac)₃) were put into a reaction container equipped with a three-way cock, the air in the container was replaced with nitrogen, and the mixture was heated at 250° C. for 40 hours. The resulting solid was dissolved in dichloromethane and purification was performed by flash column chromatography using a Biotage® SNAP KP-NH cartridge and ethyl acetate as a developing solvent. The resulting fraction was concentrated and purification was performed by flash column chromatography using a Biotage® SNAP KP-NH cartridge and dichloromethane as a developing solvent. The obtained fraction was concentrated and recrystallized with a mixed solvent of dichloromethane and hexane, whereby [Ir(Mpcztz)₃], which is the organometallic complex of one embodiment of the present invention, was obtained as a yellow solid in a yield of 5%. The synthesis scheme of Step 6 is shown below.

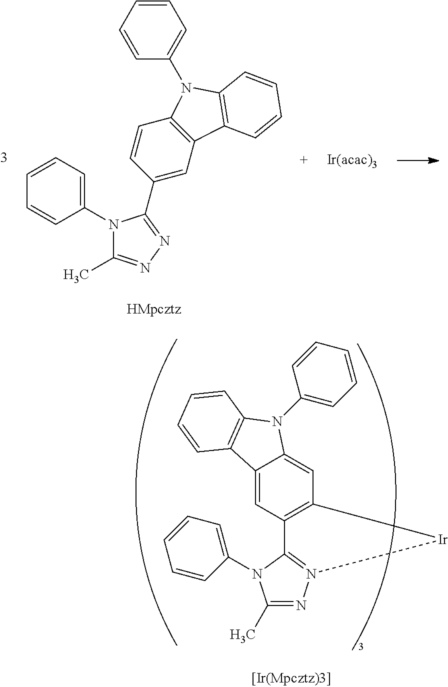

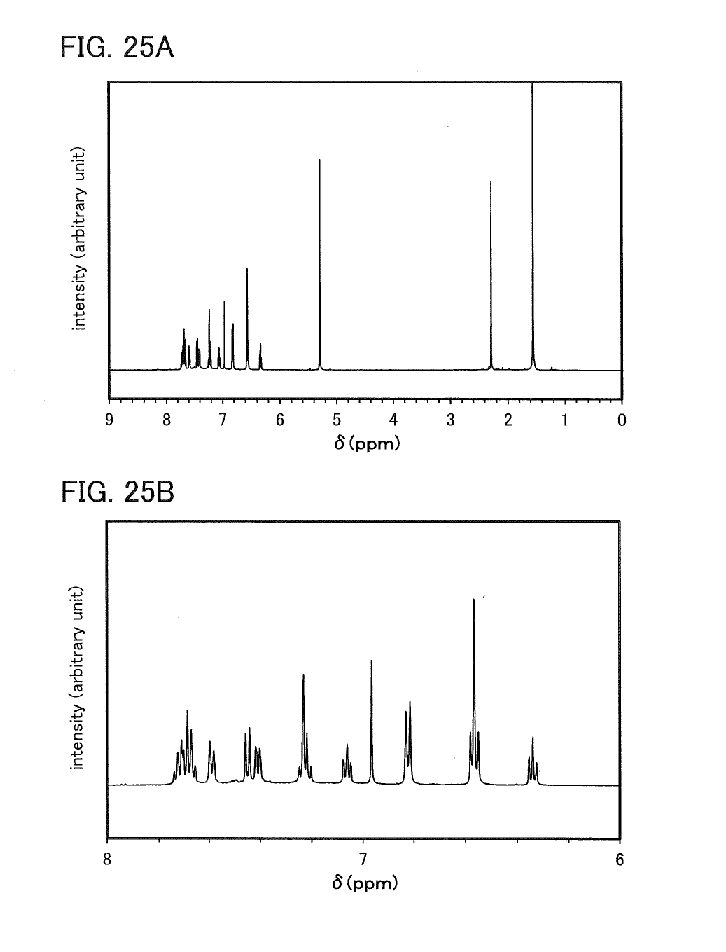

Analysis results by nuclear magnetic resonance (¹H-NMR) spectroscopy of the yellow solid obtained in Step 6 are described below. FIGS. 25A and 25B show the ¹H-NMR charts. Note that FIG. 25B is an enlarged chart showing a range of 6.0 ppm to 8.0 ppm in FIG. 25A. These results revealed that [Ir(Mpcztz)₃], which is the organometallic complex represented by Structural Formula (002), was obtained in this comparative synthesis example.

¹H-NMR. δ (CD₂Cl₂): 2.29 (s, 9H), 6.32-6.35 (t, 3H), 6.55-6.58 (t, 9H), 6.82 (d, 6H), 6.97 (s, 3H), 7.05-7.08 (t, 3H), 7.20-7.25 (m, 6H), 7.41 (d, 3H), 7.45 (d, 3H), 7.59 (d, 3H), 7.66-7.74 (m, 9H).

Next, mass spectrometry (MS) of [Ir(Mpcztz)₃] was carried out by liquid chromatography mass spectrometry (LC/MS).

In the analysis by LC/MS, liquid chromatography (LC) separation was carried out with ACQUITY UPLC (manufactured by Waters Corporation) and mass spectrometry (MS) analysis was carried out with Xevo G2 Tof MS (manufactured by Waters Corporation). ACQUITY UPLC BEH C8 (2.1×100 mm, 1.7 μm) was used as a column for the LC separation, and the column temperature was 40° C. Acetonitrile was used for Mobile Phase A and a 0.1% formic acid aqueous solution was used for Mobile Phase B. Further, a sample was prepared in such a manner that [Ir(Mpcztz)₃] was dissolved in chloroform at a given concentration and the mixture was diluted with acetonitrile. The injection amount was 5.0 μL.

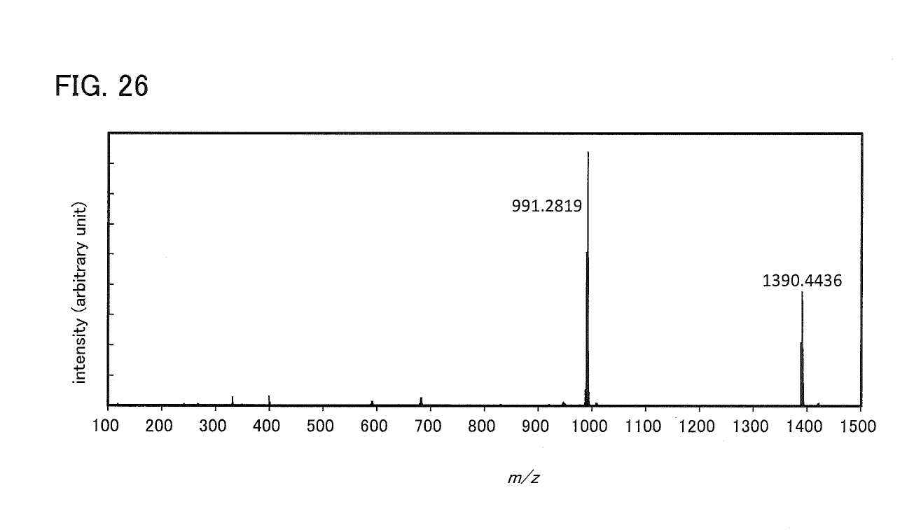

In the MS analysis, ionization was carried out by an electrospray ionization (ESI) method. At this time, the capillary voltage and the sample cone voltage were set to 3.0 kV and 30 V, respectively, and detection was performed in a positive mode. A component with m/z of 1390.44 which underwent the ionization under the above-described conditions was collided with an argon gas in a collision cell to dissociate into product ions. Energy (collision energy) for the collision with argon was 70 eV. The mass range for the measurement was m/z=100 to 1500. The detection results of the dissociated product ions by time-of-flight (TOF) MS are shown in FIG. 26.

FIG. 26 shows that product ions of [Ir(Mpcztz)₃] are mainly detected around m/z=991. The results in FIG. 26 show characteristics derived from [Ir(Mpcztz)₃] and therefore can be regarded as important data for identifying [Ir(Mpcztz)₃] contained in a mixture.

It is presumed that the product ion around m/z=991 is a cation in a state where the ligand HMpcztz is eliminated from [Ir(Mpcztz)₃], and this is characteristic of [Ir(Mpcztz)₃].

### REFERENCE NUMERALS

101: first electrode, 102: second electrode, 103: EL layer, 111: hole-injection layer, 112: hole-transport layer, 113: light-emitting layer, 114: electron-transport layer, 115: electron-injection layer, 400: substrate, 401: first electrode, 403: EL layer, 404: second electrode, 405: sealing material, 406: sealing material, 407: sealing substrate, 412: pad, 420: IC chip, 501: first electrode, 502: second electrode, 503: EL layer, 511: first light-emitting unit, 512: second light-emitting unit, 513: charge-generation layer, 601: driver circuit portion (source line driver circuit), 602: pixel portion, 603: driver circuit portion (gate line driver circuit), 604: sealing substrate, 605: sealing material, 607: space, 608: wiring, 609: flexible printed circuit (FPC), 610: element substrate, 611: switching FET, 612: current controlling FET, 613: first electrode, 614: insulator, 616: EL layer, 617: second electrode, 618: light-emitting element, 623: n-channel FET, 624: p-channel FET, 901: housing, 902: liquid crystal layer, 903: backlight unit, 904: housing, 905: driver IC, 906: terminal, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024W: first electrode of light-emitting element, 1024R: first electrode of light-emitting element, 1024G: first electrode of light-emitting element, 1024B: first electrode of light-emitting element, 1025: partition, 1028: EL layer, 1029: second electrode of light-emitting element, 1031: sealing substrate, 1032: sealing material, 1033: transparent base material, 1034R: red coloring layer, 1034G: green coloring layer, 1034B: blue coloring layer, 1035: black layer (black matrix), 1036: overcoat layer, 1037: third interlayer insulating film, 1040: pixel portion, 1041: driver circuit portion, 1042: peripheral portion, 2001: housing, 2002: light source, 3001: lighting device, 5000: display region, 5001: display region, 5002: display region, 5003: display region, 5004: display region, 5005: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: second display portion, 7401: housing, 7402: display portion, 7403: operation button, 7404: external connection port, 7405: speaker, 7406: microphone, 9033: clasp, 9034: switch, 9035: power switch, 9036: switch, 9630: housing, 9631: display portion, 9631a: display portion, 9631b: display portion, 9632a: touchscreen region, 9632b: touchscreen region, 9633: solar cell, 9634: charge and discharge control circuit, 9635: battery, 9636: DCDC converter, 9637: operation key, 9638: converter, and 9639: button.

This application is based on Japanese Patent Application serial no. 2014-151503 filed with Japan Patent Office on Jul. 25, 2014, the entire contents of which are hereby incorporated by reference.

1. An organometallic complex comprising:
a 1,2,4-triazole skeleton; and
an N-carbazolyl group bonded to a 3-position of the 1,2,4-triazole skeleton via a phenylene group,
wherein a phenyl group is bonded to a 4-position of the 1,2,4-triazole skeleton,
wherein a 2-position of the 1,2,4-triazole skeleton coordinates to iridium, and
wherein the phenylene group is bonded to the iridium.

2. A light-emitting element comprising the organometallic complex according to claim 1.

3. A light-emitting device comprising:
the light-emitting element according to claim 2; and
at least one of a transistor and a substrate.

4. An electronic device comprising:
the light-emitting device according to claim 3; and
at least one of a sensor, an operation button, a speaker, and a microphone.

5. A lighting device comprising:
the light-emitting device according to claim 3; and
a housing.

6. An organometallic complex comprising a structure represented by Formula (G0): 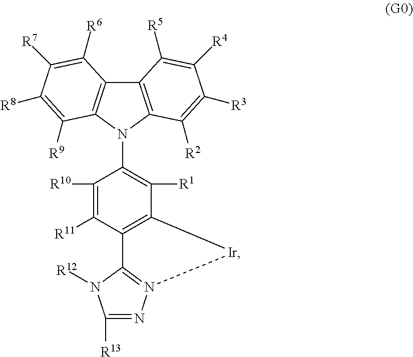
wherein R¹ to R¹³ each independently represent any one of hydrogen, an alkyl group having 1 to 6 carbon atoms, a cycloalkyl group having 5 to 7 carbon atoms, and an aryl group having 6 to 12 carbon atoms.

7. The organometallic complex according to claim 6,
wherein the organometallic complex is represented by Formula (G1):

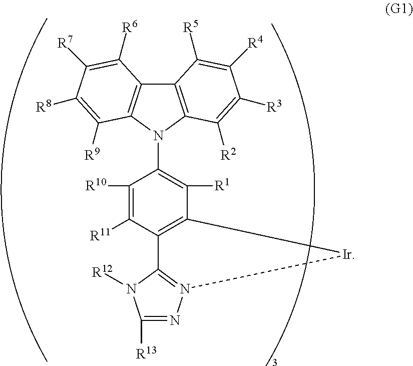

8. The organometallic complex according to claim 7,
wherein the organometallic complex is represented by Formula (G2): 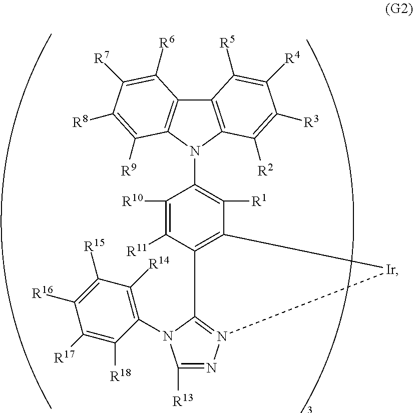
and
wherein R¹⁴ to R¹⁸ each independently represent any one of hydrogen, an alkyl group having 1 to 6 carbon atoms, a cycloalkyl group having 5 to 7 carbon atoms, and an aryl group having 6 to 12 carbon atoms.

9. The organometallic complex according to claim 8,
wherein R¹³ represents a methyl group.

10. The organometallic complex according to claim 8,
wherein the organometallic complex is represented by Formula (G4): 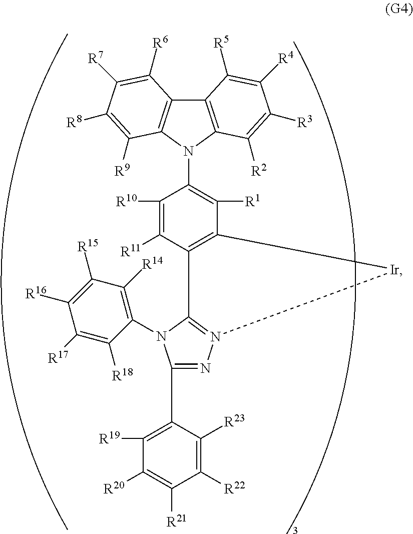
and
wherein R¹⁹ to R²³ each independently represent any one of hydrogen, an alkyl group having 1 to 6 carbon atoms, a cycloalkyl group having 5 to 7 carbon atoms, and an aryl group having 6 to 12 carbon atoms.

11. The organometallic complex according to claim 10,
wherein the organometallic complex is represented by Formula (G5):

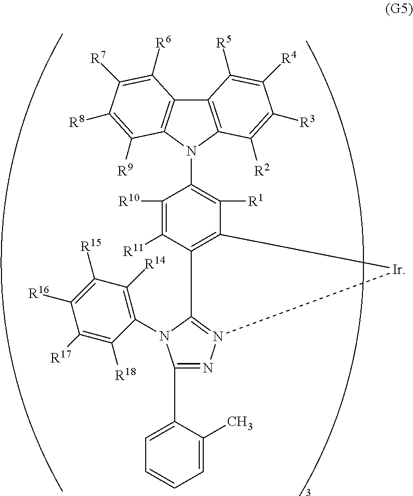

12. The organometallic complex according to claim 10,
wherein the organometallic complex is represented by Formula (G6):

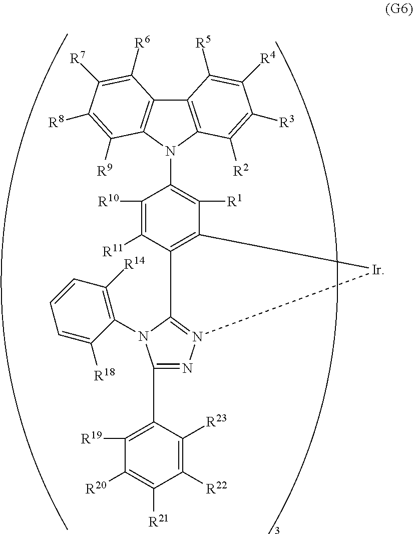

13. The organometallic complex according to claim 12, wherein each of R¹⁴ and R¹⁸ represents a methyl group or an isopropyl group.

14. The organometallic complex according to claim 12,
wherein the organometallic complex is represented by Formula (G7):

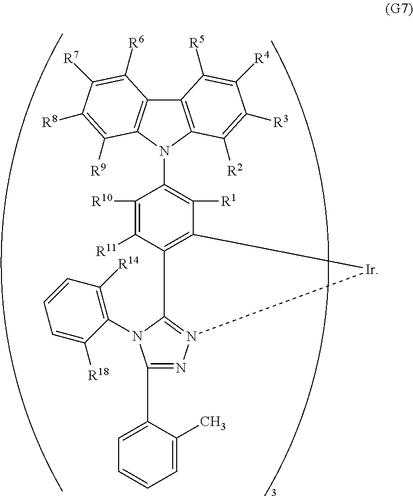

15. A light-emitting element comprising the organometallic complex according to claim 6.

16. A light-emitting device comprising:
the light-emitting element according to claim 15; and
at least one of a transistor and a substrate.

17. An electronic device comprising:
the light-emitting device according to claim 16; and
at least one of a sensor, an operation button, a speaker, and a microphone.

18. A lighting device comprising:
the light-emitting device according to claim 16; and
a housing.
